(19) United States
(12) Patent Application Publication
(10) Pub. No.: US 2013/0291922 A1
(43) Pub. Date: Nov. 7, 2013

(54) Composite Modular Power Generating Systems and Methods

(71) Applicant: BARTOS ARCHITECTURE, INC., (US)

(72) Inventors: Mark Bartos, San Mateo, CA (US); Eric Holm, San Mateo, CA (US); Kenneth Kubiak, San Carlos, CA (US)

(73) Assignee: BARTOS ARCHITECTURE, INC., San Mateo, CA (US)

(21) Appl. No.: 13/663,412

(22) Filed: Oct. 29, 2012

Related U.S. Application Data
(60) Provisional application No. 61/552,224, filed on Oct. 27, 2011.

(51) Int. Cl. H01L 31/048; H01L 31/042; H01L 31/18

(52) U.S. Cl. CPC H01L 31/048; H01L 31/18; H01L 31/0422
USPC 136/244; 29/825; 211/41.1

(57) ABSTRACT

A photovoltaic mount can include a groove to receive a plurality of photovoltaic panels spaced by seismic gaps, a wall coupled to a structural framing channel, and modular connecting devices to couple the plurality of photovoltaic panels to portions of the groove. The photovoltaic mount can be fabricated away from a power generation site. A modular photovoltaic system can include a plurality of prefabricated intermediate modules, each having photovoltaic panels modularly secured thereon, and a prefabricated termination module having photovoltaic panels modularly secured thereon. The modular photovoltaic system can be assembled at a power generation site while the prefabricated intermediate and termination modules can be fabricated away from the power generation site. A photovoltaic power generating center can include a composite arrangement of modular photovoltaic systems. Also disclosed are related methods.

### CROSS-REFERENCE TO RELATED APPLICATIONS

This application claims priority to U.S. provisional application Ser. No. 61/552,224, filed Oct. 27, 2011, entitled “Modular Photovoltaic Assemblies and Related Methods,” which is incorporated by reference.

### TECHNICAL FIELD

The technical field relates to power generation systems and methods. More particularly, the technical field relates to systems and methods for providing power generation structures.

### BACKGROUND

Power generation uses a power generation source to capture and transfer energy to a consumer, either directly or through a power distribution network. The power distribution network can take the form of an intelligent power grid that provides power to customers over widely dispersed geographic areas. Though power distribution has been widely distributed, conventional power generation has been limited to a few concentrated locations, which has often proven costly and inefficient.

Implementing a distributed network of power generating sources has also conventionally proven costly and inefficient. Power generation sources, such as solar power generation plants, often integrate into a physical structure. A facility seeking to implement a power generation source faces the prospects of having to build the power generation source from scratch on the site of the structure. As a result, the facility is typically forced to coordinate teams of architects, civil engineers, electrical engineers, and other building professionals who build the power generation source much the way they build other buildings on-site. The conventional building process can involve costly iterations of custom design and implementation. The conventional building process can prove prohibitively expensive to a facility seeking energy independence or the opportunity to sell power to a power distribution network.

### SUMMARY

Disclosed is a photovoltaic mount comprising a photovoltaic body that can include a groove adapted to receive a first edge of a first photovoltaic panel at a first predetermined point, a second edge of the photovoltaic panel at a second predetermined point, and an edge of a second photovoltaic panel at a third predetermined point separated from the second predetermined point by a seismic gap. The photovoltaic mount can include a first fastener adapted to secure the first photovoltaic panel to the photovoltaic mount, a second fastener adapted to secure the second photovoltaic panel to the photovoltaic mount, a connective housing adapted to receive an electrical conduit coupled to the first photovoltaic panel and the second photovoltaic panel, and a modular coupling interface adapted to physically link to a modular power generation assembly, and to provide an electrical current from the electrical conduit to the modular power generation assembly.

The photovoltaic mount can include a structural framing channel adapted to house the connective assembly. The second photovoltaic panel of the photovoltaic mount can include a midsection photovoltaic panel, and the photovoltaic mount can comprise a structural framing channel under the second photovoltaic panel. The first photovoltaic panel of the photovoltaic mount can comprise an endsection photovoltaic panel, and the photovoltaic mount can comprise a structural framing channel adjacent to a wall of the groove of the photovoltaic mount.

In some embodiments, the modular physical structure comprises a modular canopy. The photovoltaic structural mount can be sized to facilitate efficient transport to a power generation site. For instance, the photovoltaic structural mount can have a length of approximately forty feet and a width of approximately twelve feet.

Disclosed is a modular power generation unit. The modular power generation unit can comprise a modular base connection unit adapted to receive a support, a modular photovoltaic mount coupled to the modular base connection unit, the modular photovoltaic unit having a plurality of mounted photovoltaic panels, each of the plurality of photovoltaic panels separated by a seismic gap. The modular power generation unit can comprise a modular interface adapted to physically link the modular power generation unit to another modular power generation unit, and to provide from the plurality of photovoltaic panels to the other modular power generation unit or receive from the other modular power generation unit an electrical current.

The modular interface of the modular power generation unit can comprise a male interface adapted to provide the electric current to the other modular unit and/or a female interface adapted to receive the electric current from the other modular unit. The modular interface can comprise one or more of a modular intermediate interface and a modular termination interface.

In some embodiments, the modular photovoltaic mount of the modular power generation unit can be oriented with a specified tilt. For instance, the specified tilt can be less than 5 degrees or approximately 15 degrees. The support of the modular power generation unit can comprise a column. The base of the modular power generation unit can comprise one or more of a prefabricated base and a drilled pier. The modular power generation unit can also include a combiner box configured to receive the electrical current from the other modular structure. The modular power generation unit can further include a recombiner box configured to receive the electrical current from a combiner box on the other modular structure. In some embodiments, the modular power generation unit can include a joint attached to the framing channel, the joint adapted to connect the modular structure to the other modular structure. The modular power generation unit can be integrated into a solar canopy or a modular carport.

In some embodiments, the modular power generation unit can be sized to facilitate efficient transportation to a power generation site. The modular power generation unit can have a length of approximately forty feet and a width of approximately twelve feet.

Disclosed is a modular photovoltaic system. The modular photovoltaic system can include a plurality of prefabricated intermediate modules, each of the plurality of prefabricated intermediate modules comprising a prefabricated mount structurally connecting a plurality of photovoltaic panels to a support adapted to be received by a base, and an intermediate electrical interface that provides electrical current from the plurality of photovoltaic panels. The modular photovoltaic system can include a prefabricated termination module, which in turn can include a prefabricated mount structurally connecting a plurality of photovoltaic panels to a support adapted to be received by a base, a plurality of termination electrical interfaces, each of the plurality of termination electrical interfaces receiving the electrical current from each of the plurality of prefabricated intermediate modules, and an output interface that provides to an external load the electrical current from the plurality of photovoltaic panels on the prefabricated termination module and a sum of electrical currents from the plurality of prefabricated intermediate modules.

The plurality of prefabricated intermediate modules of the modular photovoltaic structure can be arranged in series with the prefabricated termination module. In some embodiments, the plurality of prefabricated intermediate modules can comprise a plurality of prefabricated wing modules and the prefabricated termination module comprises a center module. In various embodiments, the prefabricated termination module can include a combiner box to receive the electrical current from each of the plurality of prefabricated intermediate modules, thereby creating the sum of electrical currents. One of the plurality of prefabricated intermediate modules can comprise a combiner box to receive the electrical current from another of the plurality of prefabricated intermediate modules, thereby creating another sum of electrical currents. The prefabricated termination module can comprise a recombiner box to receive summed currents from a combiner box on one of the plurality of prefabricated intermediate modules. The modular photovoltaic system is incorporated into a carport and/or a school parking lot.

Disclosed is a method that can include: creating a photovoltaic mount comprising a groove that receives a first photovoltaic panel having a first edge and a second edge, the groove receiving a second photovoltaic panel having an edge seismically spaced from the second edge of the first photovoltaic panel; creating a plurality of modular connecting assemblies along a wall of the photovoltaic mount, the modular connecting assemblies facilitating mounting the photovoltaic mount onto a physical structure; attaching a structural framing channel to the wall; placing an electrical connectors through the structural framing channel; and connecting the electrical connectors to the first photovoltaic panel and the second photovoltaic panel.

The method can include coupling the first edge of the first photovoltaic panel to an end of the groove; coupling the second edge of the first photovoltaic panel to an intermediate point of the groove; and coupling the edge of the second photovoltaic panel to another intermediate point of the groove. The method can be executed in a dedicated manufacturing facility.

Disclosed is a method for creating a modular structure. The method can include: creating a prefabricated photovoltaic mount that receives a plurality of photovoltaic panels with a respective plurality of seismically spaced fasteners, the prefabricated photovoltaic mount comprising a plurality of modular connecting devices to connect the prefabricated photovoltaic mount to a support; obtaining one or more structural framing channels containing one or more electrical connectors; using each of the one or more structural framing channels to separate two of the plurality of photovoltaic panels on the prefabricated photovoltaic mount; adapting at least some of the one or more electrical connectors to connect the plurality of photovoltaic panels to an external load; adapting the support to be received by a base; and coupling the support to an intermediate point of the prefabricated photovoltaic mount. The method can be executed in a dedicated manufacturing facility. The method can further include connecting the support to the base. In some embodiments, connecting the support to the base can include casting the support into the base. Connecting the support to the base can be performed on the site of the created modular structure. In some embodiments, the method can include attaching a combiner box to the one or more electrical connectors, the combiner box configured to receive electrical current from another modular structure. The method can further include attaching a recombiner box to the one or more electrical connectors, the recombiner box configured to receive electrical current from a combiner box on another modular structure.

### BRIEF DESCRIPTION OF THE DRAWINGS

FIG. 1 shows an example of a power generation environment.

FIG. 2 shows an example of a composite modular power generating center.

FIG. 3 shows an example of a line diagram of a composite modular power generating center.

FIG. 4 shows an example of a group of modular solar power generation units.

FIG. 5 shows an example of a top view of a group of modular solar power generation units.

FIG. 6 shows an example of a top view of a group of modular solar power generation units.

FIG. 7 shows a flowchart of an example of a method for assembling a group of modular solar power generation units.

FIG. 8 shows an example of conceptual diagram of a modular solar power generation unit.

FIG. 9 shows a flowchart of an example of a method for fabricating modular solar power generation unit.

FIG. 10 shows an example of a side view of a tilted modular solar power generation unit.

FIG. 11 shows an example of a side view of an untilted modular solar power generation unit.

FIG. 12 shows an example of a top view of a set of photovoltaic panels mounted on a modular photovoltaic mount.

FIG. 13 shows an example of a side view of a tilted modular solar power generation unit, including a modular base connection unit.

FIG. 14 shows an example of a side view of an untilted modular solar power generation unit, including a modular base connection unit.

FIG. 15A shows an example of a side view of a midsection panel fastening assembly.

FIG. 15B shows an example of a side view of a midsection panel fastening assembly.

FIG. 16A shows an example of a side view of a midsection panel fastening assembly.

FIG. 16B shows an example of a side view of a midsection panel fastening assembly.

FIG. 17 shows an example of a side view of a modular tilted photovoltaic panel endpiece fastener.

FIG. 18 shows an example of a side view of a modular untilted photovoltaic panel endpiece fastener.

FIG. 19 shows an example of a side view of a supportive assembly of a modular solar power generation unit.

FIG. 20 shows an example of a side view and a top view of a supportive assembly of a modular solar power generation unit.

FIG. 21 shows an example of a modular photovoltaic mount.

FIG. 22 shows a flowchart of an example of a method for fabricating a modular photovoltaic mount.

FIG. 23A shows an example of a side view of a portion of a modular photovoltaic mount including two photovoltaic panels.

FIG. 23B shows an example of a side view of a portion of a modular photovoltaic mount including one photovoltaic panel.

FIG. 24A shows an example of a modular midsection fastener.

FIG. 24B shows an example of a modular end fastener.

FIG. 25A shows an example of a portion of a modular photovoltaic mount near an underlying structural framing channel.

FIG. 25B shows an example of a portion of a photovoltaic mount near an adjacent structural framing channel.

FIG. 26A shows an example of a side view of a portion of a modular coupling interface.

FIG. 26B shows an example of a top view of a portion of a modular coupling interface.

FIG. 27 shows an example of a portion of a modular coupling interface.

FIG. 28 shows examples of groups of modular solar power generation units.

FIG. 29 shows examples of groups of modular solar power generation units.

FIG. 30 shows examples of groups of modular solar power generation units.

FIG. 31 shows an example of a Class “A” modular solar power generation unit.

FIG. 32 shows an example of a Class “B1” modular solar power generation unit.

FIG. 33 shows an example of a Class “B2” modular solar power generation unit.

FIG. 34 shows an example of a Class “B3” modular solar power generation unit.

FIG. 35 shows an example of a Class “BC1” modular solar power generation unit.

FIG. 36 shows an example of a Class “C1” modular solar power generation unit.

FIG. 37 shows an example of a Class “C2” modular solar power generation unit.

FIG. 38 shows an example of a Class “C3” modular solar power generation unit.

FIG. 39 shows example of configurations of electrical stubs of modular solar power generation units.

FIG. 40 shows example of configurations of electrical stubs of modular solar power generation units.

FIG. 41 shows example of configurations of electrical stubs of modular solar power generation units.

FIG. 42 shows example of configurations of electrical stubs of modular solar power generation units.

FIG. 43 shows an example of wiring configurations of modular solar power generation units.

FIG. 44 shows an example of wiring configurations of modular solar power generation units.

FIG. 45 shows an example of wiring configurations of modular solar power generation units.

FIG. 46 shows an example of wiring configurations of modular solar power generation units.

FIG. 47 shows an example of wiring configurations of modular solar power generation units.

FIG. 48 shows an example of wiring configurations of modular solar power generation units.

FIG. 49 shows an example of wiring configurations of modular solar power generation units.

FIG. 50 shows an example of a wiring diagram for wiring a modular solar power generation unit to a structural framing channel.

FIG. 51 shows an example of a wiring diagram for wiring a modular solar power generation unit to a structural framing channel.

### DETAILED DESCRIPTION

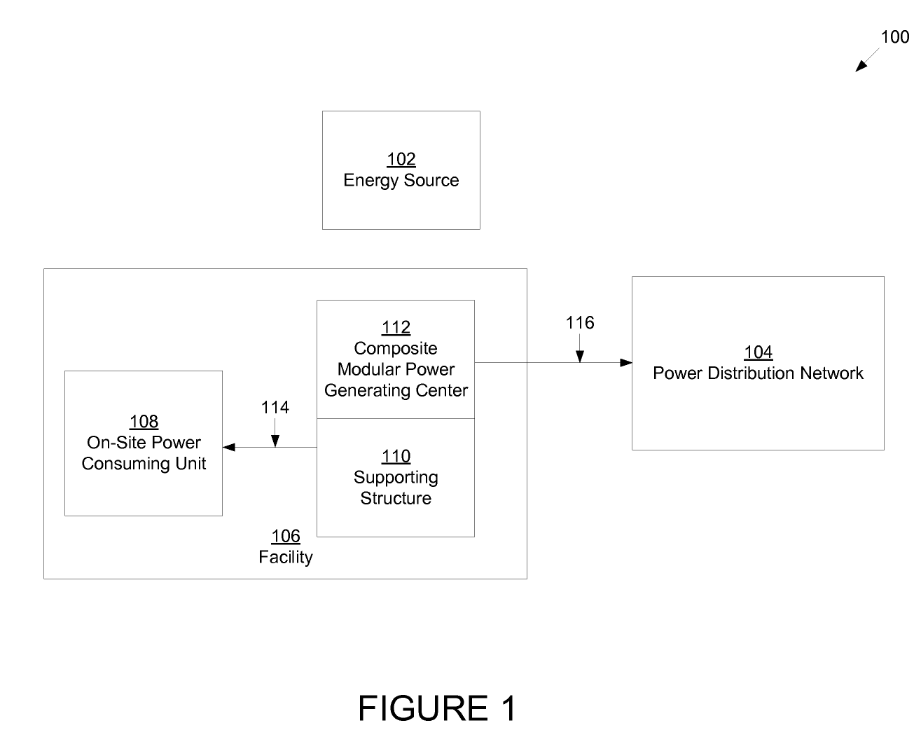

FIG. 1 shows an example of a power generating environment 100. The power generating environment 100. In the example of FIG. 1, the power generating environment 100 can include an energy source 102, a power distribution network 104, and a facility 106. The power generating environment 100 can be configured to include an easy-to assemble, cost-effective, and efficient portion of a distributed power generating system. More specifically, the power generating environment 100 may be adapted to supply power from energy sources to a power distribution network and/or to facilities associated with the power generating environment 100.

The energy source 102 can include a natural resource that can be converted to supply power, such as solar radiation. In a specific implementation, the energy source 102 is renewable. A renewable energy source has the ability to replenish through natural processes and the passage of time. Examples of renewable energy sources can include solar radiation, ocean tides, winds, geothermal energy sources, and biomass energy sources. In a specific implementation, the energy source 102 is nonrenewable. A nonrenewable energy source, conversely, does not have the ability to replenish through natural processes or the passage of time. Examples of nonrenewable energy sources can include gasoline, coal, oil, other fossil fuel sources, and enriched nuclear energy sources. The energy source 102 can be concentrated in a location near the power generating environment 100 or geographically dispersed around the area of the power generating environment 100. For instance, if the energy source 102 is a water source, a coal mine, or an oil well, the energy source 102 can be concentrated at a single location or set of locations. If the energy source 102 is wind or sunshine, the energy source 102 may be dispersed around the area of the power generating environment 100.

The power distribution network 104 can be an interconnected network for delivering power from suppliers to consumers. The power distribution network 104 can include power stations that produce power and transmission lines that carry power from power stations to demand centers and to end users. The power distribution network 104 can include a power grid. A power grid is a power distribution network having generating plants, transmission networks to move generated power over large distances, including across the borders of sovereign units like states, and local power dispersement networks that facilitate delivery of power at reduced voltages to consumers. The power distribution network 104 can be regulated by government entities and can be administered by one or more of government agencies and regulated corporations. In some embodiments, the power distribution network 104 can be limited to local power distribution about the vicinity of the power generating environment 100. Though FIG. 1 shows the power distribution network 104 outside the facility 106, those of ordinary skill in the art will appreciate that some or all of the power distribution network 104 can be included in the facility 106, or that some or all of the facility 106 can be included in the power distribution network 104.

The facility 106 can include a set of buildings such as one or more human-made structures. The facility 106 can include commercial buildings, such as hotels, resorts, schools, office complexes, sports arenas, travel facilities, convention centers, medial facilities, telecommunications facilities, factories, data facilities, and other types of facilities. The facility 106 can include government buildings or buildings administered by nonprofit agencies. The facility 106 can include components that generate power from the energy source 102. The facility 106 can also include entities that consume a combination of power generated using the energy source 102 and power received over the power distribution network 104. Power generated locally at the facility is considered power generated “on-site” while power received from the power distribution network 104 is considered power generated “off-site.” In some embodiments, the facility 106 can include a tiered power consumption plan. To this end the on facility 106 can be configured to initially meet its power needs using power generated on-site. If, at a given moment, the needs cannot be met with the power generated on-site, the facility 106 can request power from the power distribution network 104. As a result of the tiered power consumption plan, the facility 106 can reduce its power consumption costs by purchasing only the power it cannot generate on-site. In various embodiments, the facility 106 can be adapted to purchase from the power distribution network 104 only the power that cannot be generated on-site. The facility 106 can also be adapted to sell back to the power distribution network 104 the excess power that is generated on-site.

The facility 106 can include an on-site power consuming unit 108, a supporting structure 110, and a composite modular power generating center 112. The on-site power consuming unit 108 can include a set of buildings such as human-made structures. The on-site power consuming unit 108 can be configured to consume a combination of power generated using the energy source 102 and power received over the power distribution network 104. The on-site power consuming unit 108 can be located at or around a single portion of the facility 106 or can be dispersed around the facility 106. The on-site power consuming unit 108 can implement a tiered power consumption plan. The on-site power consuming unit 108 can also be adapted to signal when its power needs are met with on-site power so that power generated on-site can be sold to the power distribution network 104.

The supporting structure 110 can include structures adapted to hold a physical load and stabilize the physical load from forces or events such as gravity, wind, storms, earthquakes, and other forces or events. The supporting structure 110 can include arches, beams, and columns. In some embodiments, the supporting structure 110 can be adapted to support the composite modular power generating center 112. The supporting structure 110 can include portions of a building, such as a house, apartment, or commercial building. The supporting structure 110 can include a nonresidential structure, such as a carport. A carport is a covered structure used to offer at least limited protection to vehicles (e.g., cars) from elements such as sun, rain, and wind. The carport can be free standing or attached to a wall. The supporting structure 110 can also be a garage. A garage is a completely covered structure that is configured to offer protection to vehicles (e.g., cars) but is not ventilated. In some embodiments, the supporting structure 110 can include structures adapted to hold a canopy. A canopy is an overhead structure over which a material (e.g., metal, concrete, stone, roofing, and fabric) is attached to provide share or shelter. The supporting structure 110 can be adapted, for instance, to hold a canopy that serves as a carport.

In the example of FIG. 1, the composite modular power generating center 112 can include structures and/or components to generate power on-site by capturing energy from the energy source 102. As a power generating center, the composite modular power generating center 112 can provide power to one or more of the on-site power consuming unit 108 (e.g. over transmission line 114) and the power distribution network 104 (e.g., over transmission line 116). The composite modular power generating center 112 can include power extractors. A power extractor is an apparatus for extracting power from an energy source (e.g., energy source 102). Examples of power extractors include oil pumpjacks, coal mining apparatuses, nuclear power plants, windmills, hydroelectric apparatuses, geothermal apparatuses, and photovoltaic panels.

The composite modular power generating center 112 can include modular components. As used herein, a “modular” component is a component that can be independently created and used in different systems to drive multiple functionalities across the different systems. Modular components can be characterized as: facilitating partitioning of a system into discrete scalable, reusable and/or interchangeably usable modules comprising isolated, self-contained functional elements; facilitating systematic use of consistent interfaces between modular components, including object-oriented descriptions of module functionality, and facilitating ease of change to achieve technology transparency, and as much as possible, use of industry standards for key interfaces. In the example of FIG. 1, the composite modular power generating center 112 can include one or more modular buildings and/or construction elements. The composite modular power generating center 112 can also be composite. As used herein, a “composite” structure is a structure having a predetermined arrangement of components that can interconnect to facilitate creation of the structure. The arrangement may include layout of key component interfaces and the predesign of predetermined sets of components that can be modularly arranged to create the composite structure. As a result, the composite modular power generating center 112 can be adapted to meet the power needs of the facility 106 with energy from the energy source 102, implement a tiered power consumption plan for the facility 106, and/or be provide power to the power distribution network 104.

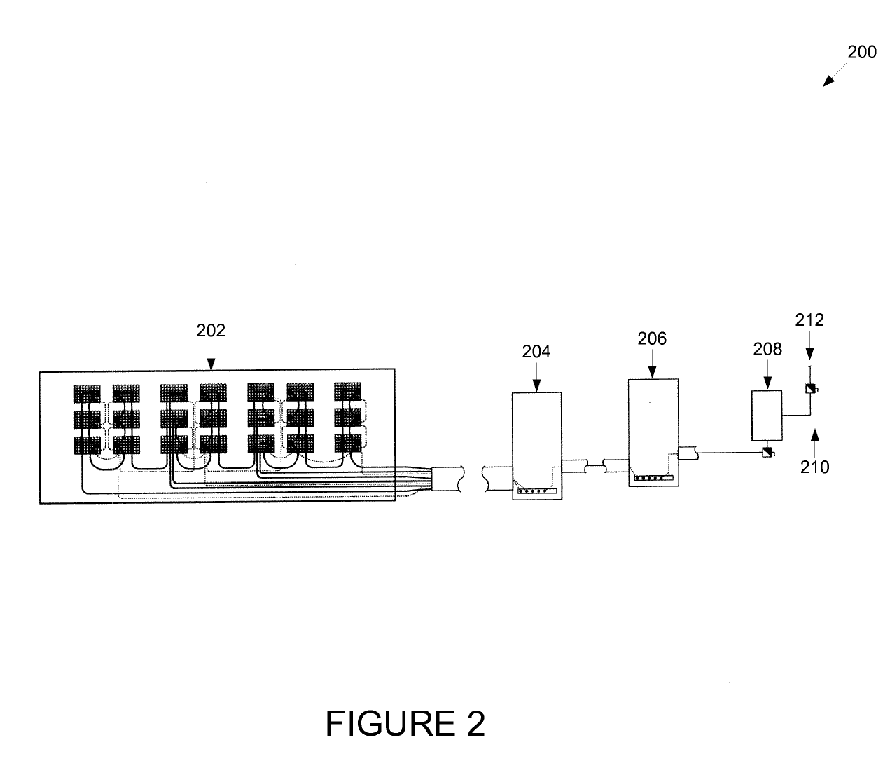

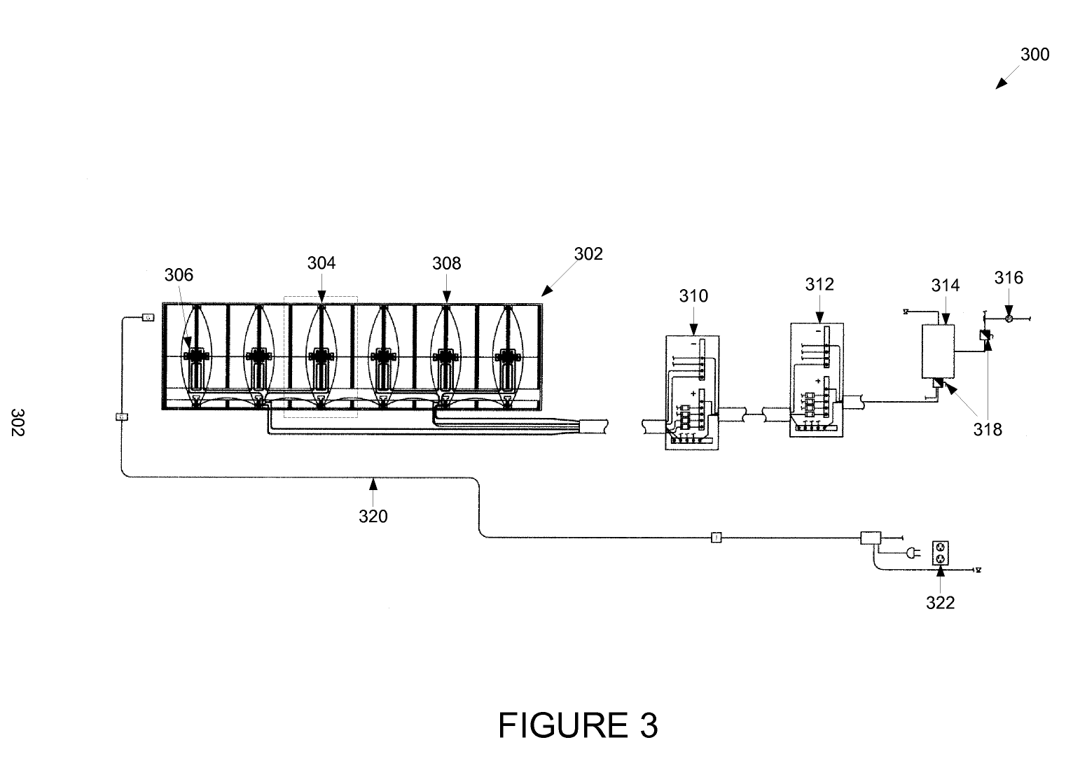

FIG. 2 shows an example of a composite modular power generating center 200. In the example of FIG. 2, the composite modular power generating center 200 can include a modular photovoltaic array 202, a combiner box 204, a recombiner box 206, a photovoltaic inverter 208, a disconnection switch 210, and a power distribution interface 212 to an electrical panel or switchboard. The modular photovoltaic array 202 can include an array of photovoltaic panels, electrical interconnections, and mounting elements. A photovoltaic panel is a packaged connected assembly of photovoltaic cells that in turn convert the energy of light directly into electricity using photovoltaic effects. The photovoltaic panels of the modular photovoltaic array 202 can be configured to convert sunlight into energy. In the example of FIG. 3, the modular photovoltaic array 202 includes seven columns of three photovoltaic panels; however, those of ordinary skill in the art will appreciate that different arrangements of photovoltaic panels are possible. Each column of the modular photovoltaic array 202 can be coupled using electrical interconnections. In the example of FIG. 2, the electrical interconnections of the various columns of the modular photovoltaic array 202 can be joined along an area (e.g., an edge) of the modular photovoltaic array 202.

The combiner box 204 can include an assembly and/or circuitry to combine a set of electrical interconnections. The combiner box 204 can include an input interface adapted to receive the joined electrical interconnections from the modular photovoltaic array 202. In various embodiments, the input interface of the combiner box 204 can also be adapted to receive joined electrical interconnections from photovoltaic arrays and/or elements other than the modular photovoltaic array 202. The combiner box 204 can provide the combined electrical signal to another element, such as the recombiner box 206. In the example of FIG. 2, the recombiner box 206 can include an assembly and/or circuitry to combine a set of electrical interconnections from the combiner box 204 and/or other elements other than the combiner box 204, such as other combiner boxes. The recombiner box 206 can provide the combined electrical signal to another element, such as the photovoltaic inverter 208. Though FIG. 2 shows a single combiner box 204, a single recombiner box 206, and a single photovoltaic inverter 208, those of ordinary skill in the art will appreciate that other permutations (including more or less combiner boxes, recombiner boxes, and inverters) are possible without departing from the inventive concepts described herein.

The photovoltaic inverter 208 can be adapted to receive signals from the recombiner box 206 and/or elements other than the recombiner box 206 (e.g. other recombiner boxes) and can provide the recombined signal to the power distribution interface 212. The photovoltaic inverter 208 can convert direct current from the modular photovoltaic array 202 into a utility frequency alternating current that can be fed into a power distribution system (e.g., a commercial power grid) and/or an on-site power consuming unit. The photovoltaic inverter 208 can allow the power generated by the modular photovoltaic array 202 to be used by applications by power distribution systems and/or on-site power consuming units.

The disconnection switch 210 can be adapted to connect and/or disconnect the photovoltaic inverter 208 from a power distribution system. The disconnection switch 210 can include a conduit configured to disrupt and/or redirect electrical current away from the power distribution interface 212. In this example, the power distribution interface 212 can be configured to couple the composite modular power generating center 200 to a power distribution system.

FIG. 3 shows an example of a line diagram of a composite modular power generating center 300. In the example of FIG. 3, the composite modular power generating center 300 can include a modular photovoltaic array 302, a combiner box 310, a recombiner box 312, a photovoltaic inverter 314, a power distribution system interface 316, disconnection switches 318, an on-site electrical interconnection 320, and an on-site electrical receptacle 322.

The modular photovoltaic array 302 can include an array of photovoltaic panels, electrical interconnections, and mounting elements. The modular photovoltaic array 302 can include a photovoltaic assembly 304, a photovoltaic junction box 306, and a frame 308. The photovoltaic assembly 304 can include a set of photovoltaic panels. The photovoltaic junction box 306 can be configured to join electrical interconnections from each photovoltaic panel in a photovoltaic assembly (e.g., each photovoltaic panel in the photovoltaic assembly 304). The modular photovoltaic array 302 can provide a unified electrical output from the various photovoltaic assemblies housed thereon. The frame 308 can provide support for photovoltaic panels mounted on the modular photovoltaic array 302.

The combiner box 310 can be adapted to receive electrical current from the modular photovoltaic array 302 and other photovoltaic arrays. The recombiner box 312 can be adapted to receive electrical current from the combiner box 310 and other combiner boxes. The photovoltaic inverter 314 can be adapted to receive electrical current from the recombiner box 312 and other recombiner boxes. The photovoltaic inverter 314 can also be configured to convert direct current into alternating current for commercial power consumption. Though FIG. 3 shows a single combiner box 310, a single recombiner box 312, and a single photovoltaic inverter 314, those of ordinary skill in the art will appreciate that other permutations (including more or less combiner boxes, recombiner boxes, and inverters) are possible without departing from the inventive concepts described herein.

In the example of FIG. 3, the power distribution system interface 316 can interface with a power distribution system. The disconnection switches 318 can be adapted to disrupt and/or redirect electrical current away from the power distribution system interface 316.

In the example of FIG. 3, the on-site electrical interconnection 320 can be configured to allow for the modular photovoltaic array 302 to receive power and/or data from third party power monitors or other entities seeking to monitor the power or other parameters of the modular photovoltaic array 302. The on-site electrical receptacle 322 can comprise an electrical outlet and/or data outlet to provide power and/or data to the modular photovoltaic array 302.

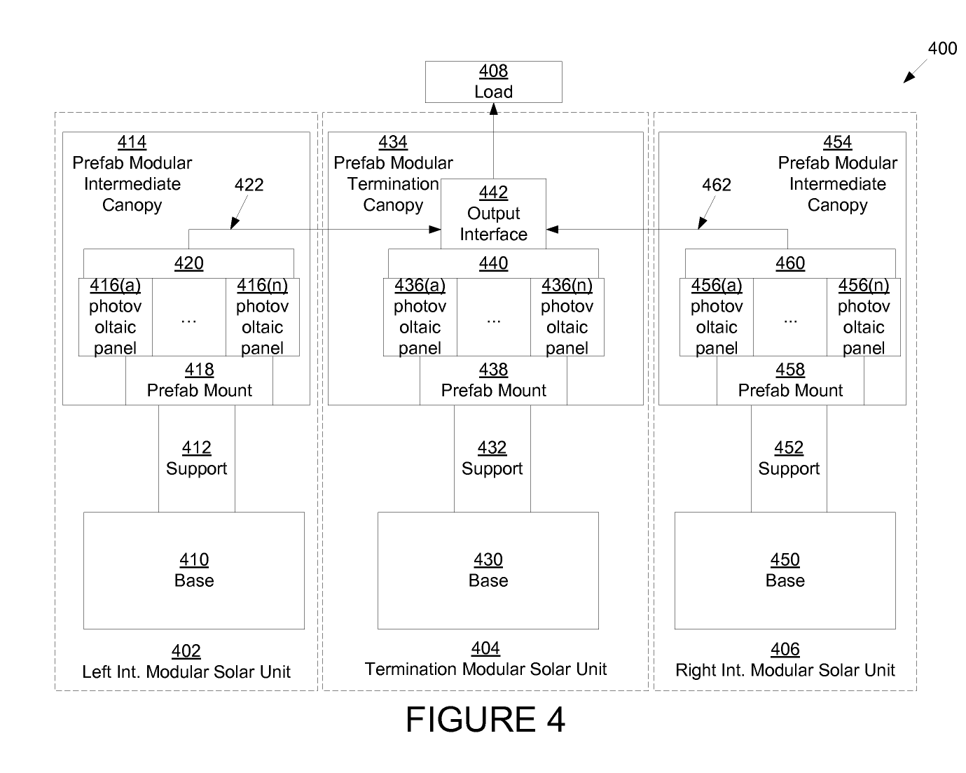

FIG. 4 shows an example of a group 400 of modular solar power generation units. The group 400 can be considered a modular power generation assembly. In the example of FIG. 4, the group 400 of modular solar power generation units can capture photovoltaic energy from a photovoltaic energy source, such as the sun. In this example, the group 400 can include a set of prefabricated modules that can be built off of the site of the group 400. For instance, the set of prefabricated modules in the group 400 can be built at a dedicated manufacturing facility such as a factory. One or more of the prefabricated modules in the group 400 can include prefabricated interfaces that facilitate modular interconnections with one another. The sizes and shapes of the prefabricated modules and the prefabricated interfaces in the group 400 can be predesigned to allow construction teams to assemble the group 400 on the site of the group 400. For instance, the sizes and shapes of both the prefabricated modules and the prefabricated interfaces can be configured to allow mounting and interconnection of the prefabricated modules into a composite modular power generating center.

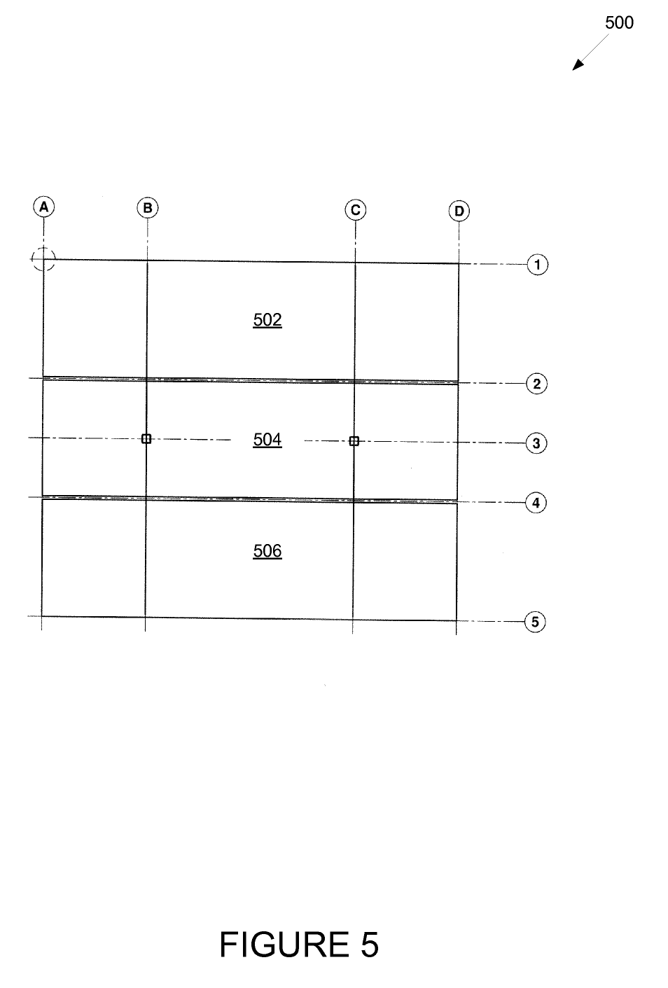

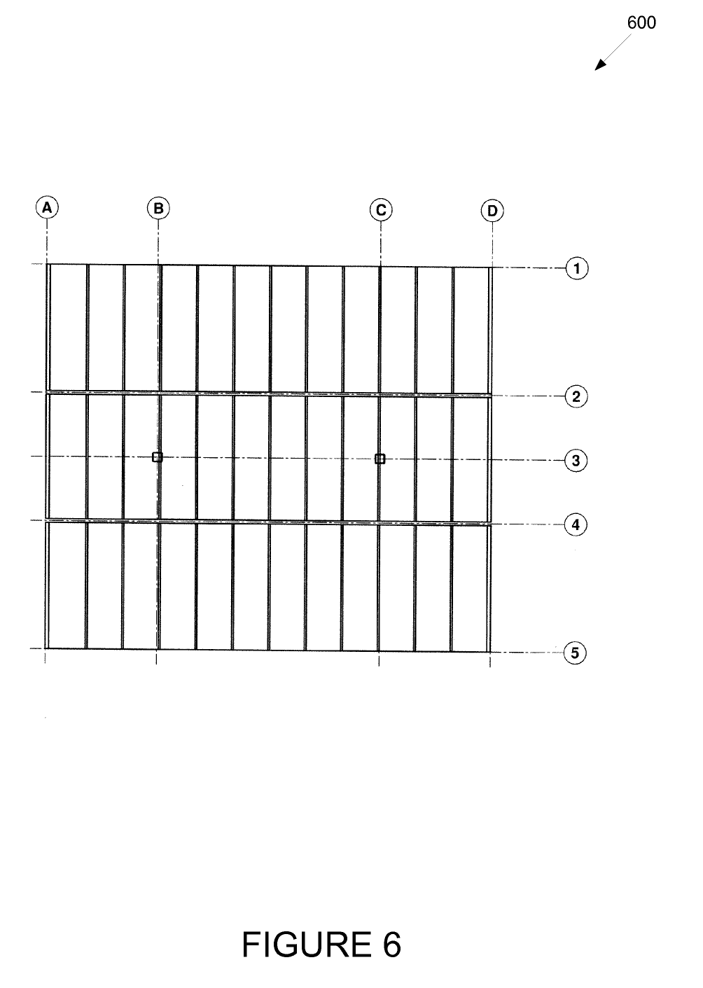

In the example of FIG. 4, the group 400 of modular solar power generation units can include a left intermediate modular solar unit 402, a termination modular solar unit 404, a right intermediate modular solar unit 406, and a load 408. FIG. 5 shows a top-view of a group 500 of modular solar power generation units. The group 500 can include a left intermediate modular solar unit 502, a termination modular solar unit 504, and a right intermediate modular solar unit 506. FIG. 6 shows an example of a top view of a group 600 of modular solar power generation units with photovoltaic panels fastened thereon.

Returning to the example of FIG. 4, the left intermediate modular solar unit 402 can include a set of modularly mounting components to facilitate mounting of photovoltaic panels, and a set of modular interfaces to facilitate both the transfer of captured photovoltaic energy and the interconnection with other modular solar units. In this example, the left intermediate modular solar unit 402 can include a base 410, a support 412, and a prefabricated modular intermediate canopy 414.

The base 410 can include the lowest and supporting layers of the left intermediate modular solar unit 402. The base 410 can comprise a foundation, such as a shallow foundation or a deep foundation. In some embodiments, the base 410 can include a rigid material (e.g., concrete) driven into ground underlying the left intermediate modular solar unit 402. In this example, the support 412 can include a structure adapted to connect the prefabricated modular intermediate canopy 414 to the base 410. In various embodiments, the support 412 can include a rod or piling driven into the base and operatively connected to the prefabricated modular intermediate canopy 414. The support 412 can be prefabricated, meaning that that the support can be a part of predetermined dimensions that is designed and fabricated away from the site of the group 400. For instance, the support 412 can be built at a dedicated manufacturing facility.

The prefabricated modular intermediate canopy 414 can include structures adapted to capture photovoltaic energy. The prefabricated modular intermediate canopy 414 can also include structures adapted to modularly interconnect with the support 412 as well as the prefabricated modular termination canopy 434.

The prefabricated modular intermediate canopy 414 can include photovoltaic panels 416(a) to 416(n), a prefabricated mount 418, and a modular intermediate solar unit interface 420. The photovoltaic panels 416(a) to 416(n) can include an implementation-specific number of photovoltaic panels mounted to a supporting surface of the prefabricated mount 418. In this example, three photovoltaic panels are shown, and the letter “n” is used to denote the implementation-specific number. The number and the dimensions of the photovoltaic panels may be chosen to match a desired canopy size. For instance, it may be desirable to modularly design the prefabricated modular intermediate canopy 414 off-site and then ship prefabricated units to a site for further assembly. In such an instance, the number and size of the photovoltaic panels 416(a) to 416(n) and the size of the prefabricated modular intermediate canopy 414 can be chosen to facilitate efficient transport of a given prefabricated modular intermediate canopy 414. In a specific implementation, the number and size of the photovoltaic panels 416(a) to 416(n) and the size of the prefabricated modular intermediate canopy 414 are be chosen to fit on the bed of a semi-trailer truck.

The prefabricated mount 418 can include structures adapted to connect the photovoltaic panels 416(a) to 416(n) to the support 412. In some embodiments, the prefabricated mount 418 can include a hole (threaded or unthreaded) to receive a rod or piling and fasteners. In this example, the prefabricated mount 418 can be fabricated and connected to the photovoltaic panels 416(a) to 416(n) off-site, but may be adapted to be connected to the support 412 on the site of the group 400.

In the example of FIG. 4, the modular intermediate solar unit interface 420 can include structures adapted to modularly couple the photovoltaic panels 416(a) through 416(n) to the prefabricated modular termination canopy 434. The modular intermediate solar unit interface 420 can include a framing channel to house electrical interconnections that provide current from the photovoltaic panels 416(a) to 416(n). The framing channel can be a metal framing channel such as a strut channel. To this end, the modular intermediate solar unit interface 420 can protect electrical interconnections from the photovoltaic panels 416(a) to 416(n) and can facilitate electrical connections to other modular units. In this example, the modular intermediate solar unit interface 420 can comprise one or more male interfaces and/or one or more female interfaces. A male interface of a unit is an interface that provides an electrical current or signal from the unit. A female interface of a unit is an interface that receives an electrical current or signal from another unit distinct from the unit containing the female interface. The arrangement of male and/or female units in the modular intermediate solar unit interface 420 can depend on the position of the left intermediate modular solar unit 402 in a composite arrangement. In the example of FIG. 4, the modular intermediate solar unit interface 420 can be connected to a modularly coupled electrical pathway 422, which provides electrical current to the termination modular solar unit 404.

The right intermediate modular solar unit 406 can include a set of modularly mounting components to facilitate mounting of photovoltaic panels, and a set of modular interfaces to facilitate both the transfer of captured photovoltaic energy and the interconnection with other modular solar units. In this example, the right intermediate modular solar unit 406 can include a base 450, a support 452, and a prefabricated modular intermediate canopy 454.

The base 450 can include the lowest and supporting layers of the right intermediate modular solar unit 406. The base 450 can be similar to the base 410 of the left intermediate modular solar unit 402. The support 452 can include a structure adapted to connect the prefabricated modular intermediate canopy 454 to the base 450. The support 452 can be similar to the support 412 of the left intermediate modular solar unit 402. The support 452 can be prefabricated.

The prefabricated modular intermediate canopy 454 can include structures adapted to capture photovoltaic energy. The prefabricated modular intermediate canopy 454 can also include structures adapted to modularly interconnect with the support 452 as well as the prefabricated modular termination canopy 434. In this example, the prefabricated modular intermediate canopy 454 can include photovoltaic panels 456(a) to 456(n), a prefabricated mount 458, and a modular intermediate solar unit interface 460. The photovoltaic panels 456(a) to 456(n) can include an arbitrary number of photovoltaic panels mounted to a supporting surface of the prefabricated mount 458. The number and dimensions of the photovoltaic panels 456(a) to 456(n) is arbitrary and need not equal the number or the dimensions of the photovoltaic panels 416(a) to 416(n). The number and dimensions of the photovoltaic panels 456(a) to 456(n) can be chosen to facilitate modular off-site design and efficient transportation (e.g., on semi-trailer trucks) of the prefabricated modular intermediate canopy 454 to the site containing the group 400. The prefabricated mount 458 can include structures adapted to connect the photovoltaic panels 456(a) to 456(n) to the support 452. The prefabricated mount 458 can be similar to the prefabricated mount 418 in the left intermediate modular solar unit 402. The prefabricated mount 458 can be fabricated and connected to the photovoltaic panels 456(a) to 456(n) off-site, but may be adapted to be connected to the support 452 on the site of the group 400.

In the example of FIG. 4, the modular intermediate solar unit interface 460 can include structures adapted to modularly couple the photovoltaic panels 456(a) through 456(n) to the prefabricated modular termination canopy 434. The modular intermediate solar unit interface 460 can include a framing channel, e.g., a strut channel, to house electrical interconnections that provide current from the photovoltaic panels 416(a) to 416(n). The modular intermediate solar unit interface 460 can comprise one or more male interfaces and/or one or more female interfaces. The arrangement of the male and/or female units in the modular intermediate solar unit interface 460 can depend on the position of the right intermediate modular solar unit 406 in a composite arrangement. For instance, the modular intermediate solar unit interface 460 can contain male and/or female interfaces that complement or are symmetrical to the interfaces in the modular intermediate solar unit interface 420 inside the left intermediate modular solar unit 402. The modular intermediate solar unit interface 460 can be connected to a modularly coupled electrical pathway 462, which provides electrical current to the termination modular solar unit 404.

The termination modular solar unit 404 can also include a set of modularly mounting components to facilitate mounting of photovoltaic panels, and a set of modular interfaces to facilitate both the transfer of captured photovoltaic energy and the interconnection with other modular solar units. The termination modular solar unit 404 can include a base 430, a support 432, and a prefabricated modular termination canopy 434.

The base 430 can include the lowest and supporting layers of the termination modular solar unit 404. The base 430 can be similar to the base 410 of the left intermediate modular solar unit 402 and/or the base 450 of the right intermediate modular solar unit 406. The support 452 can include a structure adapted to connect the prefabricated modular termination canopy 434 to the base 430. The support 432 can be similar to the support 412 of the left intermediate modular solar unit 402 and/or the support 452 of the right intermediate modular solar unit 406. The support 432 can be prefabricated.

The prefabricated modular termination canopy 434 include structures adapted to capture photovoltaic energy. The prefabricated modular termination canopy 434 can also include structures adapted to modularly interconnect with the support 432 as well as one or more of the prefabricated modular intermediate canopy 414 and/or the prefabricated modular intermediate canopy 454. In this example, the prefabricated modular termination canopy 434 can include photovoltaic panels 436(a) to 436(n), a prefabricated mount 438, and a modular intermediate solar unit interface 440. The photovoltaic panels 436(a) to 436(n) can include an arbitrary number of photovoltaic panels mounted to a supporting surface of the prefabricated mount 438. The number and dimensions of the photovoltaic panels 436(a) to 436(n) is arbitrary and need not equal the number or the dimensions of the photovoltaic panels 416(a) to 416(n) and/or the number or dimensions of the photovoltaic panels 456(a) to 456(n). The number and dimensions of the photovoltaic panels 436(a) to 436(n) can be chosen to facilitate modular off-site design and efficient transportation (e.g., on semi-trailer trucks) of the prefabricated modular termination canopy 434 to the site containing the group 400. The prefabricated mount 438 can include structures adapted to connect the photovoltaic panels 436(a) to 436(n) to the support 432. The prefabricated mount 438 can be similar to the prefabricated mount 418 in the left intermediate modular solar unit 402 and/or the prefabricated mount 458 in the right intermediate modular solar unit 406. The prefabricated mount 438 can be fabricated and connected to the photovoltaic panels 436(a) to 436(n) off-site, but may be adapted to be connected to the support 432 on the site of the group 400.

The modular intermediate solar unit interface 440 can include structures adapted to modularly couple the photovoltaic panels 436(a) through 436(n) to the output interface 442. The modular intermediate solar unit interface 440 can include a framing channel, e.g., a strut channel, to house electrical interconnections that provide current from the photovoltaic panels 436(a) to 436(n). The modular intermediate solar unit interface 440 can comprise one or more male interfaces and/or one or more female interfaces. The arrangement of the male and/or female units in the modular intermediate solar unit interface 440 can depend on the proximity of the modular intermediate solar unit interface 440 to the output interface 442. In some embodiments, the modular intermediate solar unit interface 440 may be housed within the output interface 442 or may share a framing channel with the output interface 442.

The output interface 442 can include structures adapted to couple modular intermediate solar unit interfaces 420, 440, and 460 to the load 408. The output interface 442 can include a framing channel and/or male and/or female interfaces. The design and layout of the output interface 442 can be adapted to connect to the male and/or female interfaces of the modular intermediate solar unit interfaces 420, 440, and 460. Though FIG. 4 shows the output interface 442 as distinct from the modular intermediate solar unit interface 440, it is noted that the output interface 442 and the modular intermediate solar unit interface 440 can be housed within a common framing channel.

In the example of FIG. 4, the load 408 can include structures adapted to consumer and/or distribute power. The load 408 can receive electrical current from the output interface 442. In various embodiments, the load 408 can include a power distribution network and/or an on-site power consuming unit.

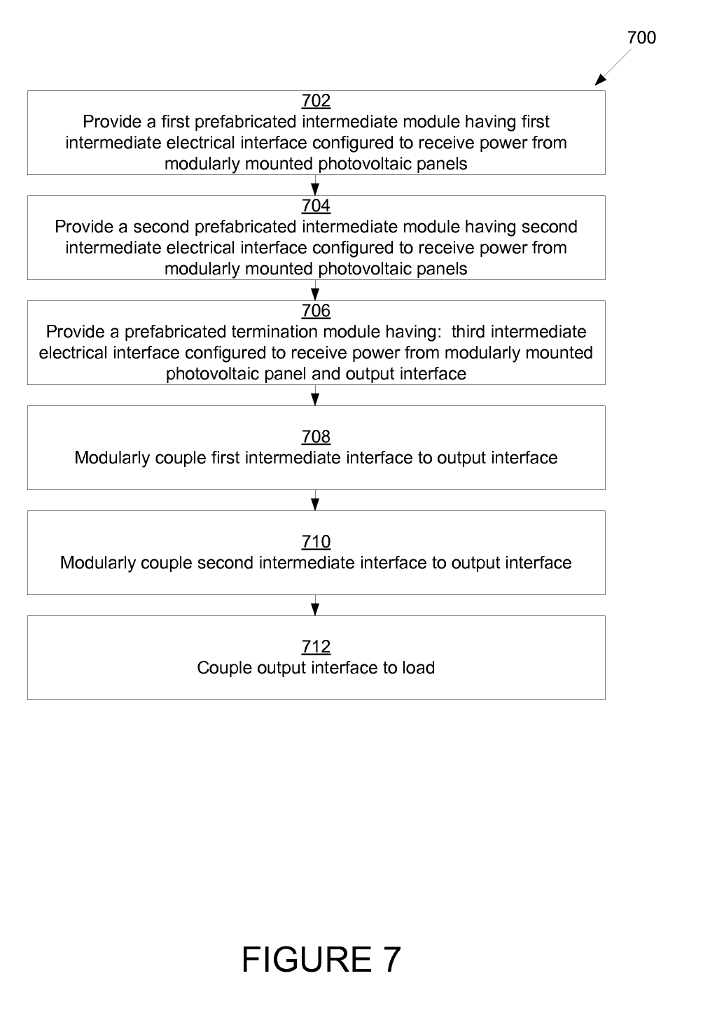

FIG. 7 shows a flowchart of an example of a method 700 for assembling a group of modular solar power generation units. The method 700 is discussed in conjunction with the structures of FIG. 4. The method 700 can contain steps or substeps other than the steps explicitly shown. It can also be possible to practice the inventive concepts of the method 700 without performing all of the illustrated steps.

Step 702 comprises providing a first prefabricated intermediate module having a first intermediate electrical interface that is configured to receive power from a set of modularly mounted photovoltaic panels. In the example of FIG. 4, there can be provided the left intermediate modular solar unit 402. The modular intermediate solar unit interface 420 can be configured to receive power from the photovoltaic panels 416(a) to 416(n), which can be modularly mounted to the prefabricated modular intermediate canopy 414 using a fabrication process.

Step 704 comprises providing a second prefabricated intermediate module having a second intermediate electrical interface that is configured to receive power from a set of modularly mounted photovoltaic panels. In the example of FIG. 4, there can be provided the right intermediate modular solar unit 406. The modular intermediate solar unit interface 460 can be configured to receive power from the photovoltaic panels 456(a) to 456(n), which can be modularly mounted to the prefabricated modular intermediate canopy 454 using a fabrication process.

Step 706 comprises providing a prefabricated termination module having a third intermediate electrical interface that is configured to receive power from a set of modularly mounted photovoltaic panels and an output interface. In the example of FIG. 4, there can be provided the termination modular solar unit 404. The modular intermediate solar unit interface 440 can be configured to receive power from the photovoltaic panels 436(a) to 436(n), which can be modularly mounted to the prefabricated modular termination canopy 434 using a fabrication process. The output interface 442 can be modularly mounted to the prefabricated modular termination canopy 434 in the fabrication process.

Step 708 comprises modularly coupling the first intermediate interface to the termination interface. In the example of FIG. 4, the modular intermediate solar unit interface 420 can be modularly coupled to the output interface 442. In some embodiments, the male interfaces of the modular intermediate solar unit interface 420 can be aligned with the female interfaces of the output interface 442, and the female interfaces of the modular intermediate solar unit interface 420 can be aligned with the male interfaces of the output interface 442. After proper alignment, the modular intermediate solar unit interface 420 can be electrically coupled to the output interface 442.

Step 710 comprises modularly coupling the second intermediate interface to the termination interface. In the example of FIG. 4, the modular intermediate solar unit interface 460 can be modularly coupled to the output interface 442. In some embodiments, the male interfaces of the modular intermediate solar unit interface 460 can be aligned with the female interfaces of the output interface 442, and the female interfaces of the modular intermediate solar unit interface 460 can be aligned with the male interfaces of the output interface 442. After proper alignment, the modular intermediate solar unit interface 460 can be electrically coupled to the output interface 442. In step 712, the output interface 442 can be coupled to the load 408. After step 712, the method 700 may terminate.

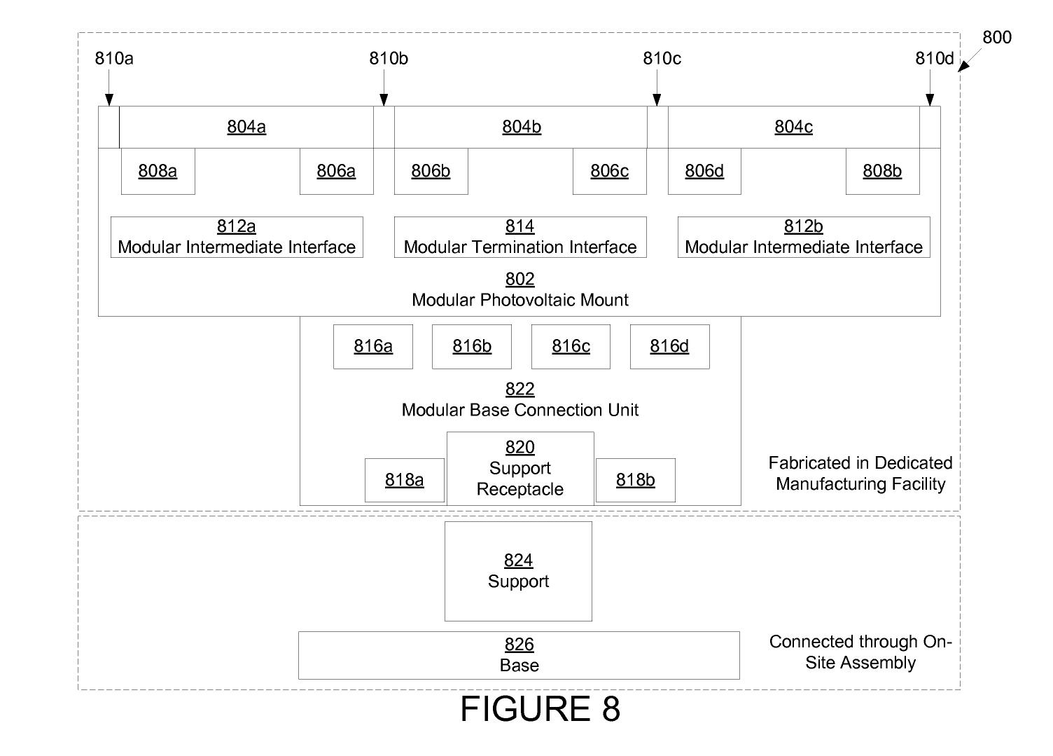

FIG. 8 shows an example of conceptual diagram of a modular solar power generation unit 800. The modular solar power generation unit 800 shows an example of a power generation component that can be fabricated as a single unit away from a power generation site. For instance, the modular solar power generation unit 800 can be fabricated at a dedicated manufacturing facility such as a factory. In some embodiments, the modular solar power generation unit 800 can be internally modular. That is, the modular solar power generation unit 800 can include components that are designed to interconnect with one another during a fabrication process. The modular solar power generation unit 800 can also be externally modular. More specifically, the modular solar power generation unit 800 can be adapted to connect to other components (e.g., support and/or base structures as well as other modular power generation units) in a power generation system. In various embodiments, the modular solar power generation unit 800 can be adapted to be easily assembled into a modular solar unit (e.g. the units 402, 404, and/or 406) in FIG. 4.

Returning to the example of FIG. 8, the modular solar power generation unit 800 can include a modular photovoltaic mount 802 and a modular base connection unit 822. The modular photovoltaic mount 802 and the modular base connection unit 822 can be fabricated in a dedicated manufacturing facility. The modular solar power generation unit 800 can also include a support 824 and a base 826. The support 824 and the base 826 can be coupled to the modular base connection unit 822 on-site.

The modular photovoltaic mount 802 can comprise a structure fabricated to support photovoltaic panels and provide electric current from the photovoltaic panels to other units, such as other modular solar power generation units and/or loads. The dimensions of the modular photovoltaic mount 802 can be chosen for ease of fabrication and efficient shipping to a power generation site. For example, the modular photovoltaic mount 802 can have a length and a width that corresponds to the length and width of a semi-trailer truck. In some embodiments, the modular photovoltaic mount 802 can be fabricated to be transported by a semi-trailer truck having a length of eighty feet and a width of eight and a half feet. In some embodiments, the modular photovoltaic mount 802 can be fabricated to have a length of approximately forty feet and a width of approximately twelve feet. The modular photovoltaic mount 802 can have other lengths and/or widths without departing from the inventive concepts described herein. Thus, the dimensions of the modular photovoltaic mount 802 can be chosen so that the modular photovoltaic mount 802 can be efficiently fabricated in a dedicated manufacturing facility while a power generation structure that incorporates the modular photovoltaic mount 802 can be assembled at a power generation site. Such a modular division of fabrication and assembly allows for creation of solar power generation facilities that are cheaper and easier to assemble but still ensures compliance with building and other regulations.

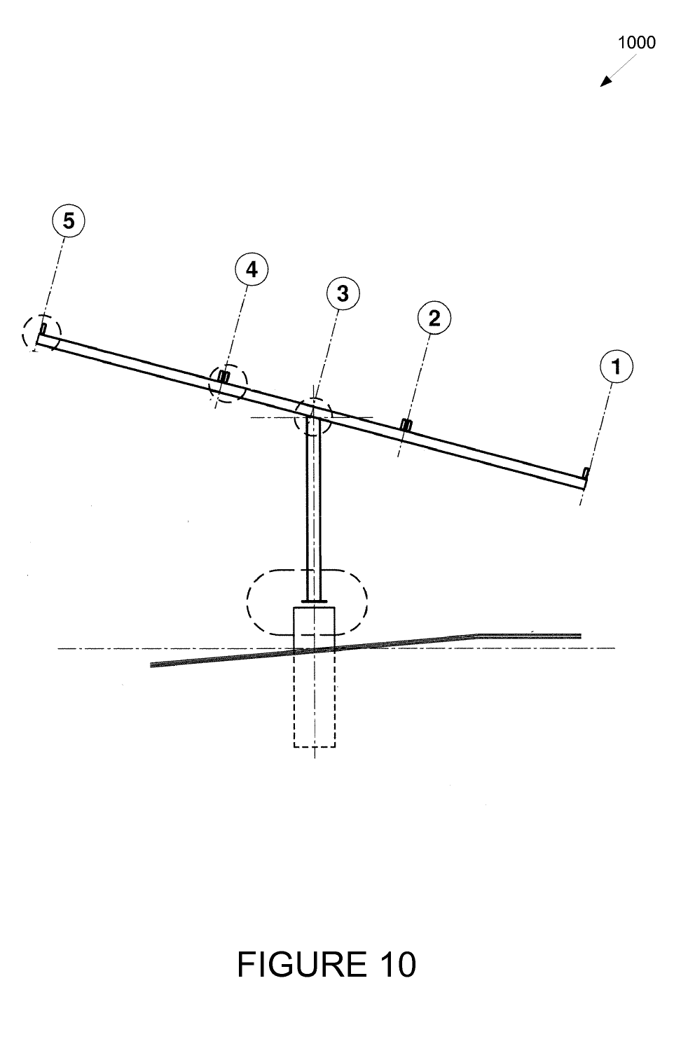

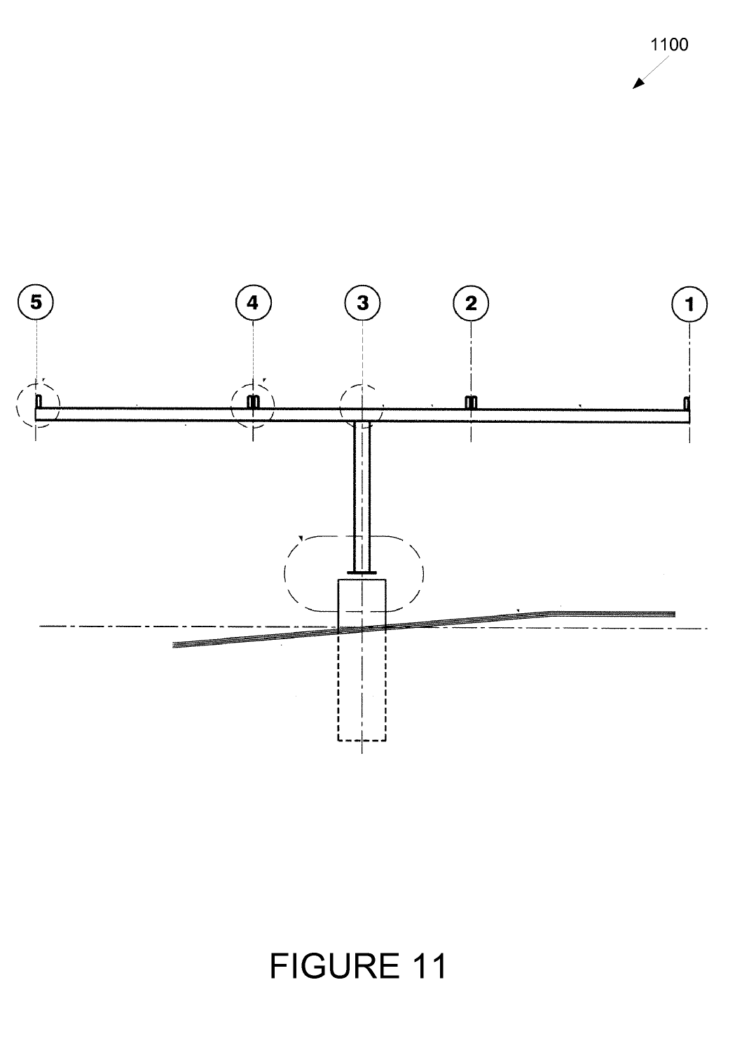

The modular solar power generation unit 800 can be adapted to tilt to optimize receiving photovoltaic rays from the sun. At any given instance, the energy produced by the photovoltaic panels on the modular solar power generation unit 800 will be optimized when the photovoltaic panels are pointed directly at the sun. Typically, this occurs when the panels are tilted perpendicular, or ninety degrees, with respect to the sun's rays at true solar noon. True solar noon is when the sun is at its highest during its daily east-west path across the sky. In some embodiments, the modular solar power generation unit 800 can have a tilt angle. Turning to the example of FIG. 10, the figure shows an example of a side view of a tilted modular solar power generation unit 1000. The tilt can be about fifteen degrees. Turning to the example of FIG. 11, the figure shows an example of a side view of an untilted modular solar power generation unit 1100. The tilt is about zero degrees. It is noted that other tilt angles are possible without deviating from the scope of the inventive concepts discussed herein. Returning to the example of FIG. 8, the tilt angle of the modular solar power generation unit 800 can depend on the direction that the modular solar power generation unit 800 can face. The tilt angle can also vary depending on the season or time of day.

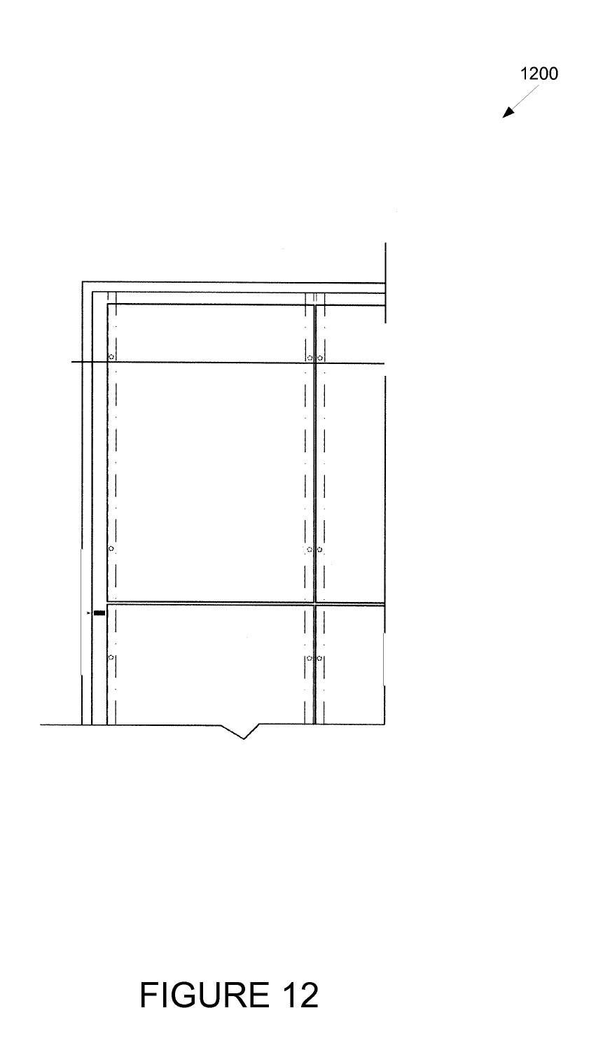

In the example of FIG. 8, the modular photovoltaic mount 802 can include a plurality of photovoltaic panels 804a, 804b, and 804c. Each of the plurality of photovoltaic panels 804a, 804b, and 804c can be adapted to convert solar radiation to electric charge using photovoltaic effects. The plurality of photovoltaic panels 804a, 804b, and 804c can also be adapted to stream the generated charge in the form of direct current. The dimensions of the plurality of the photovoltaic panels 804a, 804b, and 804c can be chosen for ease of integration into the modular photovoltaic mount 802 at a dedicated manufacturing facility. For instance, the dimensions of each of the plurality of photovoltaic panels 804a, 804b, and 804c can be chosen to fill large portions of the upper surface of the modular photovoltaic mount 802. In some embodiments, the dimensions of the photovoltaic panels 804a, 804b, and 804c can be chosen to leave a small gap between photovoltaic panels. The small gap may include a seismic gap. A “seismic gap,” as used herein, is a gap that suffices to separate each of the photovoltaic panels 804a, 804b, and 804c even in the event of a seismic event such as an earthquake. For instance, the seismic gap between photovoltaic panels 804a, 804b, and 804c can still ensure that the photovoltaic panels 804a, 804b, and 804c do not rub against and damage each other during an earthquake. Though FIG. 8 depicts three photovoltaic panels 804a, 804b, and 804c, it is noted that various embodiments can employ more or less photovoltaic panels without departing from the scope of the inventive concepts described herein. Turning the example of FIG. 12, the figure shows a top view of a set of photovoltaic panels 1200 mounted on a modular photovoltaic mount.

Returning to the example of FIG. 8, the modular photovoltaic mount 802 can include a plurality of midsection panel fastening assemblies 806a, 806b, 806c, and 806d. Each of the midsection panel fastening assemblies 806a, 806b, 806c, and 806d can be adapted to allow fastening to the modular photovoltaic mount 802 the portions of the photovoltaic panels 804a, 804b, and 804c that are away from the ends of the modular photovoltaic mount 802 (i.e., the midsection portions of the photovoltaic panels 804a, 804b, and 804c). In some embodiments, the midsection panel fastening assemblies 806a, 806b, 806c, and 806d can include screw assemblies that connect to threads on the bottoms of the photovoltaic panels 804a, 804b, and 804c. The midsection panel fastening assemblies 806a, 806b, 806c, and 806d can also include braces to orthogonally support the bottoms of the photovoltaic panels 804a, 804b, and 804c. In this example, the midsection panel fastening assembly 806a can connect to the side of the photovoltaic panel 804a that is away from the end of the modular photovoltaic mount 802. The midsection panel fastening assemblies 806b and 806c can connect to sides of the photovoltaic panel 804b. Further, the midsection panel fastening assembly 806d can connect to the side of the photovoltaic panel 804c that is away from the end of the modular photovoltaic mount 802.

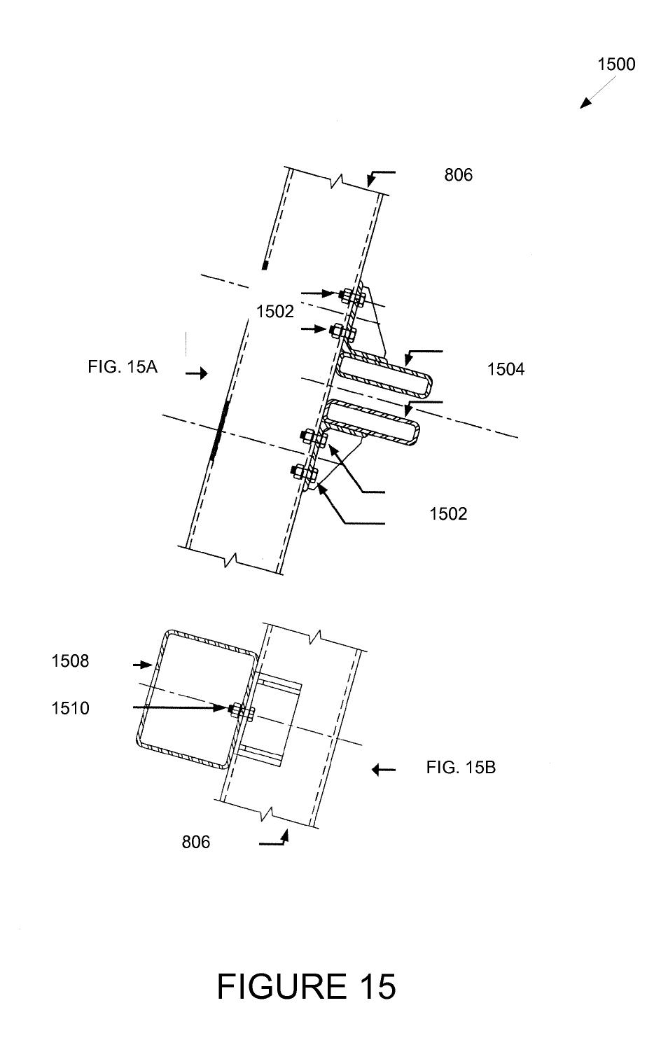

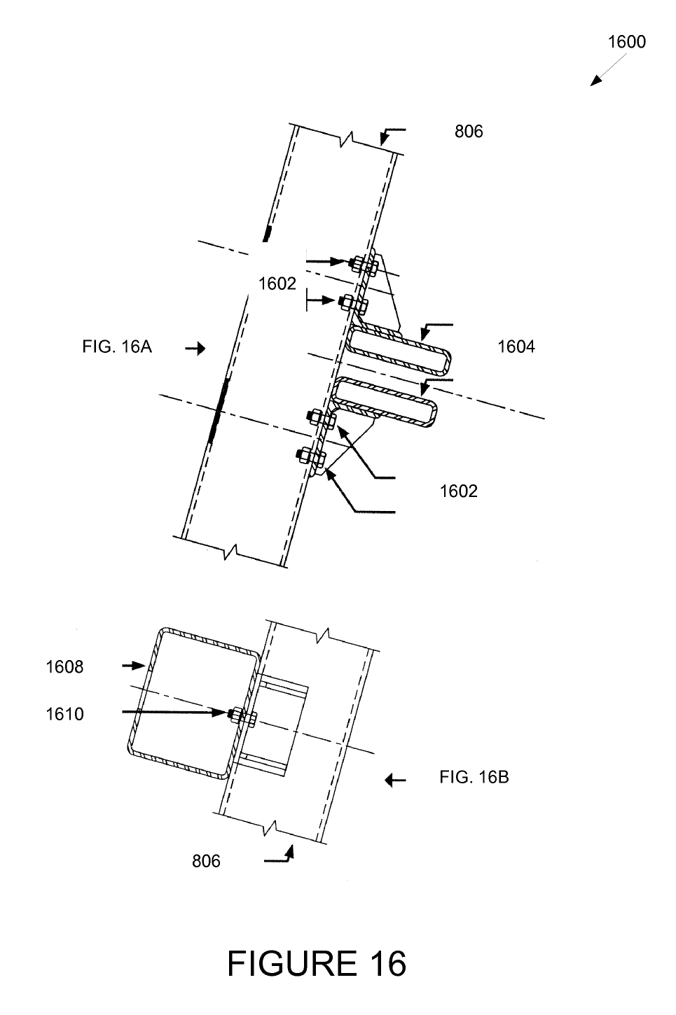

Turning to FIG. 15A, the figure shows an example of a side view of a midsection panel fastening assembly 806. The midsection panel fastening assembly 806 can include screws 1502 and support frames 1504. FIG. 15B shows another example of a side view of a midsection panel fastening assembly. The midsection panel fastening assembly 806 can include screws 1510 and a support frame 1508. FIG. 16A shows yet another example of a side view of a midsection panel fastening assembly 806. The midsection panel fastening assembly 806 can include screws 1602 and support frames 1604. FIG. 16B shows an example of a side view of a midsection panel fastening assembly 806. The midsection panel fastening assembly 806 can include screws 1610 and a support frame 1608.

Returning to the example of FIG. 8, the modular photovoltaic mount 802 can include a plurality of end panel fastening assemblies 808a and 808b. Each of the end panel fastening assemblies 808a and 808b can be adapted to allow fastening to the modular photovoltaic mount 802 the portions of the photovoltaic panels 804a, 804b, and 804c that are adjacent to the ends of the modular photovoltaic mount 802 (i.e., the ends of the photovoltaic panels 804a, 804b, and 804c). The end panel fastening assemblies 808a and 808b can comprise screws and/or braces. In this example, the end panel fastening assembly 808a is coupled to the photovoltaic panel 804a, and the end panel fastening assembly 808b is coupled to the photovoltaic panel 804c.

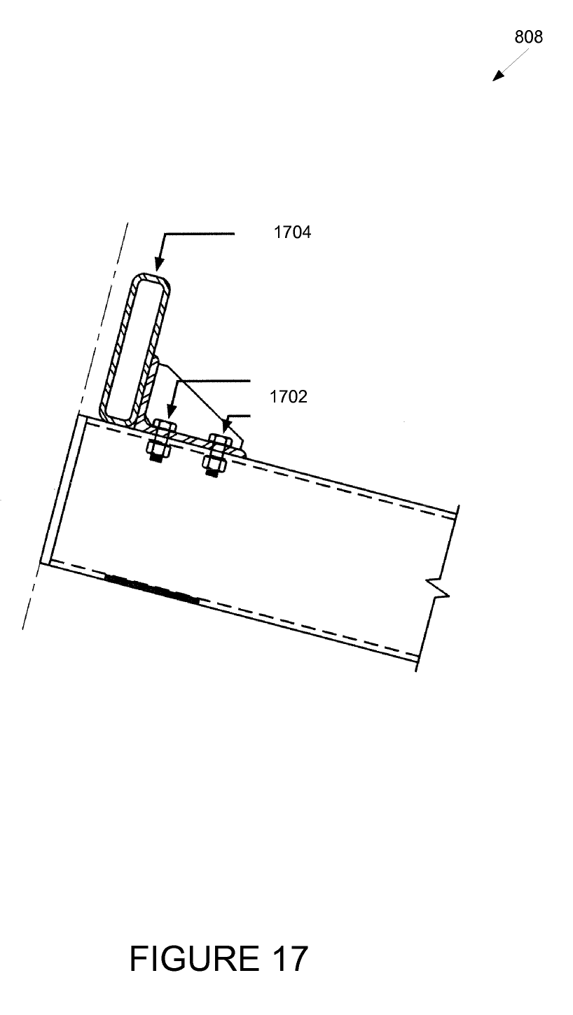

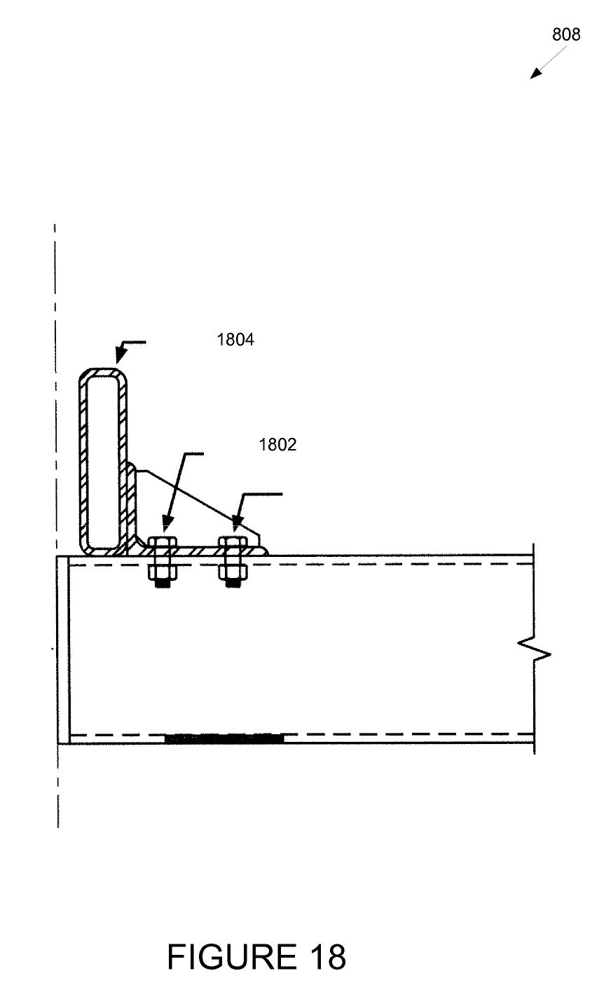

Turning to the example of FIG. 17, the figure shows an example of an end panel fastening assembly 808 in a tilted arrangement. The end panel fastening assembly 808 can include screws 1702 and a support frame 1704. Turning to the example of FIG. 18, the figure shows an example of an end panel fastening assembly 808 in an untilted arrangement. The end panel fastening assembly 808 can include screws 1802 and a support frame 1804.

Returning to the example of FIG. 8, the modular photovoltaic mount 802 can include a plurality of structural framing channels 810a, 810b, 810c, and 810d. Each of the structural framing channels 810a, 810b, 810c, and 810d can include metal framing channels such as strut channels. The structural framing channels 810a, 810b, 810c, and 810d can be adapted to house electrical interconnections from the photovoltaic panels 804a, 804b, and 804c, and electrically couple the photovoltaic panels 804a, 804b, and 804c to other portions of the modular photovoltaic mount 802. For instance, the structural framing channels 810a and 810b can be adapted to house electrical interconnections from the photovoltaic panel 804a, the structural framing channels 810b and 810c can be adapted to house electrical interconnections from the photovoltaic panel 804b, and the structural framing channels 810c and 810d can be adapted to house electrical interconnections from the photovoltaic panel 804c. It is noted that some embodiments employ only structural framing channels 810a and 810d on the sides of the modular photovoltaic mount 802.

The modular photovoltaic mount 802 can include a plurality of modular intermediate interfaces 812a and 812b. The modular intermediate interfaces 812a and 812b can be adapted to interconnect the modular photovoltaic mount 802 to other modular photovoltaic mounts. That is, the modular intermediate interfaces 812a and 812b can be adapted to interconnect with modular intermediate interfaces 812a and 812b and/or termination interfaces on other modular photovoltaic mounts as well as the modular termination interface 814.

The specific configuration of the modular intermediate interfaces 812a and 812b can vary with the position of the modular photovoltaic mount 802 in a composite arrangement of modular photovoltaic mounts. For instance, the modular intermediate interfaces 812a and 812 can be adapted to facilitate positioning of the modular photovoltaic mount 802 as an end piece in a composite arrangement. Such an end piece can be connected to one or more other end pieces or one or more center pieces in the composite arrangement. The modular intermediate interfaces 812a and 812b can be adapted to facilitate positioning of the modular photovoltaic mount 802 as a center piece in a composite arrangement. Such a center piece can be connected to one or more other center pieces or one or more end pieces in the composite arrangement. In some embodiments, one or more of the modular intermediate interfaces 812a and 812b can include male and/or female interfaces that allow interconnection to, respectively, female and/or male interfaces in other modular photovoltaic mounts. In various embodiments, the modular intermediate interfaces 812a and 812b can receive electrical interconnections from one or more of the structural framing channels 810a, 810b, 810c, and 810d. For instance, in the example of FIG. 8, each of the modular intermediate interfaces 812a and 812b can receive electrical interconnections from each of the structural framing channels 810a, 810b, 810c, and 810d. The connection of the structural framing channels 810a, 810b, 810c, and 810d to the modular intermediate interfaces 812a and 812b allows a maker of the modular photovoltaic mount 802 to efficiently connect the photovoltaic panels 804a, 804b, and 804c to other photovoltaic mounts and/or the modular termination interface 814.

The modular photovoltaic mount 802 can include a modular termination interface 814. The termination interface 814 can be adapted to interconnect the modular photovoltaic mount 802 to other modular photovoltaic mounts. As with the modular intermediate interfaces 812a and 812b, the specific configuration of the modular termination interface 814 can vary with the position of the modular photovoltaic mount 802 in a composite arrangement of modular photovoltaic mounts. In the circumstance that the modular photovoltaic mount 802 is being used as part of a termination modular solar unit (see, e.g., FIG. 4), the modular termination interface 814 may receive electrical interconnections from modular intermediate interfaces on other modular photovoltaic mounts, as well as from the modular intermediate interfaces 812a and 812b. If the modular photovoltaic mount 802 is not being used as a part of a termination modular solar unit (see FIG. 4), the modular termination interface 814 can be omitted or rendered inoperative. In the example of FIG. 8, the specific configuration of the termination interface 814 can vary with the position of the modular photovoltaic mount 802 in a composite arrangement of modular photovoltaic mounts. The termination interface 814 can include male and/or female interfaces that allow interconnection to, respectively, female and/or male interfaces in other modular photovoltaic mounts.

The modular base connection unit 822 can comprise a structure fabricated to provide support to the modular photovoltaic mount 802. To this end, the modular base connection unit 822 can serve as a physical interface between the modular photovoltaic mount 802 and a support structure. The modular base connection unit 822 can have size dimensions (e.g., a length and a width) that correspond to the modular photovoltaic mount 802. In some embodiments, the modular base connection unit 822 can have a length and a width that corresponds to the length and width of a semi-trailer truck. That is, the modular base connection unit 822 can be fabricated to be transported by a semi-trailer truck having a length of eighty feet and a width of eight and a half feet. In some embodiments, the modular base connection unit 822 can be fabricated to have a length of approximately forty feet and a width of approximately twelve feet. The modular base connection unit 822 can also have other lengths and/or widths without departing from the inventive concepts described herein. The dimensions of the modular base connection unit 822 can be chosen so that the modular base connection unit 822 can be efficiently fabricated in a dedicated manufacturing facility while a corresponding power generation structure can be assembled at a power generation site.

The modular base connection unit 822 can include modular mount fasteners 816a, 816b, 816c, and 816d, modular support fasteners 818a and 818b, and a support receptacle 820. The modular mount fasteners 816a, 816b, 816c, and 816d can comprise screw assemblies adapted to facilitate coupling of the modular photovoltaic mount 802 to the modular base connection unit 822. Though FIG. 8 shows four modular mount fasteners 816a, 816b, 816c, and 816d, it is noted that more or less modular mount fasteners can be used without departing from the scope of the inventive concepts described herein. The modular support fasteners 818a and 818b can include hole tightener adapted to fasten the support 824 to the modular base connection unit 822 by tightening the hole created by the support receptacle 820. Though FIG. 8 shows two modular support fasteners 818a and 818b, it is noted that more or less modular support fasteners can be used without departing from the scope of the inventive concepts described herein. In this example, the support receptacle 820 can include a hole sized to receive the support 824. In various embodiments, the support receptacle 820 can be adapted to be tightened by the modular support fasteners 818a and 818b.

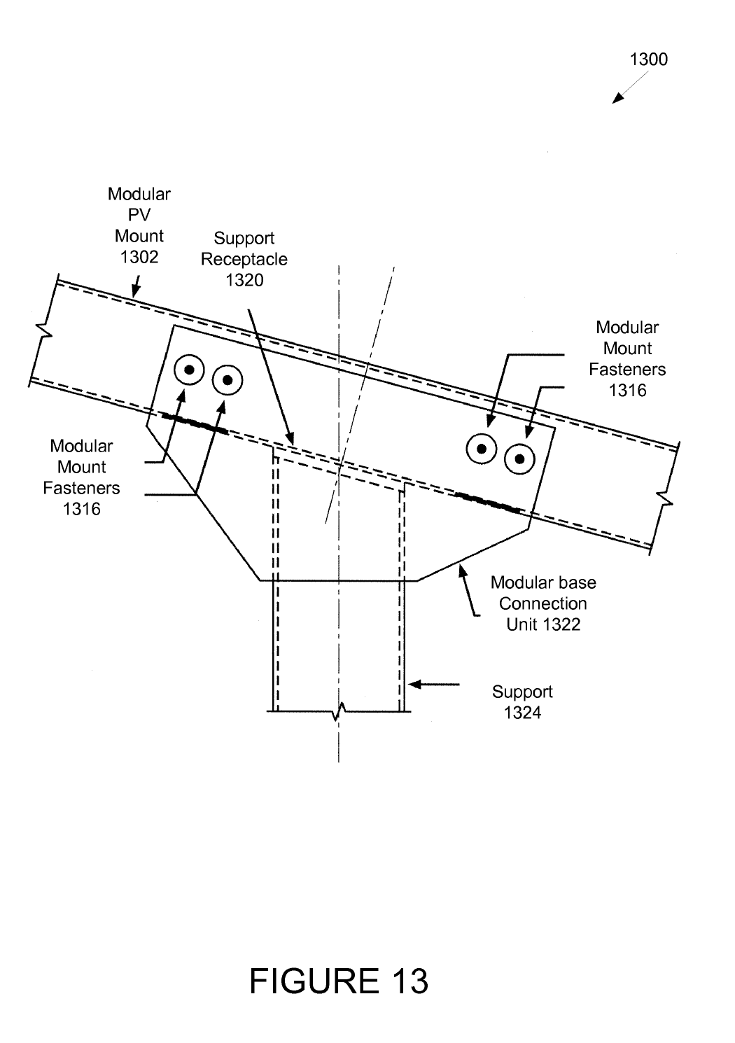

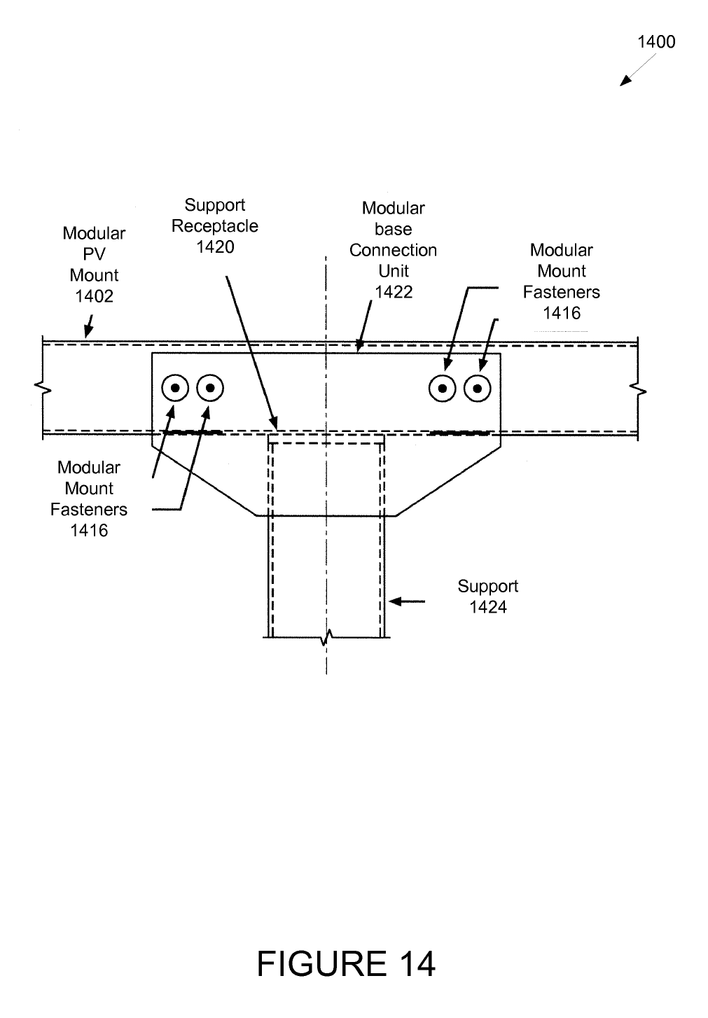

FIGS. 13 and 14 show examples of how a modular base connection unit can be arranged. FIG. 13 shows an example of a side view of a tilted modular solar power generation unit 1300, including a modular base connection unit 1324. In the example of FIG. 13, the tilted modular solar power generation unit 1300 can include a modular photovoltaic mount 1302, modular mount fasteners 1316, a support receptacle 1320, a support 1322, and a modular base connection unit. FIG. 14 shows an example of a side view of an untilted modular solar power generation unit 1400, including a modular base connection unit 1424. In the example of FIG. 14, the untilted modular solar power generation unit 1400 can include a modular photovoltaic mount 1402, modular mount fasteners 1416, a support receptacle 1420, a support 1422, and a modular base connection unit.

Returning to the example of FIG. 8, the support 824 can include a rod or piling that is received by the support receptacle 820. In various embodiments, the support receptacle 820 can be fabricated in dedicated manufacturing facility along with the modular photovoltaic mount 802 and the modular base connection unit 822. In these embodiments, the support 824 can be coupled to the support receptacle 820 during assembly of a power generation center that includes the modular solar power generation unit 800.

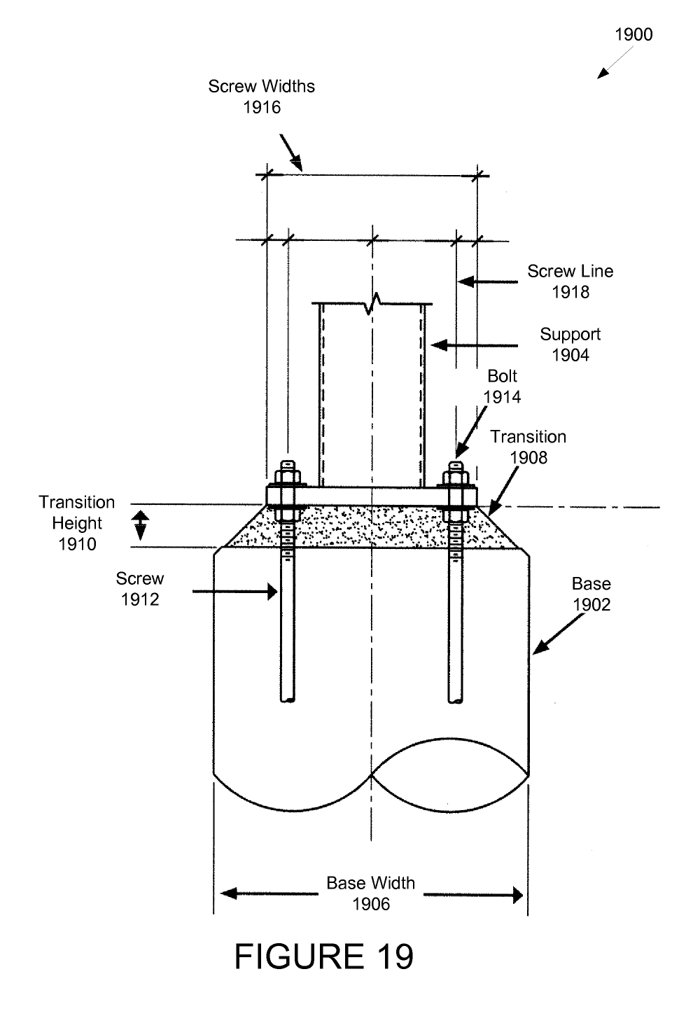

In the example of FIG. 8, the base 826 can include a rigid structure adapted to provide a foundation for the support 824. Turning to FIG. 19, the figure shows an example of a side view of a supportive assembly 1900 of a modular solar power generation unit. In the example of FIG. 19, the supportive assembly 1900 can include a base 1902 and a support 1904. The base 1902 can have a base width 1906 and a transition area 1908. The transition area can have a transition height 1910. A fastening assembly comprising a screw 1912 and a bolt 1914 can couple the support 1904 to the base 1902. The base 1902 can be configured to have screw widths 1916 and a screw line 1918.

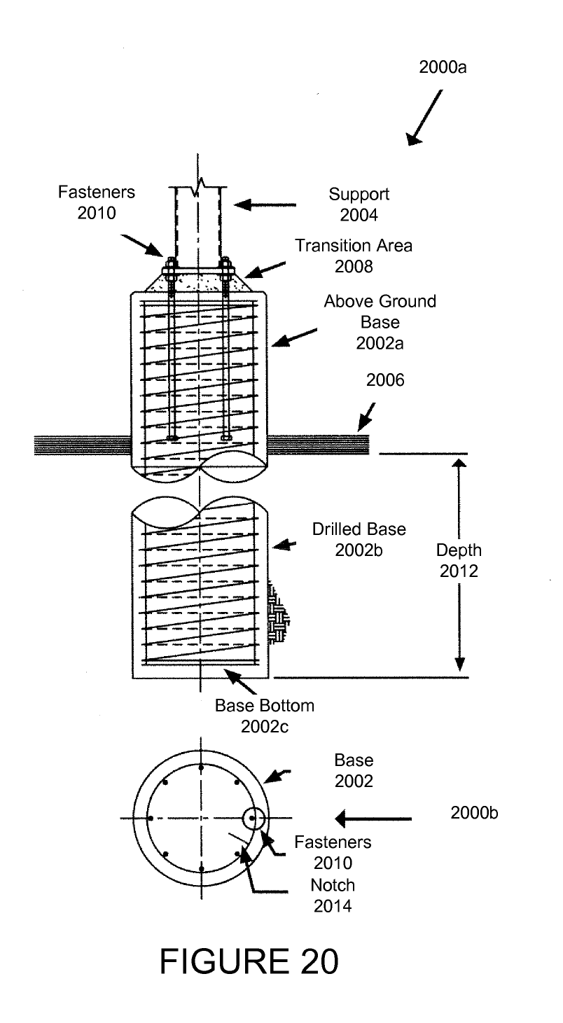

Turning to FIG. 20, the figure shows an example of a side view 2000a and a top view 2000b of a supportive assembly of a modular solar power generation unit. The side view 2000a shows a base 2002 comprising an above-ground portion 2002a, a drilled portion 2002b, and a bottom portion 2000c. The side view 2000a further shows a support 2004, a ground level 2006, and a transition area 2008. The base 2002 is coupled to the support 2004 using fasteners 2010. The base 2002 is drilled a depth 2012 into the ground. In the example of FIG. 20, the top view 2000b shows the base 2002, fasteners 2010, and a notch 2014.

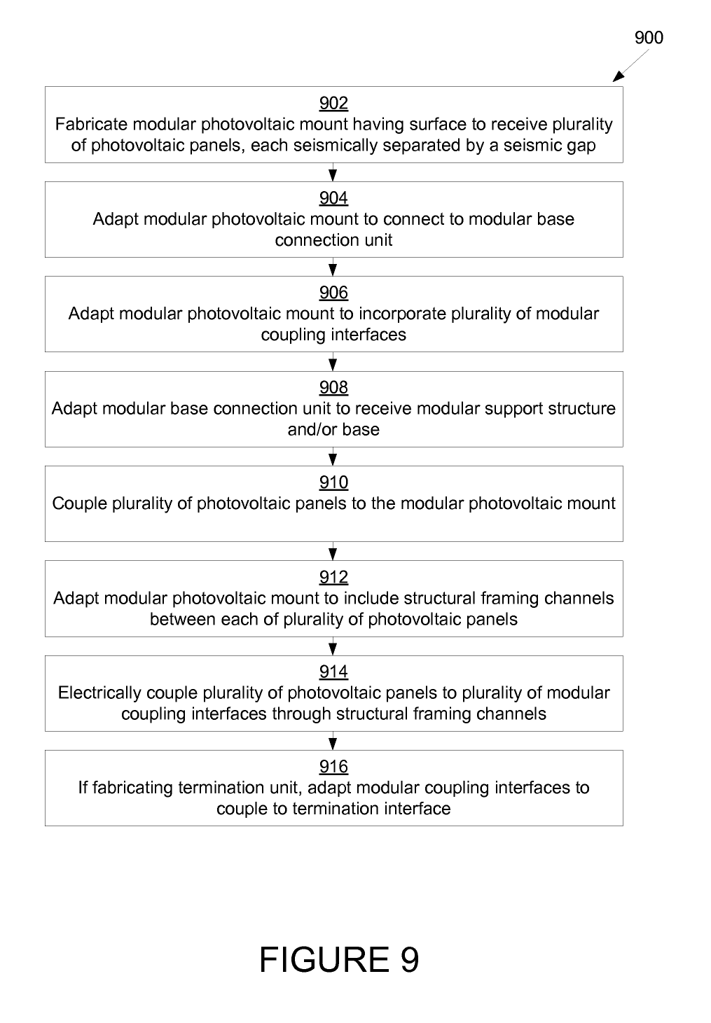

Turning to FIG. 9, the figure shows a flowchart of an example of a method 900 for fabricating modular solar power generation unit. The method 900 is discussed in conjunction with the structures of FIG. 8. The method 900 can contain steps or substeps other than the steps explicitly shown. It can also be possible to practice the inventive concepts of the method 900 without performing all of the illustrated steps.

Step 902 comprises fabricating a modular photovoltaic mount having a surface adapted to receive a plurality of photovoltaic panels, each of the photovoltaic panels seismically separated by a seismic gap. In the example of FIG. 8, there can be fabricated the modular photovoltaic mount 802. The top surface of the modular photovoltaic mount 802 can be adapted to receive the photovoltaic panels 804a, 804b, and 804c. More specifically, the top surface of the modular photovoltaic mount 802 can be prepared for receiving the photovoltaic panels 804a, 804b, and 804c. Preparation steps can include designating which portions of the top surface will receive the photovoltaic panels 804a, 804b, and 804c; creating wires for the photovoltaic panels 804a, 804b, and 804c; and surface preparation steps. Each of the portions of the top surface that are designated to receive the photovoltaic panels 804a, 804b, and 804c can be separated by a seismic gap.

Step 904 comprises adapting the modular photovoltaic mount to connect to a modular base connection unit. In the example of FIG. 8, the bottom surface of the modular photovoltaic mount 802 can be drilled with fastener holes (e.g., screws) that align with one or more of the modular mount fasteners 816a, 816b, 816c, and 816d. In some embodiments, after alignment, the modular base connection unit 822 and the modular photovoltaic mount 802 can be coupled using the modular mount fasteners 816a, 816b, 816c, and 816d.

Step 906 comprises adapting the modular photovoltaic mount to incorporate a plurality of modular coupling interfaces. In the example of FIG. 8, the modular photovoltaic mount 802 can be adapted to include one or more of the modular intermediate interfaces 812a and 812b, and the termination interface 814. As discussed, the dimensions and position of the modular intermediate interfaces 812a and 812b, and the termination interface 814 can depend on the position of the modular solar power generation unit 800 in a composite solar power generating center.

Step 908 comprises adapting the modular base connection unit to receive a modular support structure and/or a base. In the example of FIG. 8, the modular base connection unit 804 can be drilled with a hole corresponding to the support receptacle 820. The modular base connection unit 804 can also incorporate the modular support fasteners 818a and 818b.

Step 910 comprises a coupling the plurality of photovoltaic panels to the modular photovoltaic mount. In the example of FIG. 8, the photovoltaic panels 804a, 804b, and 804c can be coupled to the designated portions of the top surface of the modular photovoltaic mount 802. Electrical interconnections from the photovoltaic panels 804a, 804b, and 804c can be driven through appropriate openings in the top surface of the modular photovoltaic mount 802.

Step 912 comprises adapting the photovoltaic mount to include structural framing channels between each of the plurality of photovoltaic panels. In the example of FIG. 8, there can be incorporated the structural framing channels 810a, 810b, 810c, and 810d.

Step 914 comprises electrically coupling the plurality of photovoltaic panels to the plurality of modular coupling interfaces through the structural framing channels. In the example of FIG. 8, the electrical interconnections (e.g., the wires) from the photovoltaic panels 804a, 804b, and 804c can be driven through the structural framing channels 810a, 810b, 810c, and 810d to the modular intermediate interfaces 812a and 812b.

Step 916 comprises if fabricating a termination unit, adapting the modular coupling interfaces to couple to the termination interface. In the example of FIG. 8, if it is determined that the modular solar power generation unit 800 is to be a termination unit, then one or more of the modular intermediate interface 812a and 812b can be coupled to the modular termination interface 814. After step 914, the method 900 may terminate.

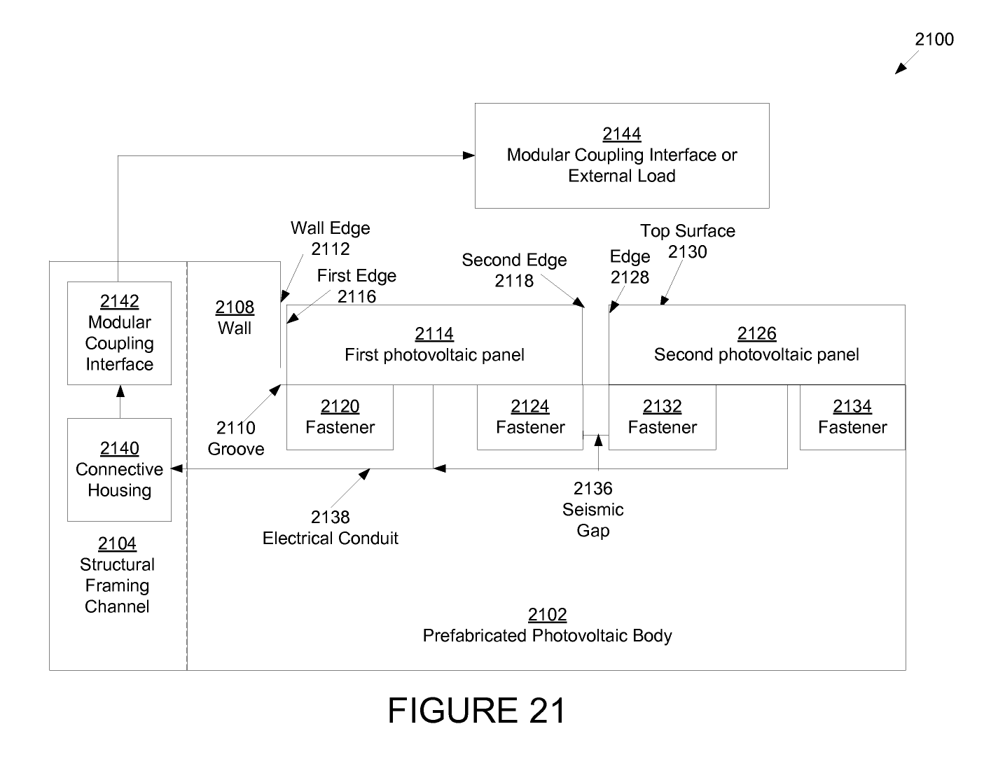

FIG. 21 shows an example of a modular photovoltaic mount 2100. The modular photovoltaic mount 2100 can be fabricated as a single unit away from a power generation site. For instance, the modular photovoltaic mount 2100 can be fabricated at a dedicated manufacturing facility such as a factory. The modular photovoltaic mount 2100 can be can be internally modular as well as externally modular, and may be adaptable to couple to other modular photovoltaic mounts.

In the example of FIG. 21, the modular photovoltaic mount 2100 can include a prefabricated photovoltaic body 2102. The prefabricated photovoltaic body 2102 can be a rigid structure that is capable of supporting photovoltaic panels. In this example, the prefabricated photovoltaic body 2102 can include a wall 2108 and a groove 2110. The wall 2108 can extend orthogonal to the groove 2110. In this example, a wall edge 2112 of the wall 2108 can separate objects located in the groove by a space.

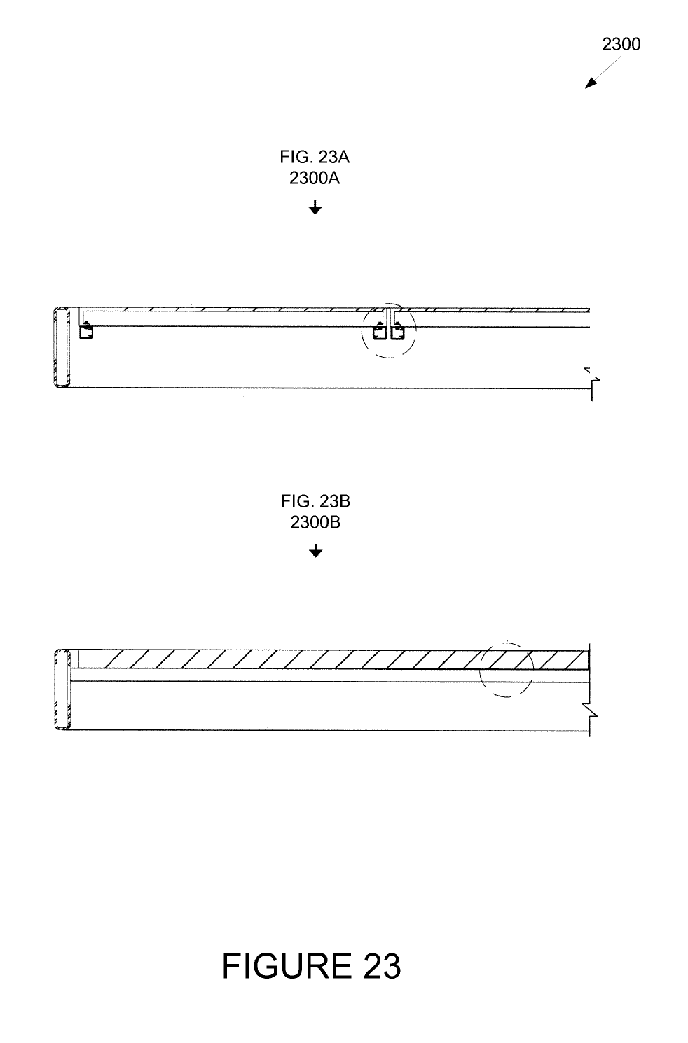

FIGS. 23A and 23B further show further structural details of a modular photovoltaic mount. FIG. 23A shows an example of a side view of a portion of a modular photovoltaic mount 2300A including two photovoltaic panels. FIG. 23B shows an example of a side view of a portion of a modular photovoltaic mount 2300B including one photovoltaic panel.

Returning to the example of FIG. 21, the groove 2110 can include a top surface that is adapted to receive a plurality of photovoltaic panels. For instance, the groove 2110 can be sized to receive a first photovoltaic panel 2114 and a second photovoltaic panel 2126. The groove 2110 can be sized so that the second edge 2118 of the first photovoltaic panel 2114 is separated from the edge 2128 of the second photovoltaic panel 2126 by a seismic gap 2136. The groove 2110 can reside over an electrical conduit 2138 that facilitates an electrical connection between the first photovoltaic panel 2114 and the second photovoltaic panel 2126 to an area outside the prefabricated photovoltaic body 2102.

In this example, an end fastener 2120 and a midsection fastener 2124 can couple the first photovoltaic panel 2114 to the prefabricated photovoltaic body 2102. Midsection fasteners 2132 and 2134 can couple the second photovoltaic panel 2126 to the prefabricated photovoltaic body 2102. The top surfaces 2130 of the first photovoltaic panel 2114 and the second photovoltaic panel 2126 may or may not be below the top surface of the wall 2108.

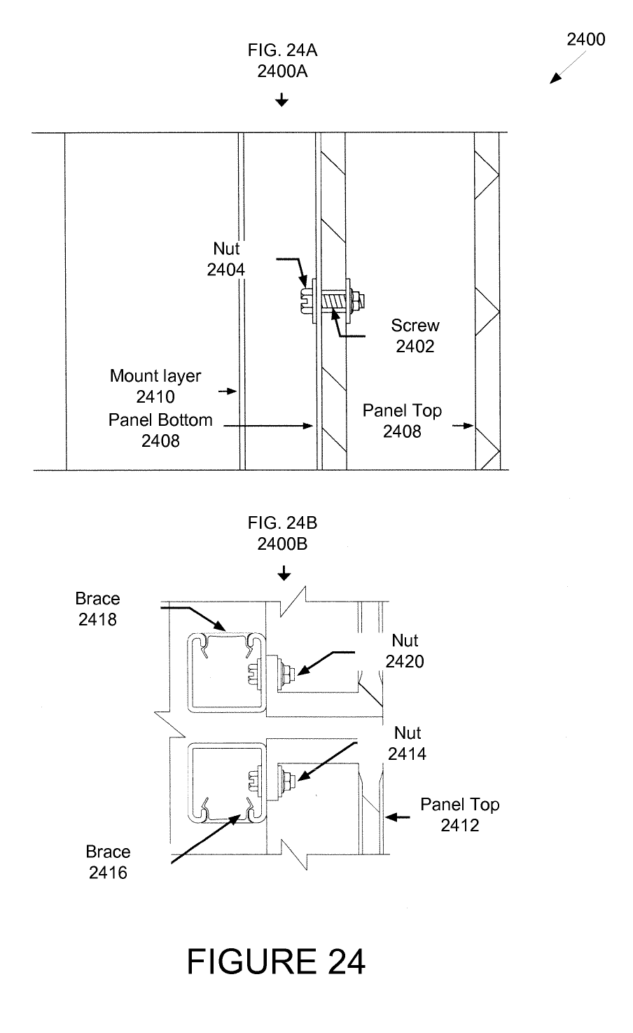

FIGS. 24A and 24B show further mechanical details of an end fastener and a midsection fastener. FIG. 24A shows an example of a modular midsection fastener 2400A. In the example of FIG. 24A, the modular midsection fastener 2400A can include a screw 2402 and a nut 2404. The screw 2402 and the nut 2404 couple a panel bottom 2408 to a mount layer 2410. The modular midsection fastener 2400A can reside near a panel top 2410. FIG. 24B shows an example of a modular end fastener 2400B. In the example of FIG. 24B, the modular end fastener 2400B can include a nut 2414 coupled to a brace 2416 and a nut 2420 coupled to a brace 2418. The modular end fastener 2400B can reside near a panel top 2412. It is noted that FIGS. 24A and 24B are oriented with the top surfaces (i.e., the panel tops 2408 and 2412 respectively) being on the right hand side. Those of ordinary skill in the art will appreciate that other orientations are possible.

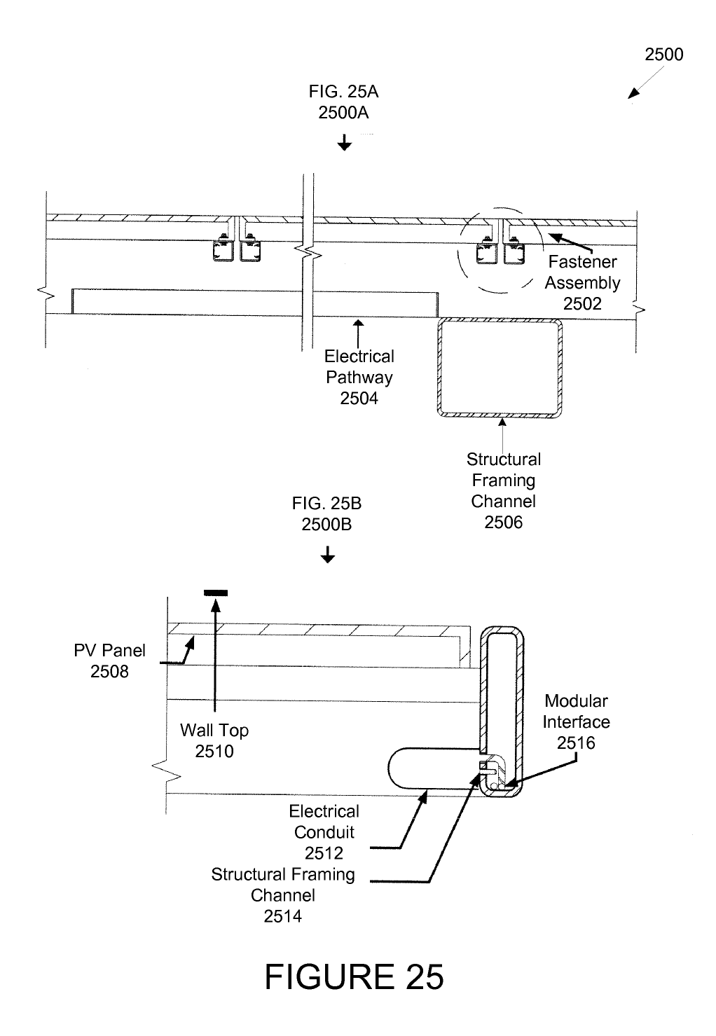

FIGS. 25A and 25B show further mechanical details of portions of modular photovoltaic mounts. FIG. 25A shows an example of a portion of a modular photovoltaic mount 2500A near an underlying structural framing channel 2506. In the example of FIG. 25A, the modular photovoltaic mount 2500A can include a fastener assembly 2502 and an electrical pathway 2504. The modular photovoltaic mount 2500A can also include an underlying structural framing channel 2506. FIG. 25B shows an example of a portion of a modular photovoltaic mount 2500B near an adjacent structural framing channel 2516. In the example of FIG. 25B, the modular photovoltaic mount 2500B can include a photovoltaic panel 2508, a boundary of a top wall edge 2510, an electrical conduit 2512, a structural framing channel 2514, and an adjacent structural framing channel 2516.

Returning to the example of FIG. 21, the modular photovoltaic mount 2100 can include a structural framing channel 2104. The structural framing channel 2104 can include a connective housing 2140 and a modular coupling interface 2142. The connective housing 2140 can be coupled to the electrical conduit 2138, and the modular coupling interface 2142 can be coupled to the connective housing 2140. The modular coupling interface 2142 can be coupled to another modular coupling interface or external load 2144.

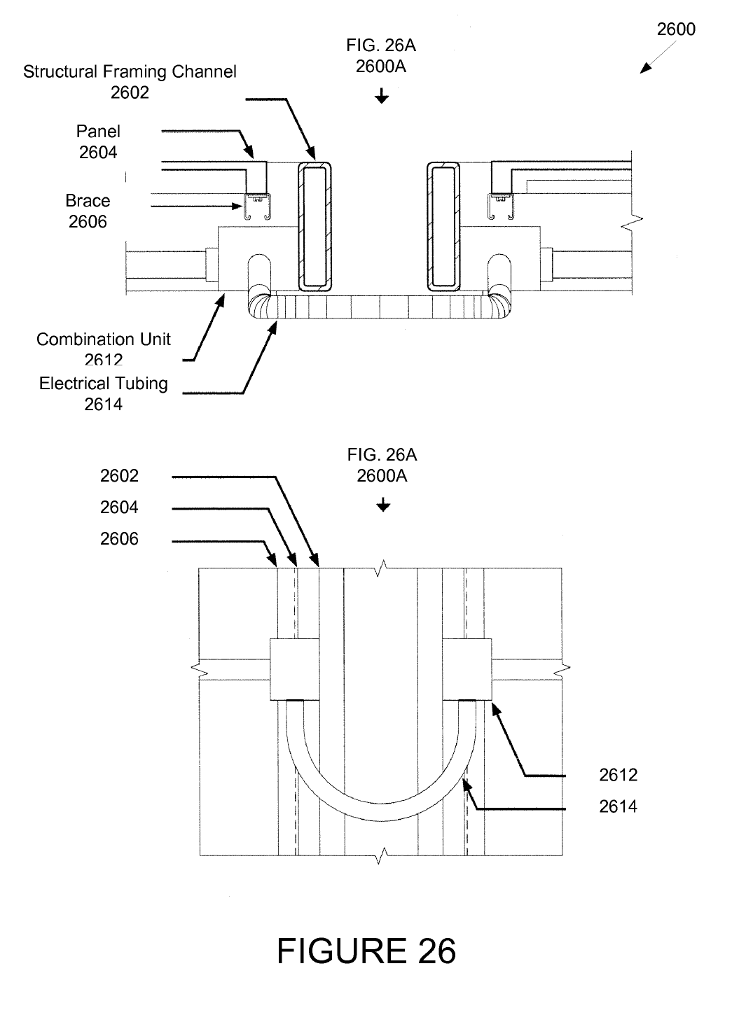

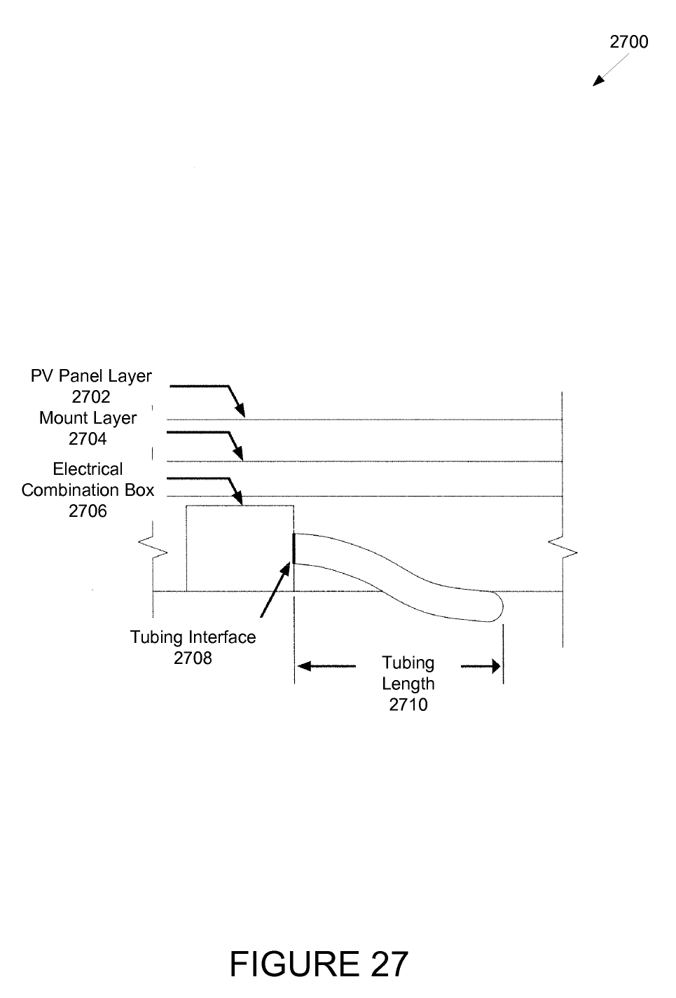

FIGS. 26A and 26B show structural details of portions of a modular coupling interfaces. FIG. 26A shows an example of a side view of a portion of a modular coupling interface 2600A. In the example of FIG. 26A, the modular coupling interface 2600A can include a structural framing channel 2602, a panel 2604 (e.g., a photovoltaic panel), a brace 2606, a combination unit 2612, and electrical tubing 2614. FIG. 26B shows an example of a top view of a portion of a modular coupling interface 2600B. In the example of FIG. 26A, the modular coupling interface 2600B can include a structural framing channel 2602, a panel 2604 (e.g., a photovoltaic panel), a brace 2606, a combination unit 2612, and electrical tubing 2614. FIG. 27 shows an example of a portion of a modular coupling interface 2700. In the example of FIG. 27, the modular coupling interface 2700 can include a photovoltaic panel layer 2702, a mount layer 2704, an electrical combination box 2706, a tubing interface 2708, and a tubing length 2710.

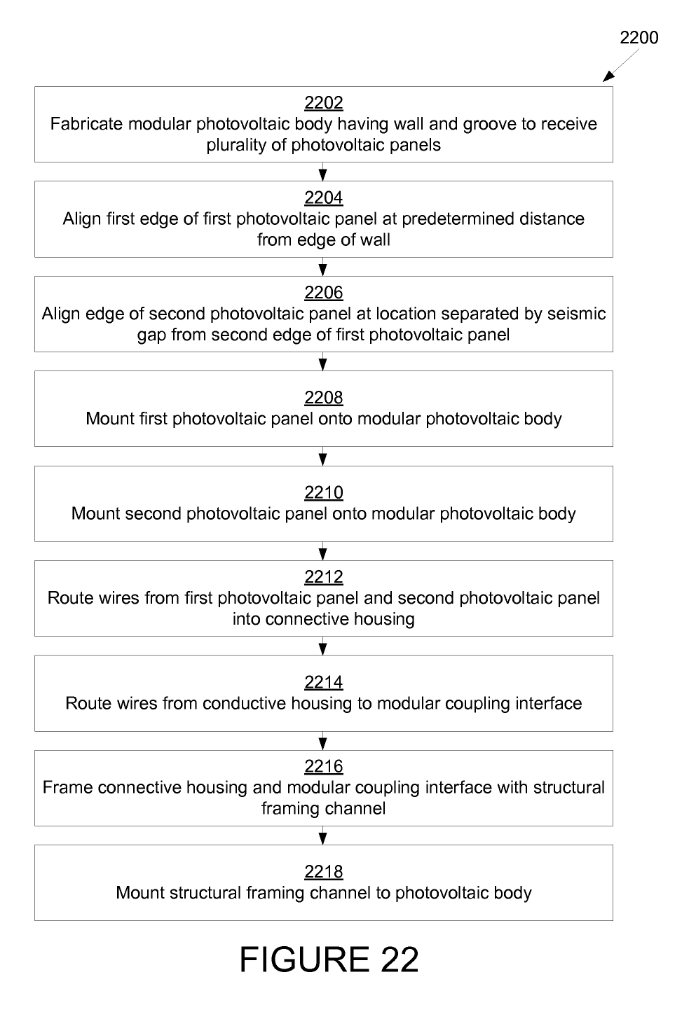

FIG. 22 shows a flowchart of an example of a method 2200 for fabricating a modular photovoltaic mount. The method 2200 is discussed in conjunction with the structures of FIG. 21. The method 2200 can contain steps or substeps other than the steps explicitly shown. It can also be possible to practice the inventive concepts of the method 2200 without performing all of the illustrated steps.

Step 2202 comprises fabricating a prefabricated photovoltaic body having a wall and a groove to receive a plurality of photovoltaic panels. In the example of FIG. 21, there can be fabricated the prefabricated photovoltaic body 2102. The prefabricated photovoltaic body 2102 can have a wall 2108 and a groove 2110. The groove 2110 can receive the first photovoltaic panel 2114 and the second photovoltaic panel 2126.

Step 2204 comprises aligning a first edge of the first photovoltaic panel at a predetermined distance from the edge of the wall. In the example of FIG. 21, there can be aligned the first edge 2116 of the first photovoltaic panel 2114 at a predetermined distance from the wall edge 2112. The predetermined distance can be selected to maximize structural integrity during seismic events.

Step 2206 comprises aligning an edge of the second photovoltaic panel at a location separated by a seismic gap from a second edge of the first photovoltaic panel. In the example of FIG. 21, there can be aligned the edge 2128 of the second photovoltaic panel 2126 at a location separated by a seismic gap 2136 from a second edge 2118 of the first photovoltaic panel 2114.

Step 2208 comprises mounting the first photovoltaic panel onto the prefabricated photovoltaic body. In the example of FIG. 21, there can be mounted the first photovoltaic panel 2114 onto the prefabricated photovoltaic body 2102. Step 2210 comprises mounting the second photovoltaic panel onto the prefabricated photovoltaic body. In the example of FIG. 21, there can be mounted the second photovoltaic panel 2126 onto the prefabricated photovoltaic body 2102.

Step 2212 comprises routing wires from the first photovoltaic panel and the second photovoltaic panels into the connective housing. In the example of FIG. 21, there can be routed wires from the first photovoltaic panel 2114 and the second photovoltaic panel 2126 into the connective housing 2140. Step 2214 comprises routing wires from the connective housing to a modular coupling interface. In the example of FIG. 21, there can be routed wires from the connective housing 2140 to the modular coupling interface 2142. Step 2216 comprises framing the connective housing and the modular coupling interface with a structural framing channel. In the example of FIG. 21, the structural framing channel 2104 can be used to frame the connective housing 2140 and the modular coupling interface 2142.

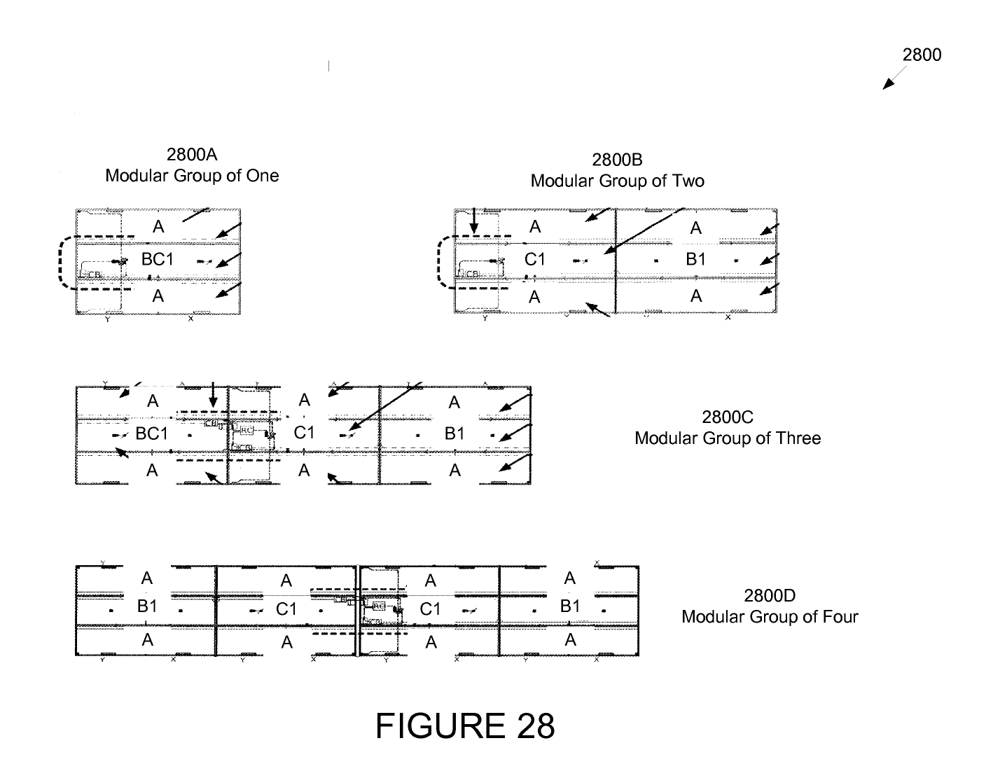

Having discussed, in various levels of generality, structures and methods relating to a power generation environment, a group of modular solar power generation units, a modular solar power generation unit, and a modular photovoltaic mount, the discussion will now proceed to FIGS. 28-38, which illustrates examples of specific implementations ranging from one modular solar power generation unit to ten modular solar power generation units that can utilize the foregoing structures and/or methods.

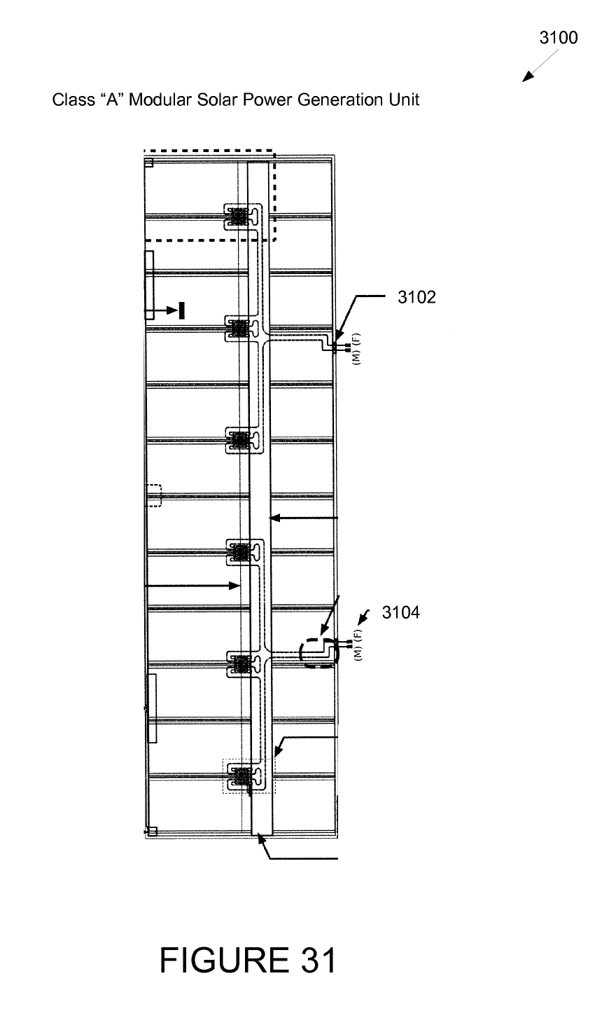

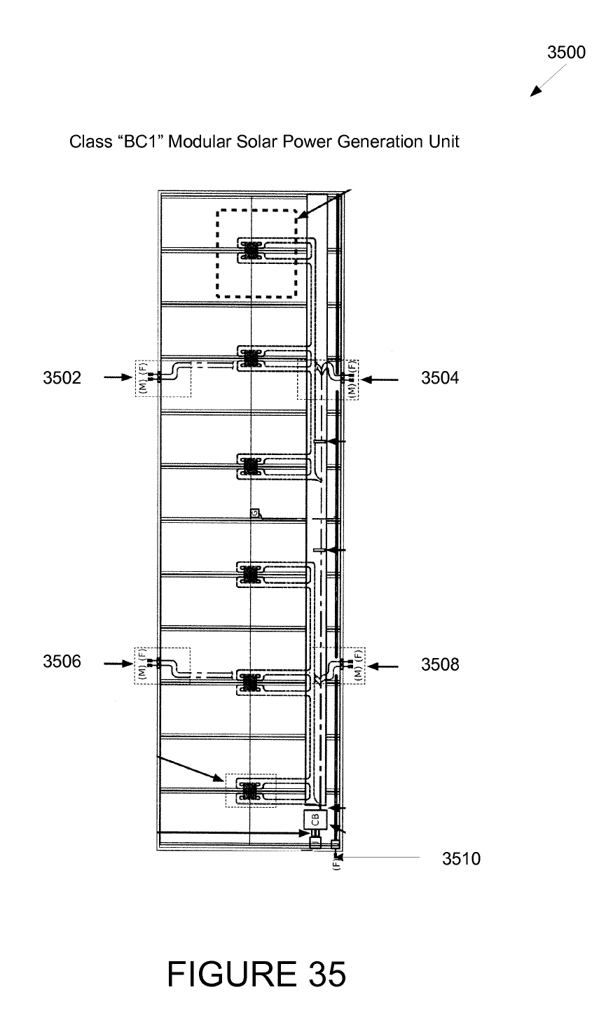

FIG. 28 shows examples of groups 2800 of modular solar power generation units. In the example of FIG. 28, the groups 2800 can include a group 2800A of one modular solar power generation unit. In this example, the group 2800A can include a column of modular solar power generation units. The column comprises a Class “A” modular solar power generation unit, a Class “BC1” modular solar power generation unit, and another Class “A” modular solar power generation unit. FIG. 31 shows an example of a Class “A” modular solar power generation unit and FIG. 35 shows an example of a Class “BC1” modular solar power generation unit.

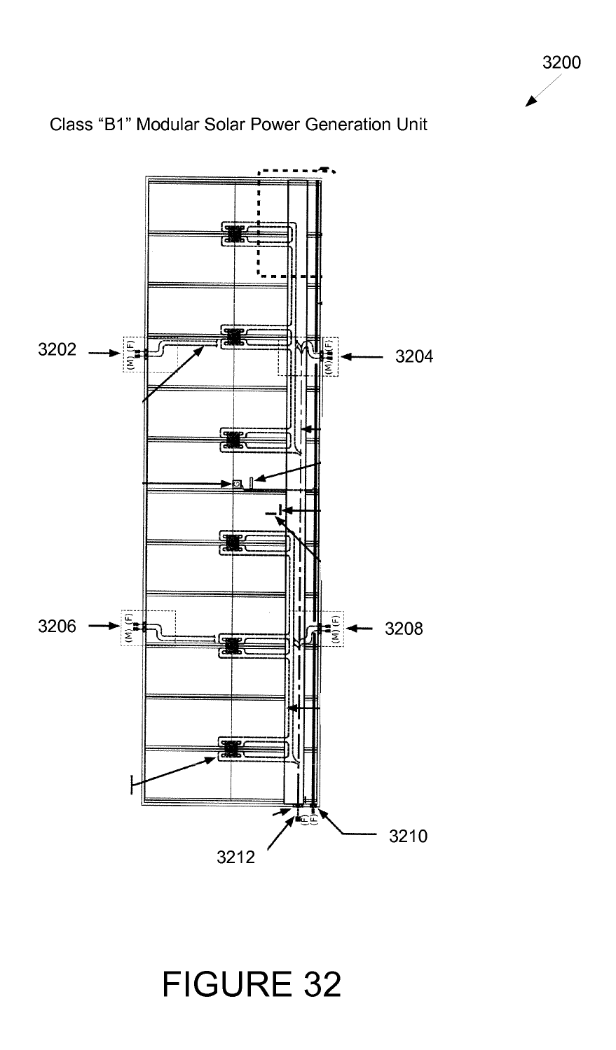

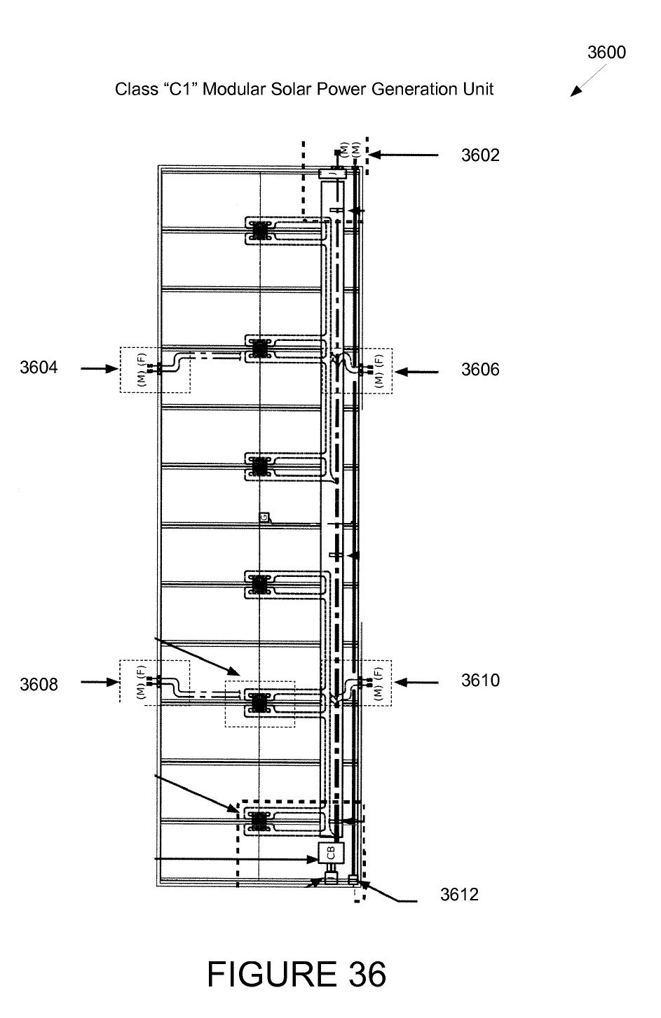

In the example of FIG. 28, the groups 2800 can include a group 2800B of two modular solar power generation units. In this example, the group 2800B can include two columns of modular solar power generation units. A first column comprises a Class “A” modular solar power generation unit, a Class “C1” modular solar power generation unit, and another Class “A” modular solar power generation unit. A second column comprises a Class “A” modular solar power generation unit, a Class “B1” modular solar power generation unit, and another Class “A” modular solar power generation unit. FIG. 31 shows an example of a Class “A” modular solar power generation unit, FIG. 32 shows an example of a Class “B1” modular solar power generation unit, and FIG. 36 shows an example of a Class “C1” modular solar power generation unit.

In the example of FIG. 28, the groups 2800 can include a group 2800C of three modular solar power generation units. In this example, the group 2800C can include three columns of modular solar power generation units. A first column comprises a Class “A” modular solar power generation unit, a Class “BC1” modular solar power generation unit, and another Class “A” modular solar power generation unit. A second column comprises a Class “A” modular solar power generation unit, a Class “C1” modular solar power generation unit, and another Class “A” modular solar power generation unit. A third column comprises a Class “A” modular solar power generation unit, a Class “B1” modular solar power generation unit, and another Class “A” modular solar power generation unit. FIG. 31 shows an example of a Class “A” modular solar power generation unit, FIG. 32 shows an example of a Class “B1” modular solar power generation unit, FIG. 35 shows an example of a Class “BC1” modular solar power generation unit, and FIG. 36 shows an example of a Class “C1” modular solar power generation unit.

In the example of FIG. 28, the groups 2800 can include a group 2800D of four modular solar power generation units. In this example, the group 2800D can include four columns of modular solar power generation units. A first column comprises a Class “A” modular solar power generation unit, a Class “B1” modular solar power generation unit, and another Class “A” modular solar power generation unit. A second column comprises a Class “A” modular solar power generation unit, a Class “C1” modular solar power generation unit, and another Class “A” modular solar power generation unit. A third column comprises a Class “A” modular solar power generation unit, a Class “C1” modular solar power generation unit, and another Class “A” modular solar power generation unit. A fourth column comprises a Class “A” modular solar power generation unit, a Class “B1” modular solar power generation unit, and another Class “A” modular solar power generation unit. FIG. 31 shows an example of a Class “A” modular solar power generation unit, FIG. 32 shows an example of a Class “B1” modular solar power generation unit, and FIG. 36 shows an example of a Class “C1” modular solar power generation unit.

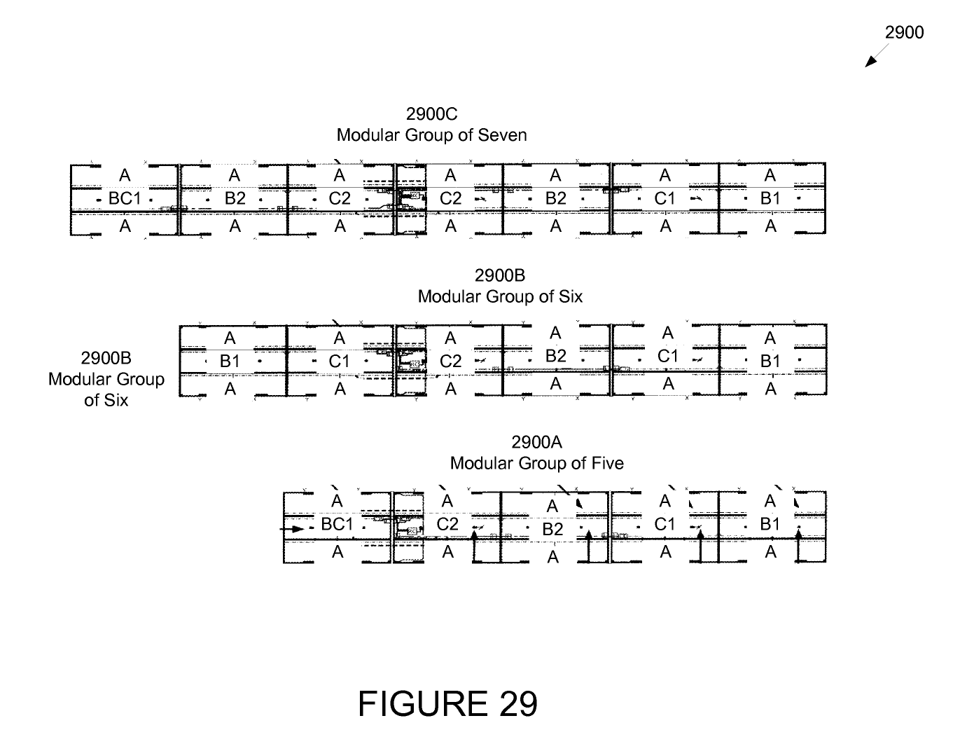

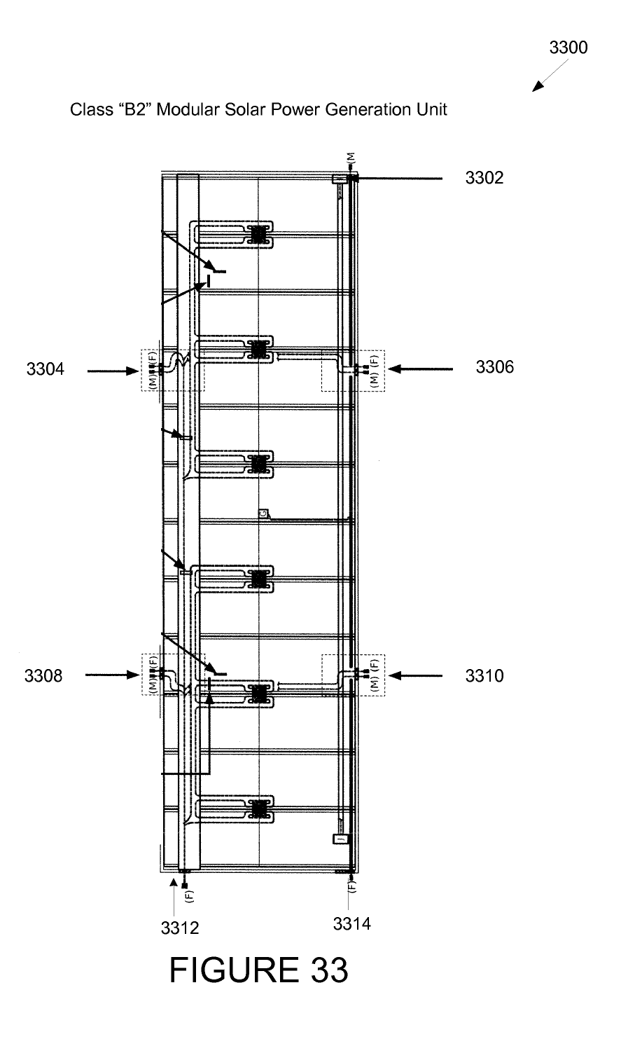

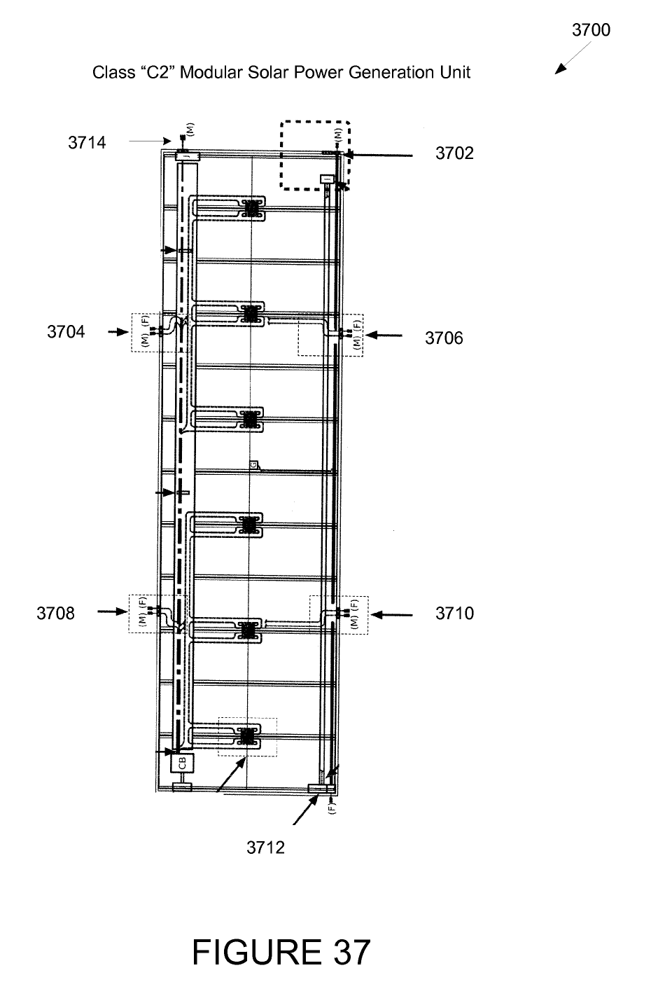

FIG. 29 shows examples of groups 2900 of modular solar power generation units. In the example of FIG. 29, the groups 2900 can include a group 2900A of five modular solar power generation units. In this example, the group 2900A can include five columns of modular solar power generation units. A first column comprises a Class “A” modular solar power generation unit, a Class “BC1” modular solar power generation unit, and another Class “A” modular solar power generation unit. A second column comprises a Class “A” modular solar power generation unit, a Class “C2” modular solar power generation unit, and another Class “A” modular solar power generation unit. A third column comprises a Class “A” modular solar power generation unit, a Class “B2” modular solar power generation unit, and another Class “A” modular solar power generation unit. A fourth column comprises a Class “A” modular solar power generation unit, a Class “C1” modular solar power generation unit, and another Class “A” modular solar power generation unit. A fifth column comprises a Class “A” modular solar power generation unit, a Class “B1” modular solar power generation unit, and another Class “A” modular solar power generation unit. FIG. 31 shows an example of a Class “A” modular solar power generation unit, FIG. 35 shows an example of a Class “BC1” modular solar power generation unit, FIG. 37 shows an example of a Class “C2” modular solar power generation unit, FIG. 33 shows an example of a Class “B2” modular solar power unit, FIG. 36 shows an example of a Class “C1” modular solar power generation unit, and FIG. 32 shows an example of a Class “B1” modular solar power generation unit.

In the example of FIG. 29, the groups 2900 can include a group 2900B of six modular solar power generation units. In this example, the group 2900B can include six columns of modular solar power generation units. A first column comprises a Class “A” modular solar power generation unit, a Class “B1” modular solar power generation unit, and another Class “A” modular solar power generation unit. A second column comprises a Class “A” modular solar power generation unit, a Class “C1” modular solar power generation unit, and another Class “A” modular solar power generation unit. A third column comprises a Class “A” modular solar power generation unit, a Class “C2” modular solar power generation unit, and another Class “A” modular solar power generation unit. A fourth column comprises a Class “A” modular solar power generation unit, a Class “B2” modular solar power generation unit, and another Class “A” modular solar power generation unit. A fifth column comprises a Class “A” modular solar power generation unit, a Class “C1” modular solar power generation unit, and another Class “A” modular solar power generation unit. A sixth column comprises a Class “A” modular solar power generation unit, a Class “B1” modular solar power generation unit, and another Class “A” modular solar power generation unit. FIG. 31 shows an example of a Class “A” modular solar power generation unit, FIG. 32 shows an example of a Class “B1” modular solar power generation unit, FIG. 36 shows an example of a Class “C1” modular solar power generation unit, FIG. 37 shows an example of a Class “C2” modular solar power generation unit, and FIG. 33 shows an example of a Class “B2” modular solar power generation unit.

In the example of FIG. 29, the groups 2900 can include a group 2900C of seven modular solar power generation units. In this example, the group 2900C can include seven columns of modular solar power generation units. A first column comprises a Class “A” modular solar power generation unit, a Class “BC1” modular solar power generation unit, and another Class “A” modular solar power generation unit. A second column comprises a Class “A” modular solar power generation unit, a Class “B2” modular solar power generation unit, and another Class “A” modular solar power generation unit. A third column comprises a Class “A” modular solar power generation unit, a Class “C2” modular solar power generation unit, and another Class “A” modular solar power generation unit. A fourth column comprises a Class “A” modular solar power generation unit, a Class “C2” modular solar power generation unit, and another Class “A” modular solar power generation unit. A fifth column comprises a Class “A” modular solar power generation unit, a Class “B2” modular solar power generation unit, and another Class “A” modular solar power generation unit. A sixth column comprises a Class “A” modular solar power generation unit, a Class “C1” modular solar power generation unit, and another Class “A” modular solar power generation unit. A seventh column comprises a Class “A” modular solar power generation unit, a Class “B1” modular solar power generation unit, and another Class “A” modular solar power generation unit. FIG. 35 shows an example of a Class “BC1” modular solar power generation unit, FIG. 31 shows an example of a Class “A” modular solar power generation unit, FIG. 32 shows an example of a Class “B1” modular solar power generation unit, FIG. 36 shows an example of a Class “C1” modular solar power generation unit, FIG. 37 shows an example of a Class “C2” modular solar power generation unit, and FIG. 33 shows an example of a Class “B2” modular solar power generation unit.

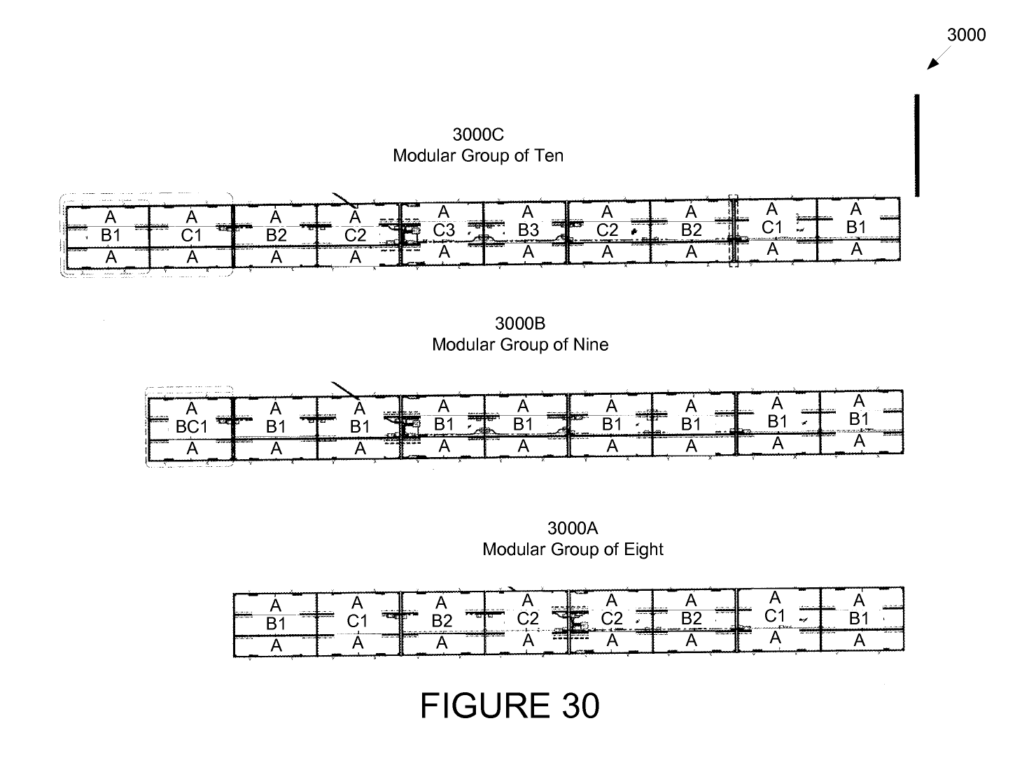

FIG. 30 shows examples of groups 3000 of modular solar power generation units. In the example of FIG. 30, the groups 3000 can include a group 3000A of eight modular solar power generation units. In this example, the group 3000A can include eight columns of modular solar power generation units. A first column comprises a Class “A” modular solar power generation unit, a Class “B1” modular solar power generation unit, and another Class “A” modular solar power generation unit. A second column comprises a Class “A” modular solar power generation unit, a Class “C1” modular solar power generation unit, and another Class “A” modular solar power generation unit. A third column comprises a Class “A” modular solar power generation unit, a Class “B2” modular solar power generation unit, and another Class “A” modular solar power generation unit. A fourth column comprises a Class “A” modular solar power generation unit, a Class “C2” modular solar power generation unit, and another Class “A” modular solar power generation unit. A fifth column comprises a Class “A” modular solar power generation unit, a Class “C2” modular solar power generation unit, and another Class “A” modular solar power generation unit. A sixth column comprises a Class “A” modular solar power generation unit, a Class “B2” modular solar power generation unit, and another Class “A” modular solar power generation unit. A seventh column comprises a Class “A” modular solar power generation unit, a Class “C1” modular solar power generation unit, and another Class “A” modular solar power generation unit. An eighth column comprises a Class “A” modular solar power generation unit, a Class “B1” modular solar power generation unit, and another Class “A” modular solar power generation unit. FIG. 31 shows an example of a Class “A” modular solar power generation unit, FIG. 32 shows an example of a Class “B1” modular solar power generation unit, FIG. 33 shows an example of a Class “B2” modular solar power generation unit, FIG. 36 shows an example of a Class “C1” modular solar power generation unit, and FIG. 37 shows an example of a Class “C2” modular solar power generation unit.

In the example of FIG. 30, the groups 3000 can include a group 3000B of nine modular solar power generation units. In this example, the group 3000B can include nine columns of modular solar power generation units. A first column comprises a Class “A” modular solar power generation unit, a Class “BC1” modular solar power generation unit, and another Class “A” modular solar power generation unit. Second through ninth columns comprises a Class “A” modular solar power generation unit, a Class “B1” modular solar power generation unit, and another Class “A” modular solar power generation unit. FIG. 31 shows an example of a Class “A” modular solar power generation unit, FIG. 35 shows an example of a Class “BC1” modular solar power generation unit, and FIG. 32 shows an example of a Class “B1” modular solar power generation unit.

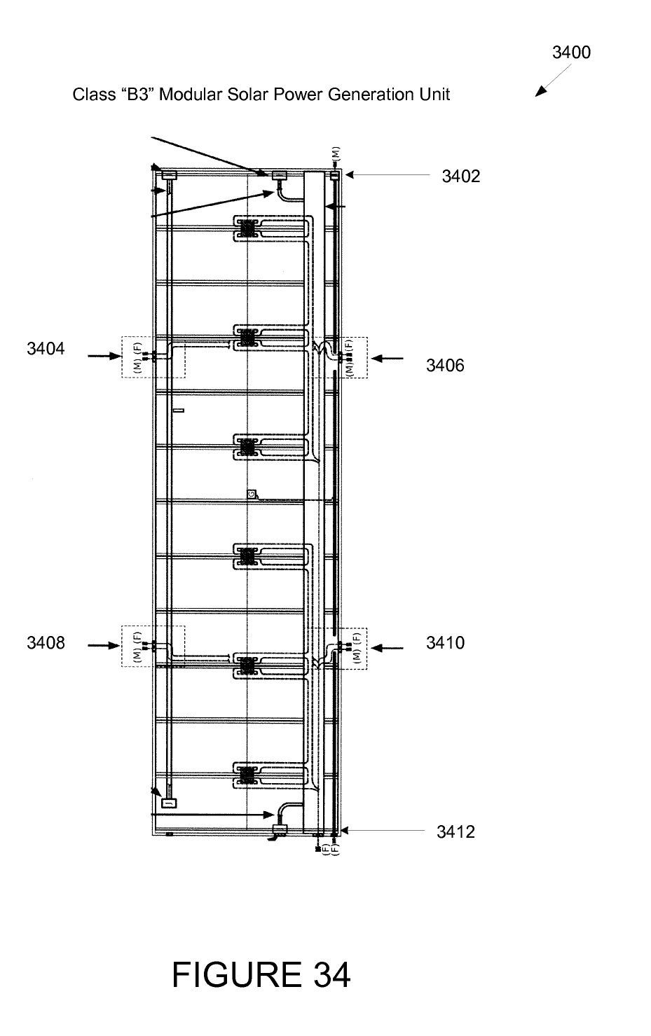

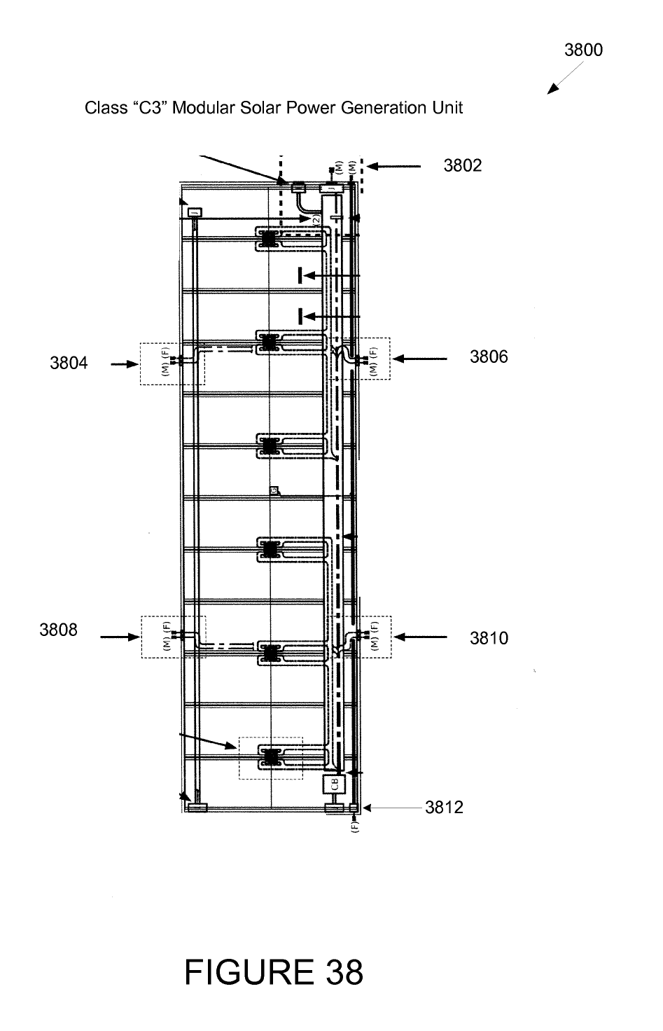

In the example of FIG. 30, the groups 3000 can include a group 3000C of ten modular solar power generation units. In this example, the group 3000C can include ten columns of modular solar power generation units. A first column comprises a Class “A” modular solar power generation unit, a Class “B1” modular solar power generation unit, and another Class “A” modular solar power generation unit. A second column comprises a Class “A” modular solar power generation unit, a Class “C1” modular solar power generation unit, and another Class “A” modular solar power generation unit. A third column comprises a Class “A” modular solar power generation unit, a Class “B2” modular solar power generation unit, and another Class “A” modular solar power generation unit. A fourth column comprises a Class “A” modular solar power generation unit, a Class “C2” modular solar power generation unit, and another Class “A” modular solar power generation unit. A fifth column comprises a Class “A” modular solar power generation unit, a Class “C3” modular solar power generation unit, and another Class “A” modular solar power generation unit. A sixth column comprises a Class “A” modular solar power generation unit, a Class “B3” modular solar power generation unit, and another Class “A” modular solar power generation unit. A seventh column comprises a Class “A” modular solar power generation unit, a Class “C2” modular solar power generation unit, and another Class “A” modular solar power generation unit. An eighth column comprises a Class “A” modular solar power generation unit, a Class “B2” modular solar power generation unit, and another Class “A” modular solar power generation unit. A ninth column comprises a Class “A” modular solar power generation unit, a Class “C1” modular solar power generation unit, and another Class “A” modular solar power generation unit. A tenth column comprises a Class “A” modular solar power generation unit, a Class “B1” modular solar power generation unit, and another Class “A” modular solar power generation unit. FIG. 31 shows an example of a Class “A” modular solar power generation unit, FIG. 32 shows an example of a Class “B1” modular solar power generation unit, FIG. 33 shows an example of a Class “B2” modular solar power generation unit, FIG. 36 shows an example of a Class “C1” modular solar power generation unit, FIG. 37 shows an example of a Class “C2” modular solar power generation unit, FIG. 34 shows an example of a Class “B3” modular solar power generation unit, and FIG. 38 shows an example of a Class “C3” modular solar power generation unit.

FIG. 31 shows an example of a Class “A” modular solar power generation unit 3100. In the example of FIG. 31, the Class “A” solar power generation unit 3100 can include a bilateral modular intermediate solar unit interface 3102 and a second bilateral modular intermediate solar unit interface 3104. In this example, each of the first bilateral modular intermediate solar unit interface 3102 and the second bilateral modular intermediate solar unit interface 3104 can include a male interface and a female interface. In the example of FIG. 31, the first bilateral modular intermediate solar unit interface 3102 and the second bilateral modular intermediate solar unit interface 3104 are located along a common edge of the Class “A” modular solar power generation unit 3100 (shown in FIG. 31 as the rightmost edge).

FIG. 32 shows an example of a Class “B1” modular solar power generation unit 3200. In the example of FIG. 32, the Class “B1” modular solar power generation unit 3200 can include a first bilateral modular intermediate solar unit interface 3202, a second bilateral modular intermediate solar unit interface 3204, a third bilateral modular intermediate solar unit interface 3206, a fourth bilateral modular intermediate solar unit interface 3208, a first unilateral modular intermediate solar unit interface 3210, and a second unilateral modular intermediate solar unit interface 3212. In this example, the first bilateral modular intermediate solar unit interface 3202 and the third bilateral modular intermediate solar unit interface 3206 are located on a common edge of the Class “B1” modular solar power generation unit 3200. The second bilateral modular intermediate solar unit interface 3204 and the fourth bilateral modular intermediate solar unit interface 3208 are located on a common edge of the Class “B1” modular solar power generation unit 3200 and opposite the edge of the interfaces 3202 and 3206. Each of the first bilateral modular intermediate solar unit interface 3202, the second bilateral modular intermediate solar unit interface 3204, the third bilateral modular intermediate solar unit interface 3206, and the fourth bilateral modular intermediate solar unit interface 3208 can include a male interface and a female interface. The unilateral modular intermediate solar unit interface 3210 and the second unilateral modular intermediate solar unit interface are located along the same edge as the interfaces 3204 and 3208 and only comprise female interfaces.

FIG. 33 shows an example of a Class “B2” modular solar power generation unit 3300. In the example of FIG. 3300, the Class “B2” modular solar power generation unit 3300 can include a first unilateral modular intermediate solar unit interface 3302, a first bilateral modular intermediate solar unit interface 3304, a second bilateral modular intermediate solar unit interface 3306, a third bilateral modular intermediate solar unit interface 3308, a fourth bilateral modular intermediate solar unit interface 3310, a second unilateral modular intermediate solar unit interface 3312, and a third unilateral modular intermediate solar unit interface 3314. The first bilateral modular intermediate solar unit interface 3304, the third bilateral modular intermediate solar unit interface 3308, and the second unilateral modular intermediate solar unit interface 3312 can be disposed on a common edge. The first unilateral modular intermediate solar unit interface, the second bilateral modular intermediate solar unit interface 3306, and the fourth bilateral modular intermediate solar unit interface 3310 can be disposed on another edge. In this example, the first bilateral modular intermediate solar unit interface 3304, the second bilateral modular intermediate solar unit interface 3306, the third bilateral modular intermediate solar unit interface 3308, and the fourth bilateral modular intermediate solar unit interface 3310 can each include male and female interfaces. The first unilateral modular intermediate solar unit interface 3302 can include only male interfaces. Each of the second unilateral modular intermediate solar unit interface 3312 and the third unilateral modular intermediate solar unit interface 3314 can include only female interfaces.

FIG. 34 shows an example of a Class “B3” modular solar power generation unit 3400. In the example of FIG. 34, the Class “B3” modular solar power generation unit 3400 can include a first unilateral modular intermediate solar unit interface 3402, a first bilateral modular intermediate solar unit interface 3404, a second bilateral modular intermediate solar unit interface 3406, a third bilateral modular intermediate solar unit interface 3408, a fourth bilateral modular intermediate solar unit interface 3410, and a second unilateral modular intermediate solar unit interface 3412. The first bilateral modular intermediate solar unit interface 3404 and the third bilateral modular intermediate solar unit interface 3408 can be disposed on one edge of the Class “B3” modular solar power generation unit 3400. The first unilateral modular intermediate solar unit interface 3402, the second bilateral modular intermediate solar unit interface 3406, the fourth bilateral modular intermediate solar unit interface 3410, and the second unilateral modular intermediate solar unit interface 3412 can be disposed on the other edge of the Class “B3” modular solar power generation unit 3400. Each of the first bilateral modular intermediate solar unit interface 3404, the second bilateral modular intermediate solar unit interface 3406, the third bilateral modular intermediate solar unit interface 3408, and the fourth bilateral modular intermediate solar unit interface 3410 can include a male interface and a female interface. The first unilateral modular intermediate solar unit interface 3402 can include only male interfaces. The second unilateral modular intermediate solar unit interface 3412 can include only female interfaces.

FIG. 35 shows an example of a Class “BC1” modular solar power generation unit 3500. In the example of FIG. 35, the Class “BC1” modular solar power generation unit 3500 can include a first bilateral modular intermediate solar unit interface 3502, a second bilateral modular intermediate solar unit interface 3504, a third bilateral modular intermediate solar unit interface 3506, a fourth bilateral 3508, and a unilateral modular intermediate solar unit interface 3510. The first bilateral modular intermediate solar unit interface 3502 and the third bilateral modular intermediate solar unit interface 3506 can be disposed on a common edge of the Class “BC1” modular solar power generation unit 3500. The second bilateral modular intermediate solar unit interface 3504, the fourth bilateral modular intermediate solar unit interface 3508, and the unilateral modular intermediate solar unit interface 3510 can be disposed on another edge of the Class “BC1” modular solar power generation unit 3500. Each of the first bilateral modular intermediate solar unit interface 3502, the second modular intermediate solar unit interface 3504, the third modular intermediate solar unit interface 3506, and the fourth modular intermediate solar unit interface 3508 can include a male interface and a female interface. The unilateral modular intermediate solar unit interface 3510 can include only female interfaces.

FIG. 36 shows an example of a Class “C1” modular solar power generation unit 3600. In the example of FIG. 36, the Class “C1” modular solar power generation unit 3600 can include a first unilateral modular intermediate solar unit interface 3602, a first bilateral modular intermediate solar unit interface 3604, a second bilateral modular intermediate solar unit interface 3606, a third bilateral modular intermediate solar unit interface 3608, a fourth bilateral modular intermediate solar unit interface 3610, and a second unilateral modular intermediate solar unit interface 3612. In this example, each of the first bilateral modular intermediate solar unit interface 3604 and the third bilateral modular intermediate solar unit interface 3608 can be located on a common edge of the Class “C1” modular solar power generation unit 3600. The first unilateral modular intermediate solar unit interface 3602, the second bilateral modular intermediate solar unit interface 3606, the fourth bilateral modular intermediate solar unit interface 3610, and the second unilateral modular intermediate solar unit interface 3612 can be disposed on an opposite edge of the Class “C1” modular solar power generation unit 3600. In this example, each of the first bilateral modular intermediate solar unit interface 3604, the second bilateral modular intermediate solar unit interface 3606, the third bilateral modular intermediate solar unit interface 3608, and the fourth modular intermediate solar unit interface 3610 can include both male and female interfaces. The first unilateral modular intermediate solar unit interface 3602 can include only male interfaces. The second unilateral modular intermediate solar unit interface 3612 can include only female interfaces.

FIG. 37 shows an example of a Class “C2” modular solar power generation unit 3700. In the example of FIG. 37, the Class “C2” modular solar power generation unit 3700 can include a first unilateral modular intermediate solar unit interface 3702, a first bilateral modular intermediate solar unit interface 3704, a second bilateral modular intermediate solar unit interface 3706, a third bilateral modular intermediate solar unit interface 3708, a fourth bilateral modular intermediate solar unit interface 3710, a second unilateral modular intermediate solar unit interface 3712, and a third unilateral modular intermediate solar unit interface 3714. The third unilateral modular intermediate solar unit interface 3714, the first bilateral modular intermediate solar unit interface 3704 and the third bilateral modular intermediate solar unit interface 3708 can share a common edge of the Class “C2” modular solar power generation unit 3700. The first unilateral modular intermediate solar unit interface 3702, the second bilateral modular intermediate solar unit interface 3704, the second bilateral modular intermediate solar unit interface 3710, and the second unilateral modular intermediate solar unit interface 3712. Each of the first bilateral modular intermediate solar unit interface 3704, the second bilateral modular intermediate solar unit interface 3706, the third unilateral modular intermediate solar unit interface 3708, and the fourth unilateral modular intermediate solar unit interface 3710 can include both male and female interfaces. The first unilateral modular intermediate solar unit interface 3702 and the third unilateral modular intermediate solar unit interface 3714 can include only male interfaces. The second unilateral modular intermediate solar unit interface 3712 can include only female interfaces.

FIG. 38 shows an example of a Class “C3” modular solar power generation unit 3800. In the example of FIG. 38, the Class “C3” modular solar power generation unit 3800 can include a first unilateral modular intermediate solar unit interface 3802, a first bilateral modular intermediate solar unit interface 3804, a second bilateral modular intermediate solar unit interface 3206, a third bilateral modular intermediate solar unit interface 3208, a fourth bilateral modular intermediate solar unit interface 3210, and a second unilateral modular intermediate solar unit interface 3812. Each of the first bilateral modular intermediate solar unit interface 3804 and the third bilateral modular intermediate solar unit interface 3808 can be disposed on a common edge of the Class “C3” modular solar power generation unit 3800. Each of the first unilateral modular intermediate solar unit interface 3802, the second bilateral modular intermediate solar unit interface 3806, the fourth bilateral modular intermediate solar unit interface 3810, and the second unilateral modular intermediate solar unit interface 3812 can be disposed on the other edge of the Class “C3” modular solar power generation unit 3800. Each of the first bilateral modular intermediate solar unit interface 3804, the second bilateral modular intermediate solar unit interface 3806, the third modular intermediate solar unit interface 3808, and the fourth bilateral modular intermediate solar unit interface 3810 can include both male and female interfaces. The first unilateral modular intermediate solar unit interface 3802 can include only male interfaces. The second unilateral modular intermediate solar unit interface 3812 can include only female interfaces.

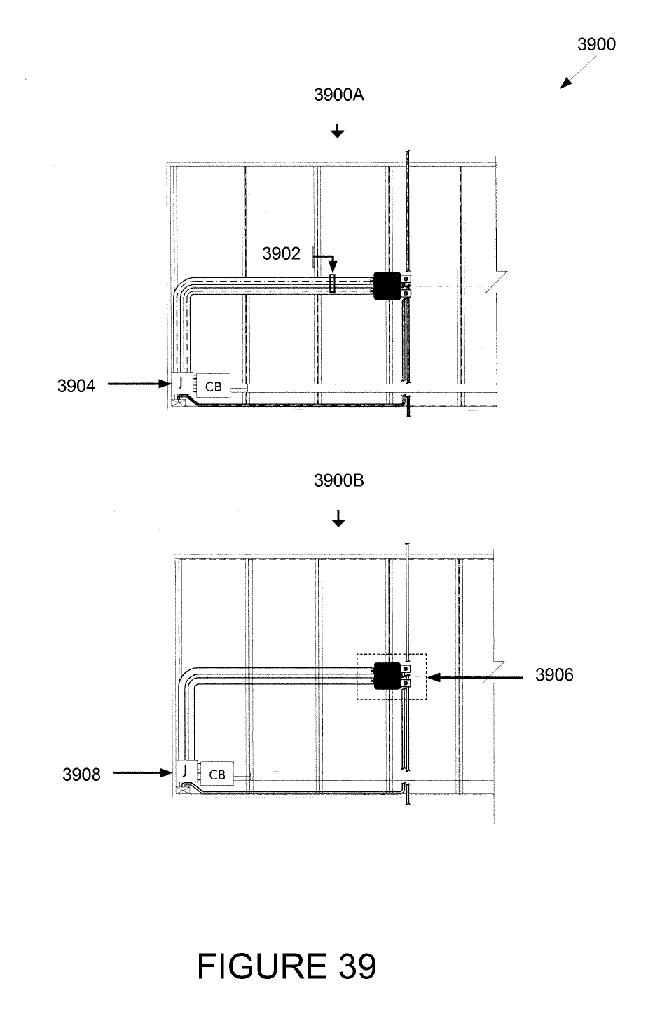

FIG. 39 shows example of configurations 3900 of electrical stubs of modular solar power generation units. In the example of FIG. 39, the configurations 3900 can include a first configuration 3900A and a second configuration 3900B. The first configuration 3900A shows a conduit 3902 and a joiner assembly 3904. The conduit 3902 can contain an electrical feeder and the conduit 3902 can be routed underground. The conduit 3902 can be wired on-site. The second configuration 3900B shows a wiring interface 3906 and a joiner assembly 3908.

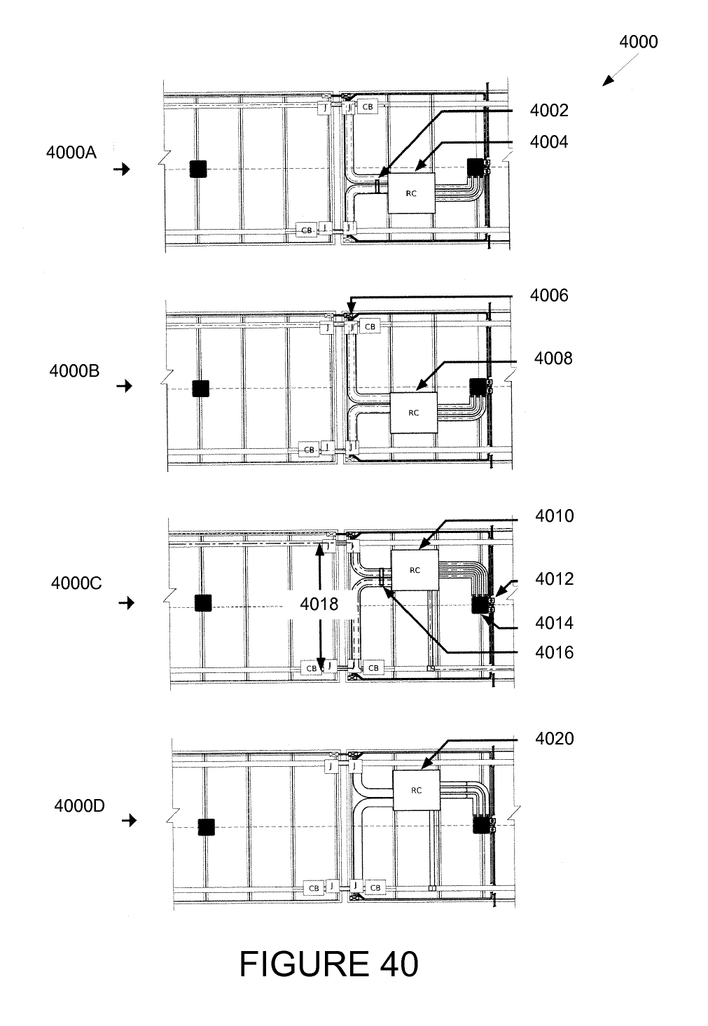

FIG. 40 shows an example of configurations 4000 of electrical stubs of modular solar power generation units. In the example of FIG. 40, the configurations 4000 can include a first configuration 4000A, a second configuration 4000B, a third configuration 4000C, and a fourth configuration 4000D. In the example of FIG. 40, the first configuration 4000A can include electrical feeders 4002 and a recombiner box 4004. The electrical feeders 4002 can be installed on a conduit, in some embodiments, on-site. The recombiner box 4004 can be mounted on the underside of the structure and installed on-site. The second configuration 4000B can include a joiner assembly 4006 and a recombiner box 4008. In this example, the joiner assembly 4006 can comprise one gang exterior rated J-box. The recombiner box can be mounted on the underside of the structure and installed on-site. The third configuration 4000C can include a recombiner box 4010, a joiner assembly 4012, a wiring interface 4014, an electrical feeder 4016, and a flexible conduit loop 4018. In this example, the recombiner box 4010, the joiner assembly 4012, and the flexible conduit loop 4018 can be installed on-site. The wiring interface 4010 can be installed in a dedicated manufacturing facility. The fourth configuration 4000D can include a recombiner box 4020, which can be installed in on-site.

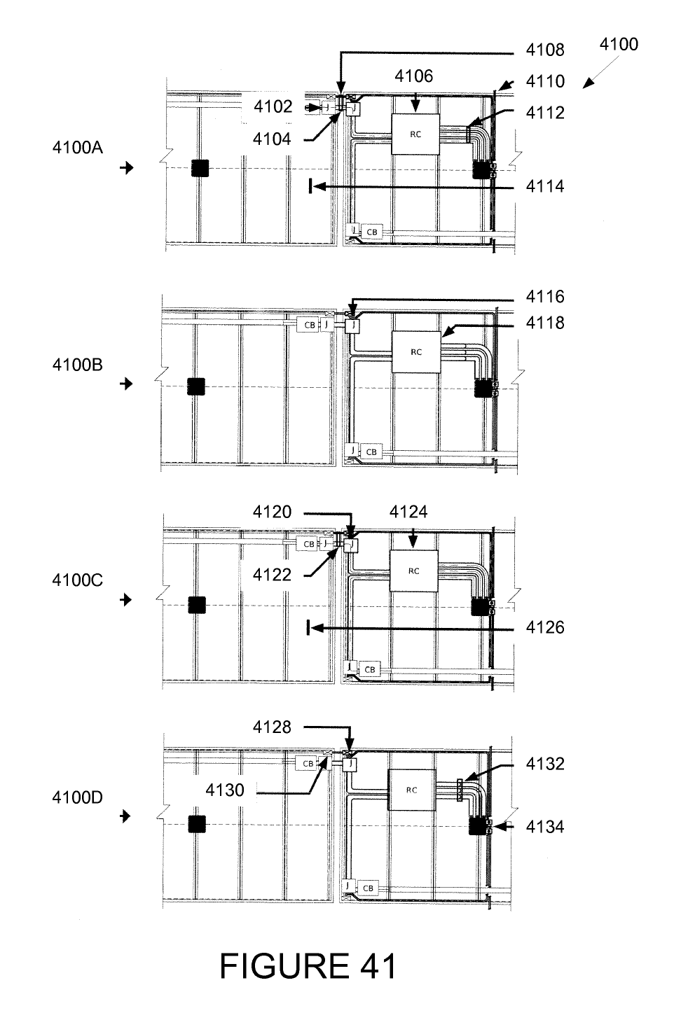

FIG. 41 shows an example of configurations 4100 of electrical stubs of modular solar power generation units. In the example of FIG. 41, the configurations 4100 can include a first configuration 4100A, a second configuration 4100B, a third configuration 4100C, and a fourth configuration 4100D. In the example of FIG. 41, the first configuration can include a joiner assembly 4102, a feeder 4104, a recombiner box 4106, a conduit 4108, a panel edge 4110, a feeder 4112, and a fixture 4114. Any of the components in the first configuration 4100A can be installed on-site or in a dedicated manufacturing facility. The second configuration 4100B can include a joiner assembly 4116 and a recombiner box 4118. The third configuration 4100C can include a joiner assembly 4120, a feeder 4122, a recombiner box 4124, and a fixture 4126. The fourth configuration 4100D can include a joiner assembly 4128, a joiner assembly 4130, a feeder 4132, and a wiring assembly 4134.

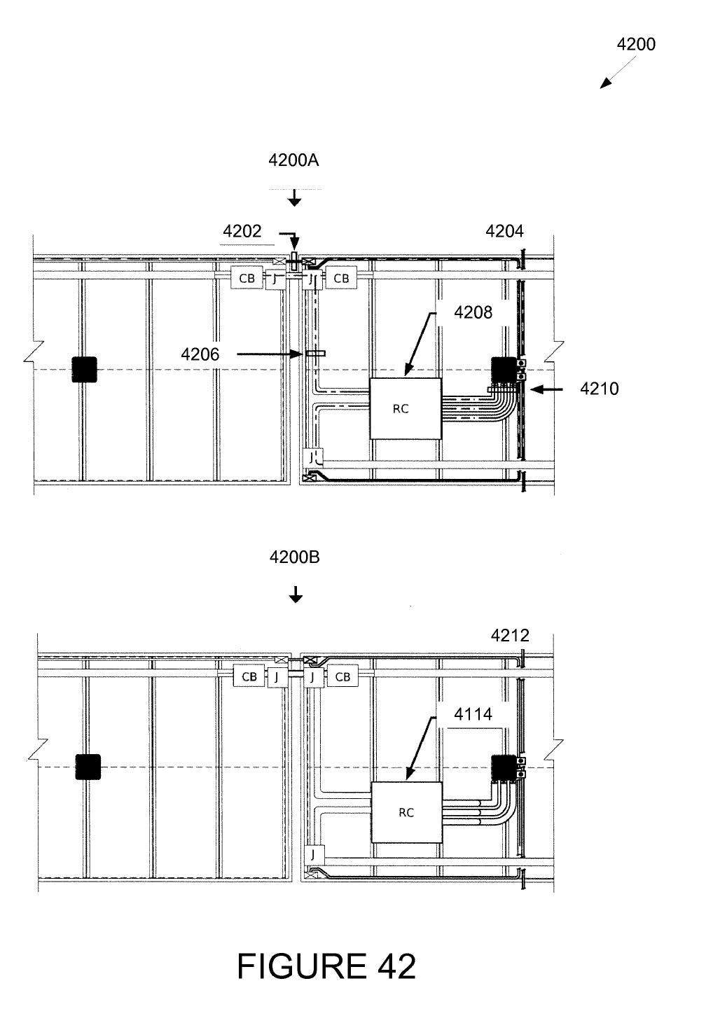

FIG. 42 shows an example of configurations 4200 of electrical stubs of modular solar power generation units. In the example of FIG. 42, the configurations 4200 can include a first configuration 4200A and a second configuration 4200B. The first configuration 4200A can include a flexible conduit loop 4202, a structural framing channel 4204, a feeder 4206, a recombiner box 4208, and a wiring assembly 4210. The second configuration 4200B can include a structural framing channel 4212 and a recombiner box 4214.

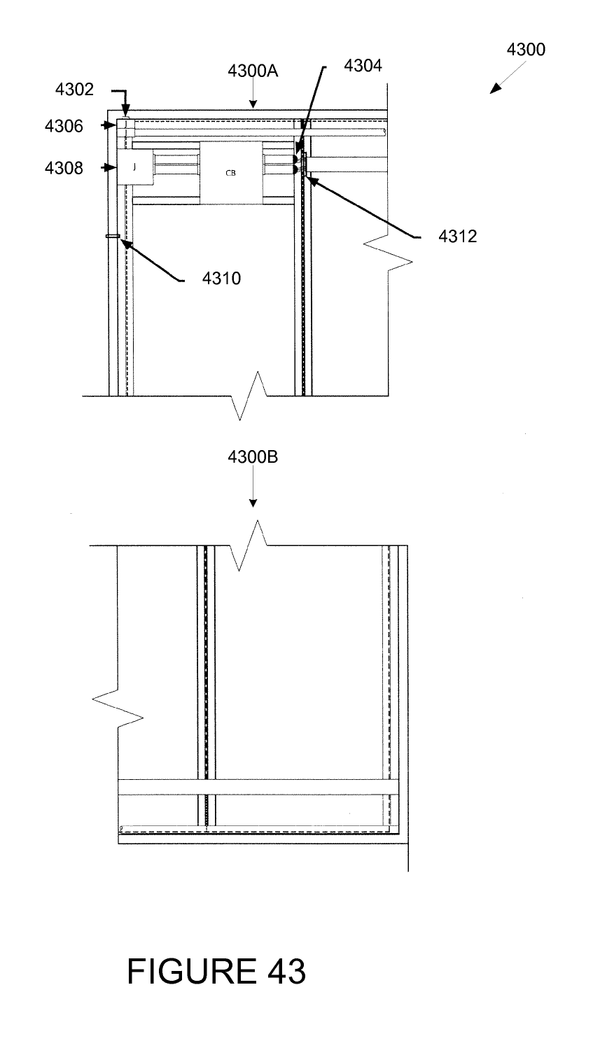

FIG. 43 shows an example of wiring configurations 4300 of modular solar power generation units. In the example of FIG. 43, the configurations 4300 can include a first configuration 4300A and a second configuration 4300B. The first configuration 4300A can include a structural frame 4302, a physical joint 4304, a joiner assembly 4306, an exterior rated pull box 4308, a structural frame 4310, and photovoltaic module wires 4312. The second configuration 4300B shows solar panels mounted on modular assemblies.

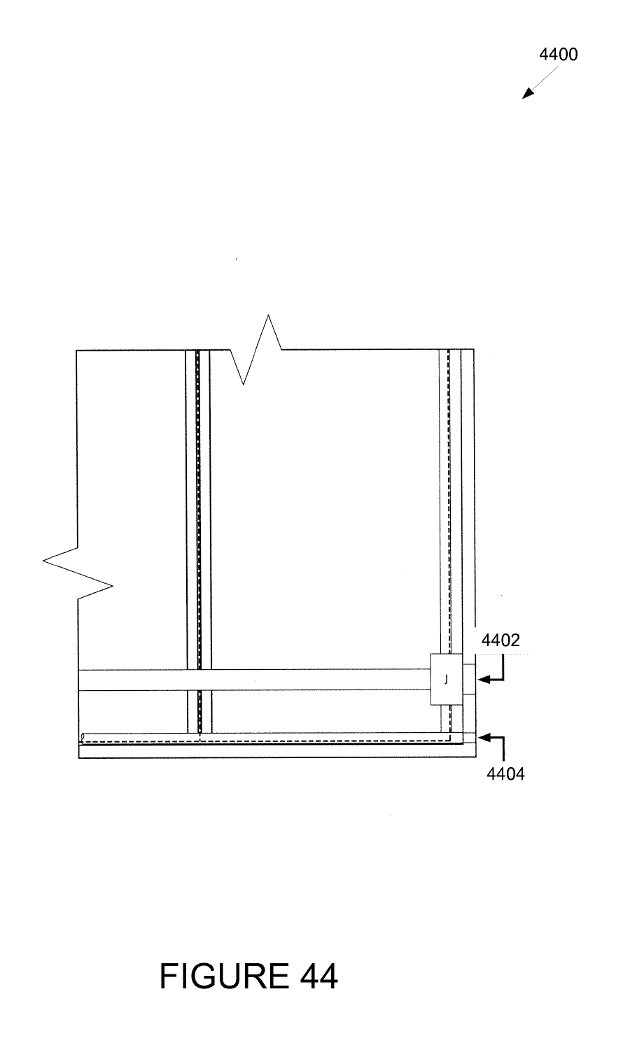

FIG. 44 shows an example of wiring configurations 4400 of modular solar power generation units. In the example of FIG. 44, the wiring configurations 4400 can include a first conduit sleeve 4402 and a second conduit sleeve 4404.

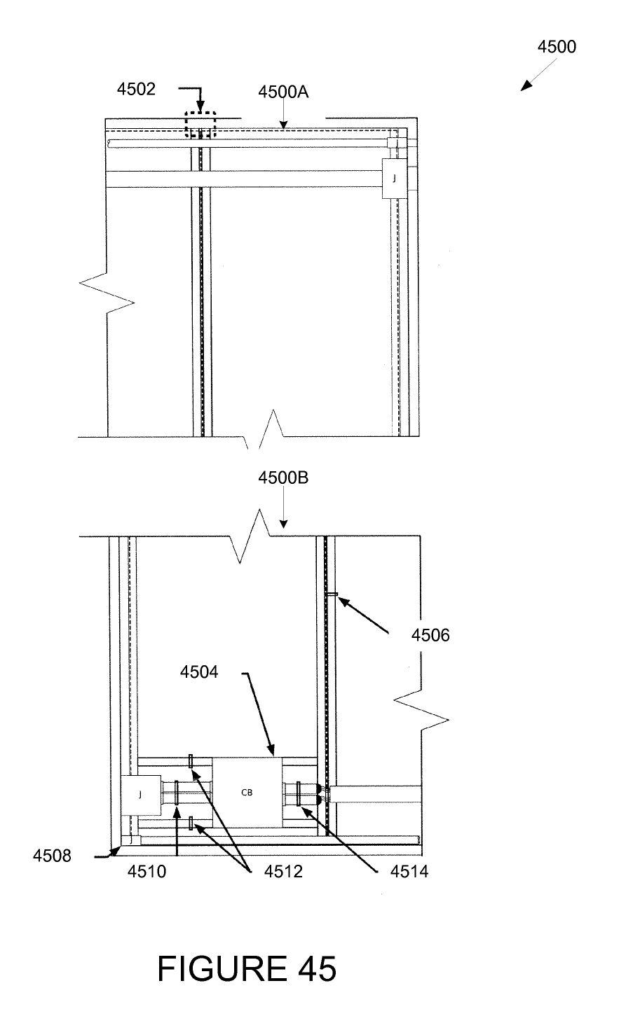

FIG. 45 shows an example of wiring configurations 4500 of modular solar power generation units. In the example of FIG. 45, the configurations 4500 can include a first configuration 4500A and a second configuration 4500B. The first configuration 4500A can include a structural framing channel attachment 4502. The second configuration 4500B can include a photovoltaic combiner box 4504, a structural framing channel 4506, a joiner assembly 4508, a conduit 4510, box supporting structural framing channels 4512, and a conduit 4514. In this example, box supporting structural framing channels 4512 are configured to physically support the photovoltaic combiner box 4504 and other components.

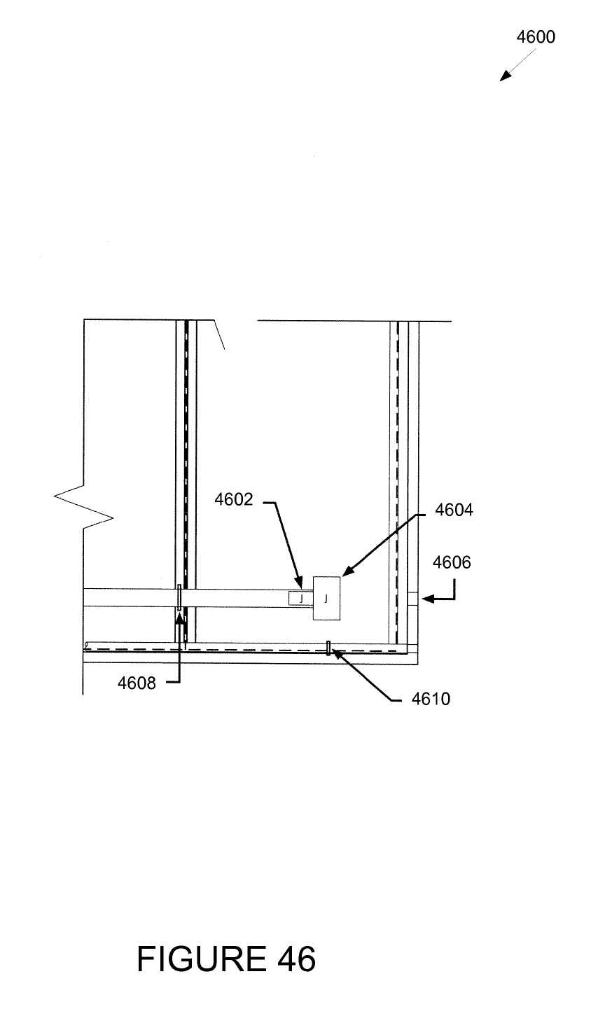

FIG. 46 shows an example of wiring configurations 4600 of modular solar power generation units. In the example of FIG. 46, the wiring configurations 4600 can include a joiner assembly 4602, a pull box 4604, a conduit sleeve 4606, a first structural framing channel 4608, and a second structural framing channel 4608.

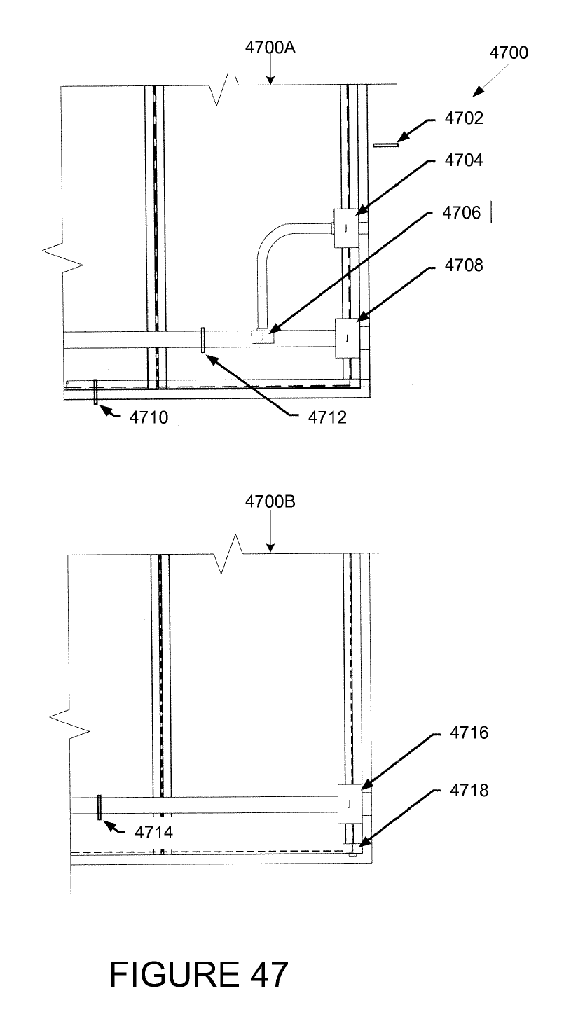

FIG. 47 shows an example of wiring configurations 4700 of modular solar power generation units. In the example of FIG. 47, the configurations 4700 can include a first configuration 4700A and a second configuration 4700B. The first configuration 4700A can include a structural frame 4702, holes 4704, a joiner assembly 4706, a joiner assembly 4708, a first structural framing channel 4710, and a second structural framing channel 4712. In this example, the holes 4704 can be configured to comprise holes through the structural frame 4702 to facilitate running electrical wires between structures. The second configuration 4700B can include a structural framing channel 4714, a first joiner assembly 4716, and a second joiner assembly 4718.

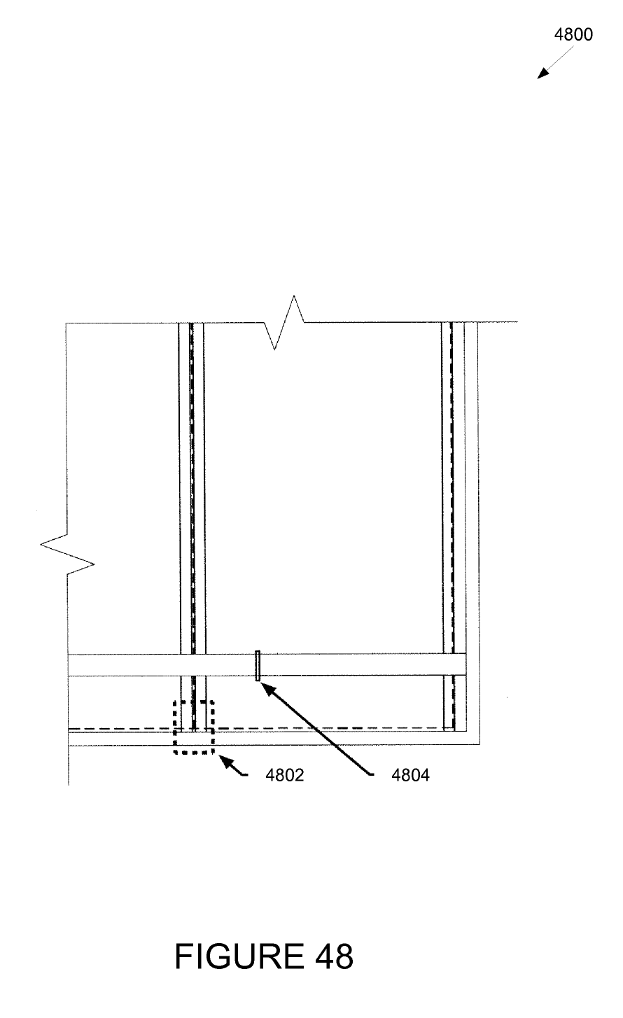

FIG. 48 shows an example of wiring configurations 4800 of modular solar power generation units. In the example of FIG. 48, the wiring configurations 4800 can include a channel attachment 4802 and a structural framing channel 4804.

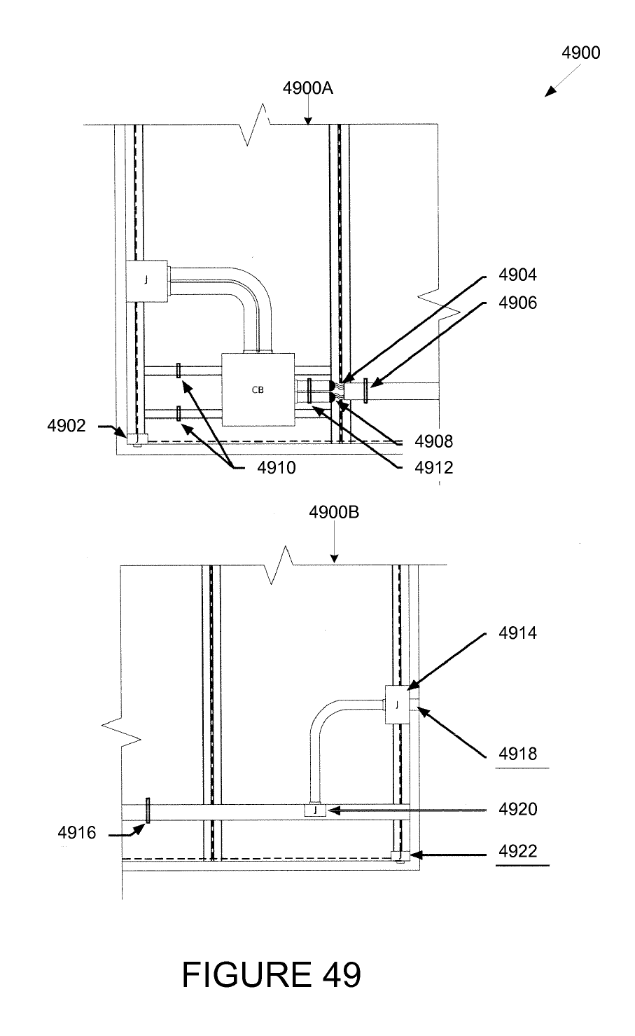

FIG. 49 shows an example of wiring configurations 4900 of modular solar power generation units. In the example of FIG. 49, the configurations 4900 can include a first configuration 4900A and a second configuration 4900B. The first configuration 4900A can include a joiner assembly 4902, a photovoltaic module wire 4904, a structural framing channel 4906, a physical joint 4908, structural framing channels 4910, and a conduit 4912 from a combiner box. The second configuration 4900B can include a pull box 4914, a structural framing channel 4916, holes, 4918, a joiner assembly 4920, and a joiner assembly 4922.

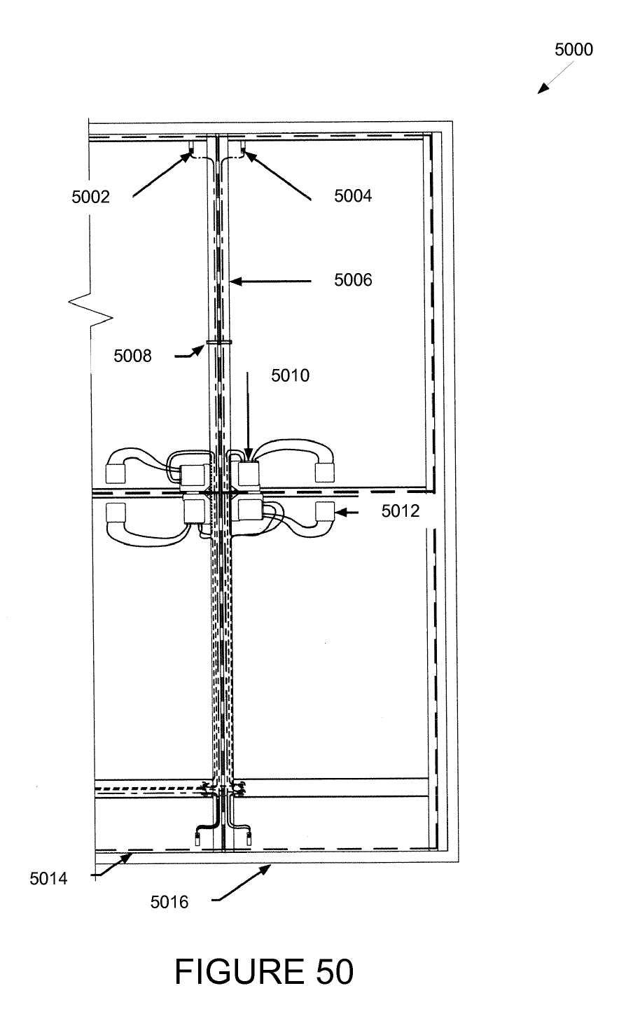

FIG. 50 shows an example of a wiring diagram 5000 for wiring a modular solar power generation unit to a structural framing channel. In the example of FIG. 50, the wiring diagram 5000 can include a first channel interface 5002, a second channel interface 5004, and a structural framing channel 5006. The diagram 5000 can further include an alignment device 5008 and a photovoltaic panel electrical outlet 5010. The diagram 5000 can also include another photovoltaic panel electrical outlet 5012. In this example, the diagram 5000 shows a panel edge 5014 and a canopy edge 5016.

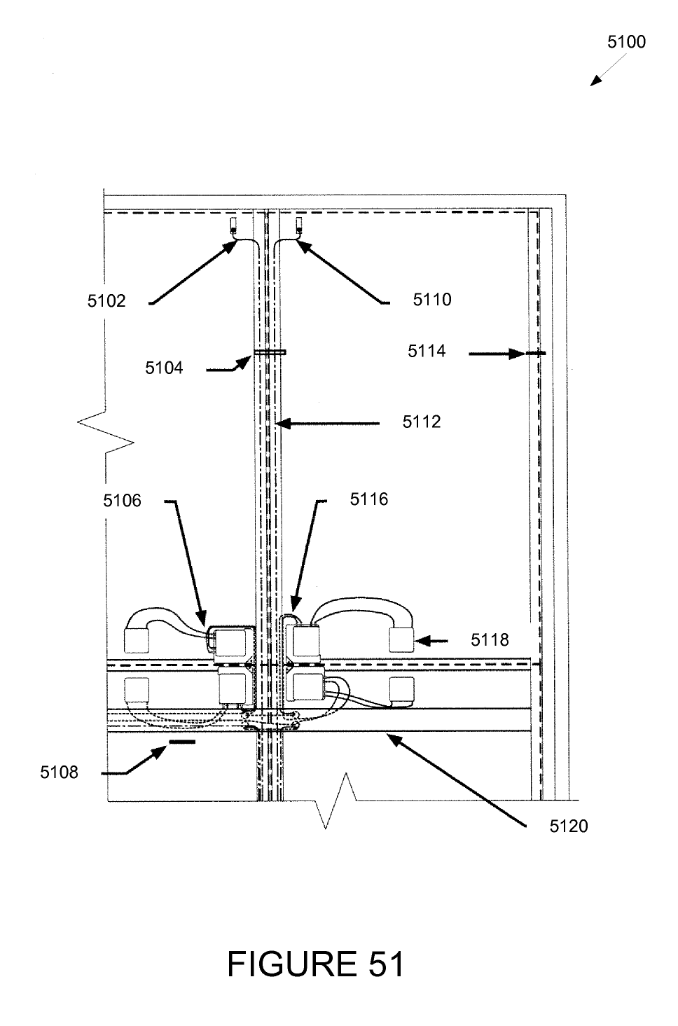

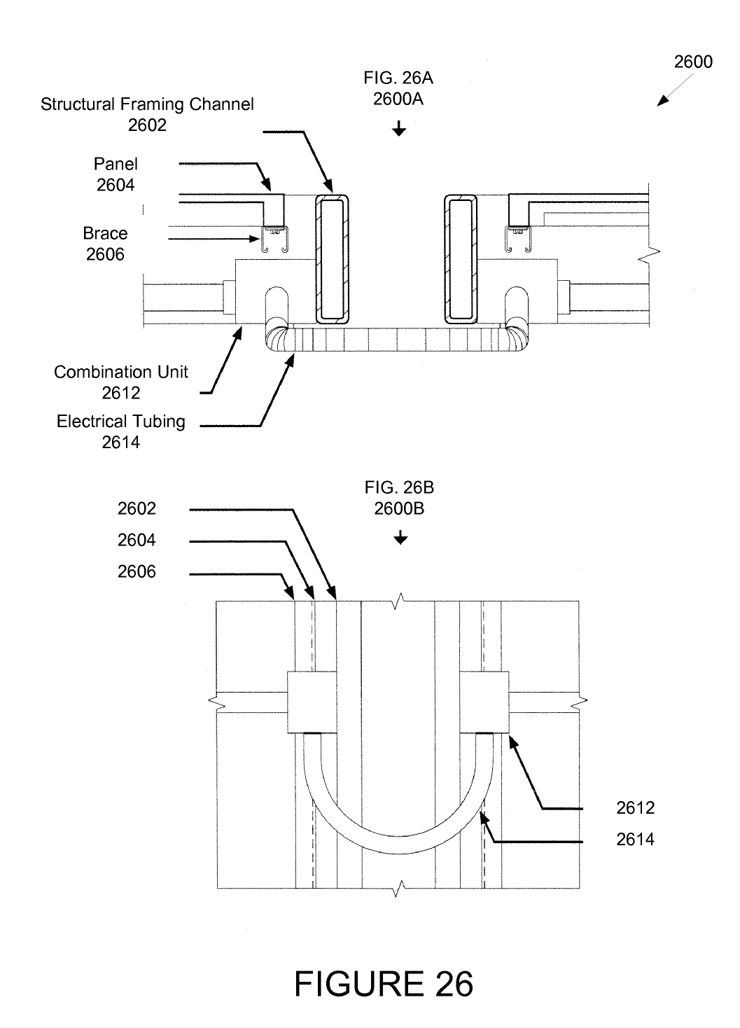

FIG. 51 shows an example of a wiring diagram 5100 for wiring a modular solar power generation unit to a structural framing channel. In the example of FIG. 51, the diagram 5100 can include a first channel interface 5102 and a second channel interface 5110. The diagram 5100 further shows an alignment device 5104, a structural framing channel 5112, wires 5106 from a photovoltaic panel electrical outlet, wires 5116 from a photovoltaic panel electrical outlet, and a photovoltaic panel electrical outlet 5118. In this example, the diagram 5100 can include a first fixture 5108 and a second fixture 5114. The diagram 5100 can further include a panel edge 5120.

We claim:

1. A photovoltaic mount comprising:
a photovoltaic body including a groove adapted to receive a first edge of a first photovoltaic panel at a first predetermined point, a second edge of the photovoltaic panel at a second predetermined point, and an edge of a second photovoltaic panel at a third predetermined point separated from the second predetermined point by a seismic gap;
a first fastener adapted to secure the first photovoltaic panel to the photovoltaic mount;
a second fastener adapted to secure the second photovoltaic panel to the photovoltaic mount;
a connective housing adapted to receive an electrical conduit coupled to the first photovoltaic panel and the second photovoltaic panel;
a modular coupling interface adapted to physically link to a modular power generation assembly, and to provide an electrical current from the electrical conduit to the modular power generation assembly.

2. The photovoltaic mount of claim 1, further comprising a structural framing channel adapted to house the connective assembly.

3. The photovoltaic mount of claim 1, wherein the second photovoltaic panel comprises a midsection photovoltaic panel, and the photovoltaic mount comprises a structural framing channel under the second photovoltaic panel.

4. The photovoltaic mount of claim 1, wherein the first photovoltaic panel comprises an endsection photovoltaic panel, and the photovoltaic mount comprises a structural framing channel adjacent to a wall of the groove of the photovoltaic mount.

5. The photovoltaic mount of claim 1, wherein the modular physical structure comprises a modular canopy.

6. The photovoltaic mount of claim 1, wherein the photovoltaic structural mount is sized to facilitate efficient transport to a power generation site.

7. The photovoltaic mount of claim 1, wherein the photovoltaic structural mount has a length of approximately forty feet and a width of approximately twelve feet.

8. A modular power generation unit comprising:
a modular base connection unit adapted to receive a support;
a modular photovoltaic mount coupled to the modular base connection unit, the modular photovoltaic unit having a plurality of mounted photovoltaic panels, each of the plurality of photovoltaic panels separated by a seismic gap;
a modular interface adapted to physically link the modular power generation unit to another modular power generation unit, and to provide from the plurality of photovoltaic panels to the other modular power generation unit or receive from the other modular power generation unit an electrical current.

9. The modular power generation unit of claim 8, wherein the modular interface comprises a male interface adapted to provide the electric current to the other modular unit.

10. The modular power generation unit of claim 8, wherein the modular interface comprises a female interface adapted to receive the electric current from the other modular unit.

11. The modular power generation unit of claim 8, wherein the modular interface comprises one or more of a modular intermediate interface and a modular termination interface.

12. The modular power generation unit of claim 8, wherein the modular photovoltaic mount is oriented with a specified tilt.

13. The modular power generation unit of claim 12, wherein the specified tilt is less than 5 degrees.

14. The modular power generation unit of claim 12, wherein the specified tilt is approximately 15 degrees.

15. The modular power generation unit of claim 8, wherein the support comprises a column.

16. The modular power generation unit of claim 8, wherein the base comprises one or more of a prefabricated base and a drilled pier.

17. The modular power generation unit of claim 8, further comprising a combiner box configured to receive the electrical current from the other modular structure.

18. The modular power generation unit of claim 8, further comprising a recombiner box configured to receive the electrical current from a combiner box on the other modular structure.

19. The modular power generation unit of claim 8, further comprising a joint attached to the framing channel, the joint adapted to connect the modular structure to the other modular structure.

20. The modular power generation unit of claim 8, wherein the modular power generation unit is integrated into a solar canopy.

21. The modular power generation unit of claim 8, wherein the modular power generation unit is integrated into a modular carport.

22. The modular power generation unit of claim 8, wherein the modular power generation unit is sized to facilitate efficient transportation to a power generation site.

23. The modular power generation unit of claim 8, wherein the modular power generation unit has a length of approximately forty feet and a width of approximately twelve feet.

24. A modular photovoltaic system, comprising:
a plurality of prefabricated intermediate modules, each of the plurality of prefabricated intermediate modules comprising a prefabricated mount structurally connecting a plurality of photovoltaic panels to a support adapted to be received by a base, and an intermediate electrical interface that provides electrical current from the plurality of photovoltaic panels;
a prefabricated termination module including:
a prefabricated mount structurally connecting a plurality of photovoltaic panels to a support adapted to be received by a base,
a plurality of termination electrical interfaces, each of the plurality of termination electrical interfaces receiving the electrical current from each of the plurality of prefabricated intermediate modules,
an output interface that provides to an external load the electrical current from the plurality of photovoltaic panels on the prefabricated termination module and a sum of electrical currents from the plurality of prefabricated intermediate modules.

25. The modular photovoltaic system of claim 24, wherein the plurality of prefabricated intermediate modules are arranged in series with the prefabricated termination module.

26. The modular photovoltaic system of claim 24, wherein the plurality of prefabricated intermediate modules comprise a plurality of prefabricated wing modules and the prefabricated termination module comprises a center module.

27. The modular photovoltaic system of claim 24, wherein the prefabricated termination module comprises a combiner box to receive the electrical current from each of the plurality of prefabricated intermediate modules, thereby creating the sum of electrical currents.

28. The modular photovoltaic system of claim 24, wherein one of the plurality of prefabricated intermediate modules comprises a combiner box to receive the electrical current from another of the plurality of prefabricated intermediate modules, thereby creating another sum of electrical currents.

29. The modular photovoltaic system of claim 24, wherein the prefabricated termination module comprises a recombiner box to receive summed currents from a combiner box on one of the plurality of prefabricated intermediate modules.

30. The modular photovoltaic system of claim 24, wherein the modular photovoltaic system is incorporated into a carport.

31. The modular photovoltaic system of claim 24, wherein the modular photovoltaic system is incorporated into a school parking lot.

32. A method, comprising:
creating a photovoltaic mount comprising a groove that receives a first photovoltaic panel having a first edge and a second edge, the groove receiving a second photovoltaic panel having an edge seismically spaced from the second edge of the first photovoltaic panel;
creating a plurality of modular connecting assemblies along a wall of the photovoltaic mount, the modular connecting assemblies facilitating mounting the photovoltaic mount onto a physical structure;
attaching a structural framing channel to the wall;
placing an electrical connectors through the structural framing channel;
connecting the electrical connectors to the first photovoltaic panel and the second photovoltaic panel.

33. The method of claim 32, further comprising:
coupling the first edge of the first photovoltaic panel to an end of the groove;
coupling the second edge of the first photovoltaic panel to an intermediate point of the groove;
coupling the edge of the second photovoltaic panel to another intermediate point of the groove.

34. The method of claim 32, wherein the method is executed in a dedicated manufacturing facility.

35. A method for creating a modular structure, the method comprising:
creating a prefabricated photovoltaic mount that receives a plurality of photovoltaic panels with a respective plurality of seismically spaced fasteners, the prefabricated photovoltaic mount comprising a plurality of modular connecting devices to connect the prefabricated photovoltaic mount to a support;
obtaining one or more structural framing channels containing one or more electrical connectors;
using each of the one or more structural framing channels to separate two of the plurality of photovoltaic panels on the prefabricated photovoltaic mount;
adapting at least some of the one or more electrical connectors to connect the plurality of photovoltaic panels to an external load;
adapting the support to be received by a base;
coupling the support to an intermediate point of the prefabricated photovoltaic mount.

36. The method of claim 35, wherein the method is executed in a dedicated manufacturing facility.

37. The method of claim 35, further comprising connecting the support to the base.

38. The method of claim 35, wherein connecting the support to the base comprises casting the support into the base.

39. The method of claim 35, wherein connecting the support the base is performed on the site of the created modular structure.

40. The method of claim 35, further comprising attaching a combiner box to the one or more electrical connectors, the combiner box configured to receive electrical current from another modular structure.

41. The method of claim 35, further comprising attaching a recombiner box to the one or more electrical connectors, the recombiner box configured to receive electrical current from a combiner box on another modular structure.
